(19) United States
(12) Patent Application Publication
(10) Pub. No.: US 2014/0338750 A1
(43) Pub. Date: Nov. 20, 2014

(54) ORGANIC PHOTOELECTRIC CONVERSION ELEMENT

(71) Applicant: Konica Minolta, Inc., Tokyo (JP)

(72) Inventors: Takayuki Iijima, Tokyo (JP); Yasushi Okubo, Tokyo (JP); Takamune Hattori, Tokyo (JP)

(21) Appl. No.: 14/366,797

(22) PCT Filed: Dec. 10, 2012
(86) PCT No.: PCT/JP2012/081924

§ 371 Date: Jun. 19, 2014

(30) Foreign Application Priority Data
Dec. 22, 2011 (JP) 2011-282048

(51) Int. Cl. H01L 51/00; H01L 51/42

(52) U.S. Cl. CPC H01L 51/0036; H01L 51/42; H01L 51/0043
USPC 136/263; 526/240

(57) ABSTRACT

The present invention has an object to provide an organic photoelectric conversion element exhibiting excellent durability. The present invention is to provide an organic photoelectric conversion element comprising a conjugated polymer compound having a partial structure represented by the following Chemical Formula 1.

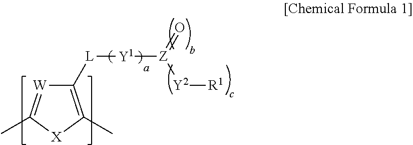

wherein X independently represents O, S, NR², or CR³═CR⁴; W independently represents CH or N; L independently represents a linear or branched alkylene group having 1 to 10 carbon atoms; Y¹ and Y² independently represent O or NR⁵; Z independently represents C, S, or P; R¹ to R⁵ independently represent H, a linear or branched alkyl group having 1 to 24 carbon atoms, a cycloalkyl group having 3 to 20 carbon atoms, an alkenyl group having 2 to 20 carbon atoms, an aryl group having 6 to 30 carbon atoms, or a heteroaryl group having 1 to 20 carbon atoms; and a, b, and c independently represent an integer satisfying the relation: 3≦a+b+c≦4 and 0≦a, b, c≦2.

### TECHNICAL FIELD

The present invention relates to an organic photoelectric conversion element. More specifically, the present invention relates to a technology for improving durability of an organic photoelectric conversion element.

### BACKGROUND ART

In recent years, reduction in carbon dioxide emission has been strongly desired to deal with global warming. In addition, it is expected that fossil fuels such as petroleum oil, coal, and natural gas are depleted in the near future. Hence, it is an urgent matter to secure earth-friendly energy resources to replace these fuels. Accordingly, the development of power generation technology using solar light, wind force, geothermal energy, and nuclear energy has been extensively conducted. Among them, photovoltaic power generation has received particular attention in terms of high safety.

In photovoltaic power generation, light energy is directly converted into electricity by a photoelectric conversion element using a photovoltaic effect. The photoelectric conversion element generally has a structure that a photoelectric conversion layer (light absorbing layer) is sandwiched between a pair of electrodes, and light energy is converted into electric energy in the photoelectric conversion layer. The photoelectric conversion elements are classified depending materials used in the photoelectric conversion layer and form of element, and a silicon-based photoelectric conversion element using monocrystallin silicon, polycrystalline silicon, and amorphous silicon, a compound-based photoelectric conversion element using a compound semiconductor such as GaAs or CIGS (semiconductor including copper (Cu)), indium (In), gallium (Ga), and selenium (Se)), a dye-sensitized photoelectric conversion element (Gratzel cell), and the like have been proposed and practically used.

The power generation cost when these solar cells are used, however, is still higher compared to the cost when fossil fuels are used to generate and transmit power, which has been an obstacle to the spread of photovoltaic power generation. In addition, reinforcement work is required when solar cells are installed on a roof since heavy glass is necessarily used as a substrate, which has also been a cause to contribute to the sharp rise in the power generation cost.

As a technology for reducing power generation cost of photovoltaic power generation, it has been proposed a bulk heterojunction (BHJ) type photoelectric conversion element which comprises as a photoelectric conversion layer a mixture of an electron donating organic compound (p-type organic semiconductor) and an electron accepting organic compound (n-type organic semiconductor) between a transparent electrode and a counter electrode. In 2007, photoelectric conversion efficiency exceeding 5% has been reported (Non-Patent Literature 1). Further, a prospect that even 10% photoelectric conversion efficiency can be theoretically achieved has been made (Non-Patent Literature 2).

The bulk heterojunction type organic photoelectric conversion element has a light weight and high flexibility, and thus is expected to be applied to various products. In addition, the structure thereof is relatively simple and the photoelectric conversion layer can be formed by coating a p-type organic semiconductor and an n-type organic semiconductor, and thus cost reduction can be expected by mass production by a roll-to-roll process, and thus it is thought that the bulk heterojunction type organic photoelectric conversion element contributes to the early spread of solar cell. More specifically, an electrode (anode and cathode), and a metal oxide layer constituting a hole transport layer, or the like can be formed by a process (for example, a vacuum deposition method or the like) other than coating process in the bulk heterojunction type organic photoelectric conversion element. On the other hand, the other layers can be formed using a coating process. Consequently, it is expected that the production of bulk heterojunction type organic photoelectric conversion element can be carried out at a high speed and a low cost, and thus it is thought that there is a possibility to solve the problem of power generation cost as described above. Moreover, unlike the production of a conventional silicon-based photoelectric conversion element, compound-based photoelectric conversion element, dye-sensitized photoelectric conversion element, and the like, the bulk heterojunction type organic photoelectric conversion element does not essentially involve a manufacturing process at a temperature higher than 160° C., and thus it is expected that the formation thereof on a plastic substrate of a low cost and a lightweight is also possible.

The organic photoelectric conversion element, however, cannot have sufficient durability against heat or light compared to other type photoelectric conversion elements. Hence, various improvements have proceeded in order to improve the durability. As an example, it has been proposed a so-called reverse layered type organic photoelectric conversion element (Patent Literature 1), in which individual layers are laminated in reverse to a conventional organic photoelectric conversion element, to extract electrons from a transparent electrode side and to extract holes are from a stable metal electrode side of a deep work function. Such a reverse layered type organic photoelectric conversion element has a disadvantageous configuration from the viewpoint of the utilization efficiency of light (Non-Patent Literature 3), since a hole transport layer including a conductive polymer with poor optical transparency is generally present between a counter electrode (anode) and a photoelectric conversion layer and light reflected from the counter electrode cannot be effectively reused in the photoelectric conversion layer. On the other hand, the reverse layered type organic photoelectric conversion element has higher durability than a stacked one since a metal such as gold or silver, which is hardly corroded by oxygen or water, can be used as an electrode.

In addition, the improvement of bulk heterojunction (BHJ) structure in the photoelectric conversion layer has been also attempted in order to improve the durability. In the BHJ type photoelectric conversion layer, each of the two kinds of materials of a p-type organic semiconductor and an n-type organic semiconductor is randomly filled by forming a domain of a specific size, and the charge separation occurs at the interface thereof. Consequently, it is thought that it is important to maintain the favorable morphology between the p-type organic semiconductor and the n-type organic semiconductor even when exposed to light or heat for a long period of time for the improvement in durability.

Recently, it has been reported that intermolecular interaction between p-type organic semiconductor material and n-type organic semiconductor material is improved by introducing an ester group, an amide group, or the like into a side chain alkyl group of polythiophene of the p-type organic semiconductor material, and thus a favorable morphology is formed, and as a result, the durability is improved (Patent Literature 2). In addition, in Non-Patent Literature 4, it has been reported that durability can be improved by reacting a side chain of a donor unit-acceptor unit copolymer capable of absorbing light to 700 nm by heat to convert into carboxylic acid.

### CITATION LIST

### Patent Literature

Patent Literature 1: JP-A-2009-146981
Patent Literature 2: WO 2011/069554 A

### Non-Patent Literature

Non-Patent Literature 1: A. Heeger et al., Nature Mat., vol. 6 (2007): P497
Non-Patent Literature 2: Christoph J. Brabec et al., Adv. Mater., 2006, 18: P789
Non-Patent Literature 3: Appl. Phys. Lett., 98, 043301 (2011)
Non-Patent Literature 4: Polym. Chem., 2011, 2: P2536

### SUMMARY OF INVENTION

The p-type organic semiconductor material described in the Patent Literature 2, however, has a short absorption wavelength, and the photoelectric conversion efficiency of the element is also less than 2.5%. In addition, the element using a photoelectric conversion material described in the Non-Patent Literature 4 also has low photoelectric conversion efficiency as of 1.5% and thus is far from practical use. Moreover, durability of the element is not yet sufficient, and thus further improvement in durability has been desired. As described above, it is significantly difficult to attain both improved durability and sufficient photoelectric conversion efficiency, and thus further improvements have been required.

An object of the present invention is to provide an organic photoelectric conversion element exhibiting excellent durability.

Another object of the present invention is to provide an organic photoelectric conversion element capable of achieving sufficient photoelectric conversion efficiency.

The present inventors have conducted intensive investigations in order to solve the problems described above. As a result, it is found out that an organic photoelectric conversion element having high durability can be obtained by introducing a strong polar group such as a sulfonamide group or a carbamate group to a side chain alkyl group of a conjugated polymer compound used in a organic photoelectric conversion element, thereby completing the present invention.

In other words, the organic photoelectric conversion element of the present invention has a feature in comprising a conjugated polymer compound having a partial structure represented by the following Chemical Formula 1.

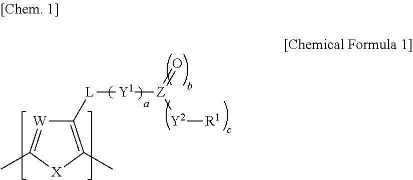

In the Formula, X independently represents an oxygen atom (O), a sulfur atom (S), NR², or CR³═CR⁴; W independently represents CH or a nitrogen atom (N); L independently represents a linear or branched alkylene group having 1 to 10 carbon atoms; Y¹ and Y² independently represent an oxygen atom (O) or NR⁵; Z independently represents a carbon atom (C), a sulfur atom (S), or a phosphorus atom (P); R¹ to R⁵ independently represent a hydrogen atom (H), a linear or branched alkyl group having 1 to 24 carbon atoms, a cycloalkyl group having 3 to 20 carbon atoms, an alkenyl group having 2 to 20 carbon atoms, an aryl group having 6 to 30 carbon atoms, or a heteroaryl group having 1 to 20 carbon atoms; and a, b, and c independently represent an integer satisfying the relation: 3≦a+b+c≦4 and 0≦a, b, c≦2

### BRIEF DESCRIPTION OF DRAWINGS

FIG. 1 is a schematic cross-sectional view schematically illustrating a forward layered type organic photoelectric conversion element according to an embodiment of the present invention. In FIG. 1, reference numeral 10 represents an organic photoelectric conversion element; reference numeral 11 represents an anode; reference numeral 12 represents a cathode; reference numeral 14 represents a photoelectric conversion layer; reference numeral 25 represents a substrate; reference numeral 26 represents a hole transport layer; and reference numeral 27 represents an electron transport layer, respectively.

FIG. 2 is a schematic cross-sectional view schematically illustrating a reverse layered type organic photoelectric conversion element according to another embodiment of the present invention. In FIG. 2, reference numeral 20 represents an organic photoelectric conversion element; reference numeral 11 represents an anode; reference numeral 12 represents a cathode; reference numeral 14a represents a first photoelectric conversion layer; reference numeral 14b represents a second photoelectric conversion layer; reference numeral 25 represents a substrate; 26 represents a hole transport layer; and reference numeral 27 represents an electron transport layer, respectively.

FIG. 3 is a schematic cross-sectional view schematically illustrating an organic photoelectric conversion element equipped with a tandem type photoelectric conversion layer according to still another embodiment of the present invention. In FIG. 3, reference numeral 30 represents an organic photoelectric conversion element; reference numeral 11 represents an anode; reference numeral 12 represents a cathode; reference numeral 14 represents a photoelectric conversion layer; reference numeral 25 represents a substrate; reference numeral 26 represents a hole transport layer; reference numeral 27 represents an electron transport layer; and reference numeral 38 represents a charge recombination layer, respectively.

### DESCRIPTION OF EMBODIMENTS

Hereinafter, preferred embodiments of the present invention will be described.

<Organic Photoelectric Conversion Element>

An organic photoelectric conversion element according to an embodiment of the present invention has a feature in comprising a conjugated polymer compound obtained by introducing a specific polar group into a side chain alkyl group. In other words, the conjugated polymer compound according to the present embodiment has a partial structure represented by the following Chemical Formula 1. By taking the configuration described above, the organic photoelectric conversion element of the present invention can exhibit excellent durability. Meanwhile, the conjugated polymer compound of the present invention contains one or two or more of the partial structure represented by Chemical Formula 1, but X, W, L, Y¹ and Y², Z, R¹ to R⁵, and a, b, and c in each of the partial structures may be the same as or different from each other when two or more of the partial structures are present.

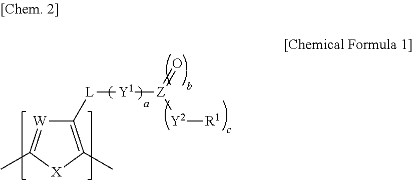

In the Chemical Formula 1, X independently represents an oxygen atom (O), a sulfur atom (S), NR², or CR³═CR⁴. W independently represents CH or a nitrogen atom (N). Specifically, the ring including X and W in the Chemical Formula 1 independently has any structure of a furan ring (X is O and W is CH), a thiophene ring (X is S and W is CH), a pyrrole ring (X is NR² and W is CH), a benzene ring (X is CR³═CR⁴ and W is CH), an oxazole ring (X is O and W is N), a thiazole ring (X is S, W is N), an imidazole ring (X is NR² and W is N), or a pyridine ring (X is CR³═CR⁴ and W is N). Meanwhile, any of the rings including X and W is an aromatic ring, and constitutes a main chain of the conjugated polymer compound according to the present embodiment. Accordingly, the ring including X and W is also referred to as the “main chain aromatic ring” hereinafter. Among the main chain aromatic rings, a main chain aromatic ring, in which X is a sulfur atom (S) or W is CH, is preferable from the viewpoint of achieving high photoelectric conversion efficiency. In particular, a conjugated polymer compound exhibiting high electrical conductivity and high mobility can be obtained when the main chain aromatic ring is a thiophene ring, in which X is a sulfur atom (S) and W is CH.

In the Chemical Formula 1, L independently represents a linear or branched alkylene group having 1 to 10 carbon atoms. Specific examples thereof include a methylene group (—CH₂—), an ethylene group (—CH₂CH₂—), a trimethylene group (—CH₂CH₂CH₂—), a propylene group (—CH(CH₃)CH₂—), or a 2-ethylhexamethylene group (—CH₂CH(CH₂CH₃)CH₂CH₂CH₂CH₂—). Among them, it is preferable that the carbon atom at position 3 or position 4 of the aromatic ring to which the side chain alkyl group is bonded and Y¹ or Z (when a=0) are sufficiently apart from each other in distance (in specific, the carbon atom at position 3 or position 4 of the aromatic ring and Y¹ or Z (when a=0) are present via a distance equal to or longer than an ethylene group (—CH₂CH₂—)), in consideration of steric hindrance between the hydrogen atom in the side chain alkyl group and the main chain aromatic ring. Hence, the carbon number of the main chain of L is preferably two or more. In addition, the main chain of L is preferably an ethylene group from the viewpoint of easy synthesis.

In the Chemical Formula 1, the group represented by the following Chemical Formula 5 is bonded to the main chain aromatic group via the linking group L, and represents a polar group.

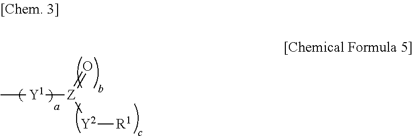

In the Chemical Formula 1 (Chemical Formula 5), Y¹ and Y² independently represent an oxygen atom (O) or NR⁵. Z independently represents a carbon atom (C), a sulfur atom (S), or a phosphorus atom (P). a, b, and c independently represent an integer satisfying the relation: 3≦a+b+c≦4 and 0≦a, b, c≦2. Specifically, specific examples of the polar group represented by Chemical Formula 5 include a sulfonamide group (—SO₂NR¹R⁵), a carbamate group (—OCONR¹R⁵ or —NR⁵C(O)OR¹), a carbonate group (—OCOOR¹), a phosphoric acid ester group (—PO(OR¹)²), a urea group (—NR⁵CONR¹R⁵), a phosphoric acid amide group (—PO(NR¹R⁵)₂), or a sulfonic acid ester group (—SO₂OR¹). Among them, from the viewpoints of strong polarity and excellent stability, at least either Y¹ or Y² in the Chemical Formula 1 (Chemical Formula 5) is preferably NR⁵ and Y² is particularly preferably NR⁵. In addition, Z in the Chemical Formula 1 (Chemical Formula 5) is preferably a sulfur atom (S) from the viewpoint of that a thiophene ring can impart high conductivity. More specifically, among the polar groups exemplified above, in consideration of the stability of the polar group itself or ease of synthesis, a sulfonamide group, a carbamate group, a carbonate group, and a phosphoric acid ester group are preferable; a sulfonamide group, a carbamate group, and a carbonate group are more preferable; a sulfonamide group and a carbamate group are still more preferable; and a sulfonamide group is the most preferable.

The conjugated polymer compound of the present embodiment has a feature in that the polar group represented by the Chemical Formula 5 is included in the side chain alkyl group of the partial structure represented by the Chemical Formula 1. The mechanism for the improvement in durability of the organic photoelectric conversion element in a case in which the conjugated polymer compound is used is not clear but is presumed as follows by the inventors. Specifically, it is thought that the polar group represented by the Chemical Formula 5 exhibits strong polarity since Z (a carbon atom, a sulfur atom, or a phosphorus atom) in the formula is bonded to three or more hetero atoms (an oxygen atom or NR⁵). It is thought that a strong intermolecular interaction is expressed since the molecule is more polarized by introducing a strong polar group into the alkyl chain in this manner. As a result, it is thought that a favorable morphology between the conjugated polymer compound and the n-type organic semiconductor is formed and maintained and the morphology is also stable with respect to light or heat resulting in improvement in durability of the element, for example, when the conjugated polymer compound is used in the BHJ type photoelectric conversion layer. When measurement was actually performed using infrared spectroscopy, for example, a carbamate group exhibited a higher absorption wave number than an ester group, and it was expected that the carbamate group was more polarized and thus intermolecular interaction thereof was stronger. Meanwhile, the mechanism described above is merely based on presumption. Hence, the technical scope of the present invention is not affected in any way even though the effect as described above is obtained by a mechanism other than the mechanism described above.

R¹ to R⁵, which may be present in the partial structure represented by the Chemical Formula 1, independently represents a hydrogen atom (H), a linear or branched alkyl group having 1 to 24 carbon atoms, a cycloalkyl group having 3 to 20 carbon atoms, an alkenyl group having 2 to 20 carbon atoms, an aryl group having 6 to 30 carbon atoms, or a heteroaryl group having 1 to 20 carbon atoms. In particular, R¹ is preferably a linear or branched alkyl group having 1 to 24 carbon atoms, a cycloalkyl group having 3 to 20 carbon atoms, an alkenyl group having 2 to 20 carbon atoms, an aryl group having 6 to 30 carbon atoms, or a heteroaryl group having 1 to 20 carbon atoms. On the other hand, R² to R⁴ are preferably a hydrogen atom.

The alkyl group having 1 to 24 carbon atoms is not particularly limited, and examples thereof include a methyl group, an ethyl group, an n-propyl group, an isopropyl group, an n-butyl group, an isobutyl group, a sec-butyl group, a tert-butyl group, an n-pentyl group, an isopentyl, a neopentyl, an n-hexyl group, a cyclohexyl group, an n-heptyl, an n-octyl, an n-nonyl, an n-decyl group, a 2-ethylhexyl group, a 2-hexyldecyl group, an n-undecyl group, an n-dodecyl group, an n-tridecyl group, an n-tetradecyl group, a 2-tetraoctyl group, an n-pentadecyl group, an n-hexadecyl group, a 2-hexyldecyl group, an n-heptadecyl group, a 1-octylnonyl group, an n-octadecyl group, an n-nonadecyl group, an n-icosyl group, and a 2-decyltetradecyl group. Among them, from the viewpoints of increasing crystallinity of the conjugated polymer compound and improving mobility of carrier; or from the viewpoint of improving solubility of monomer in the production of the conjugated polymer compound, an alkyl group having 1 to 20 carbon atoms is preferable, and a linear alkyl group having relatively a large number of carbon atoms (a carbon number of 4 to 16, and particularly 6 to 14) are more preferable, and specifically, an n-octyl group, an n-nonyl group, an n-decyl group, and the like are preferable.

The cycloalkyl group having 3 to 20 carbon atoms is not particularly limited, and examples thereof include a cyclopropyl group, a cyclopentyl group, a cyclohexyl group, a norbornyl group, and an adamantyl group. Among them, a cycloalkyl group having from 4 to 8 carbon atoms is preferable from the viewpoint of improving solubility.

The alkenyl group having 2 to 20 carbon atoms is not particularly limited, and examples thereof include an ethynyl group, a propynyl group, a butynyl group, an octynyl group, a nonynyl group, and a decynyl group. Among them, an alkenyl group having 6 or more carbon atoms, and particularly 6 to 10 carbon atoms is preferable from the viewpoint of improving solubility.

The aryl group having 6 to 30 carbon atoms is not particularly limited, and examples thereof include a non-condensed hydrocarbon group such as a phenyl group, a biphenyl group, or a terphenyl group; and a condensed polycyclic hydrocarbon group such as a pentalenyl group, an indenyl group, a naphthyl group, an azulenyl group, a heptalenyl group, a biphenylenyl group, a fluorenyl group, an acenaphthylenyl group, a pleiadenyl group, an acenaphthenyl group, a phenalenyl group, a phenanthryl group, an anthryl group, a fluoranthenyl group, an acephenantolylenyl group, an aceanthrylenyl group, a triphenylenyl group, a pyrenyl group, a chrysenyl group and a naphthacenyl group.

The heteroaryl group having 1 to 20 carbon atoms is not particularly limited, and examples thereof include a pyridyl group, a pyrimidyl group, a pyrazinyl group, a triazinyl group, a furanyl group, a pyrrolyl group, a thiophenyl group (thienyl group), a quinolyl group, a furyl group, a piperidyl group, a coumarinyl group, a silafluorenyl group, a benzofuranyl group, a benzimidazolyl group, a benzoxazolyl group, a benzothiazolyl group, a dibenzofuranyl group, a benzothiophenyl group, a dibenzothiophenyl group, an indolyl group, a carbazolyl group, a pyrazolyl group, an imidazolyl group, an oxazolyl group, an isoxazolyl group, a thiazolyl group, an indazolyl group, a benzothiazolyl group, a pyridazinyl group, a cinnolyl group, a quinazolyl group, a quinoxalyl group, aphthalazinyl group, aphthalazinedionyl group, a phthalamidyl group, a chromonyl group, a naphtholactamyl group, a quinolonyl group, a naphthalidinyl group, a benzimidazolonyl group, a benzoxazolonyl group, a benzothiazolonyl group, a benzothiazothionyl group, a quinazolonyl group, a quinoquixalonyl group, a phthalazonyl group, a dioxopyrimidinyl group, a pyridonyl group, an isoquinolonyl group, an isoquinolinyl group, an isothiazolyl group, a benzisoxazolyl group, a benzisothiazolyl group, an indazilonyl group, an acridinyl group, an acridonyl group, a quinazoline dionyl group, a quinoxaline dionyl group, a benzoxazine dionyl group, a benzoxazinonyl group, a naphthalimidyl group, a dithienocyclopentadienyl group, a dithienosilacyclopentadienyl group, a dithienopyrrolyl group, and a benzodithiophenyl group.

Hereinafter, preferred examples of the partial structure represented by the Chemical Formula 1 will be exemplified.

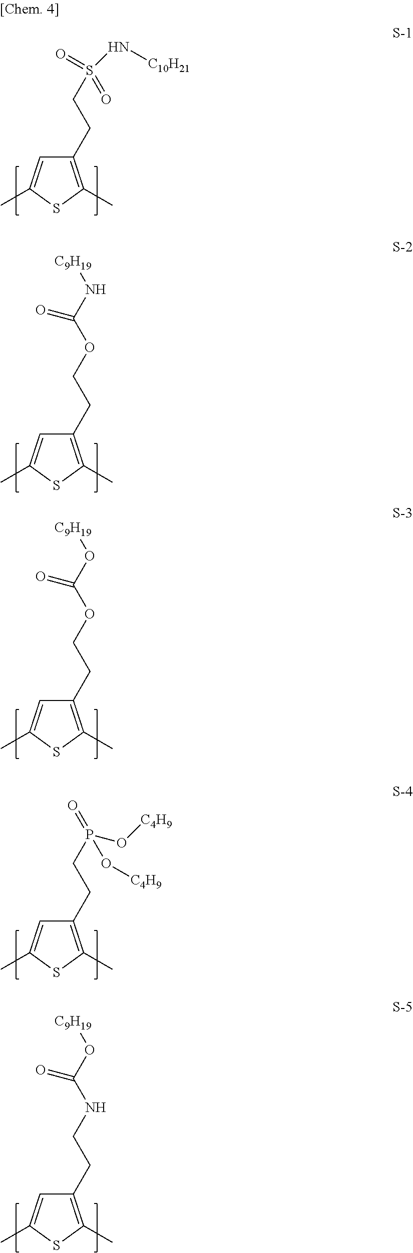

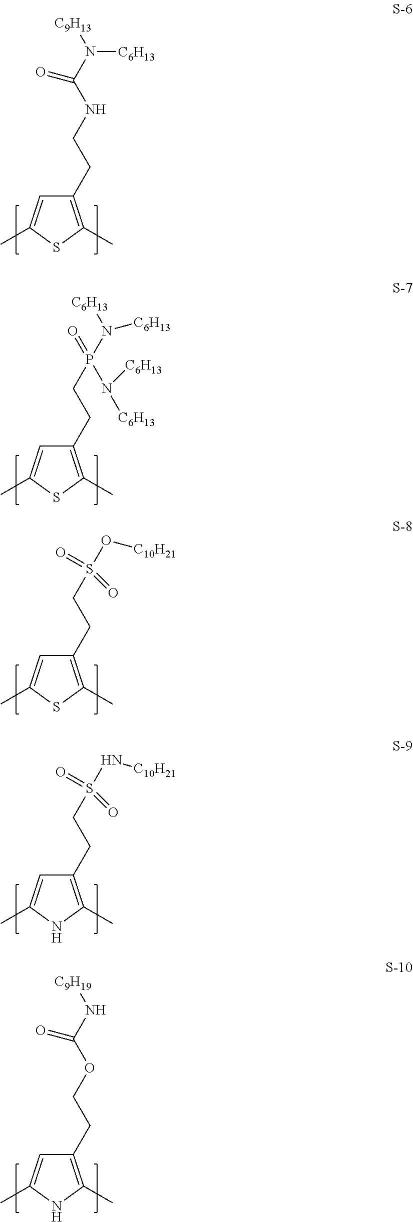

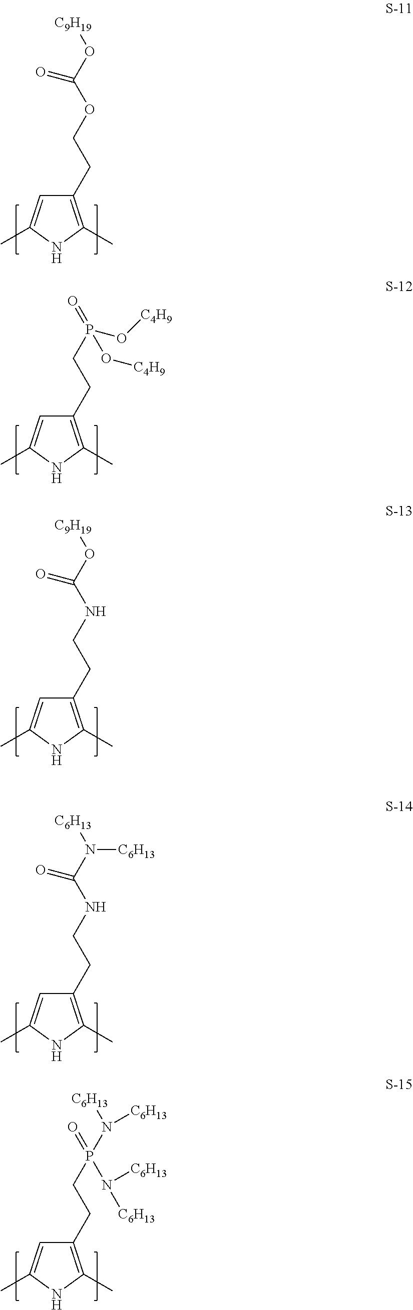

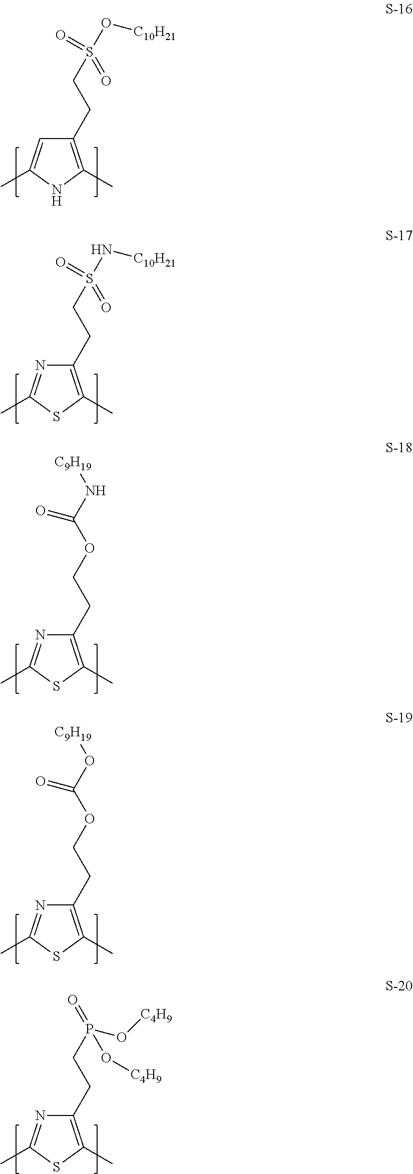

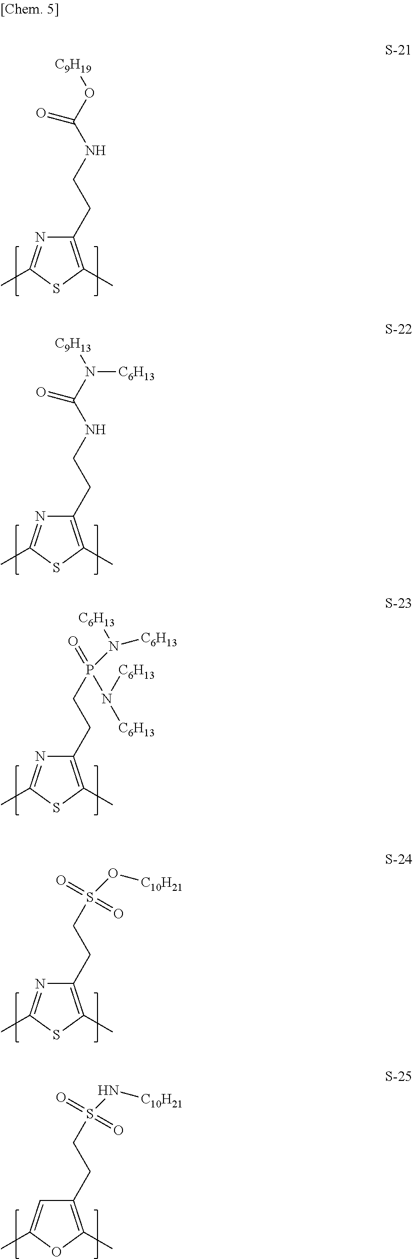

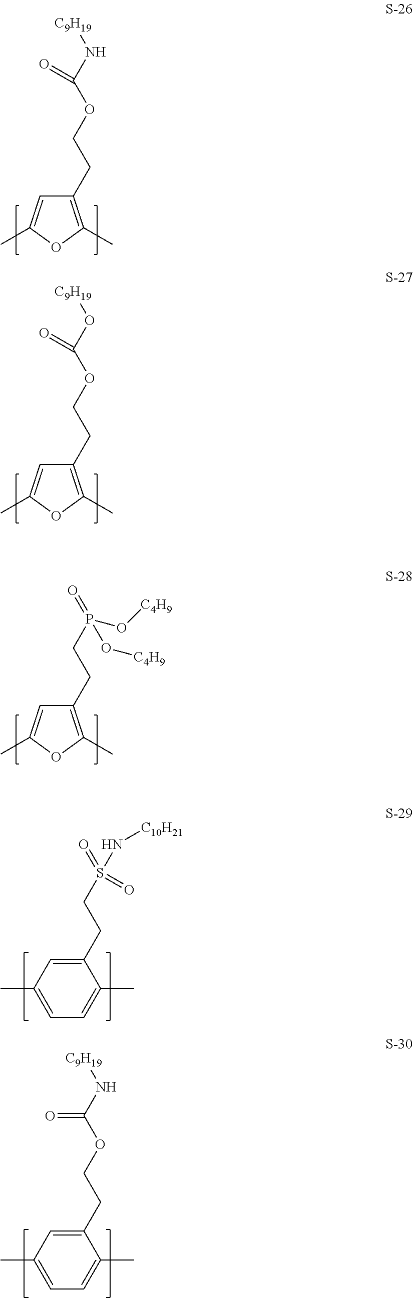

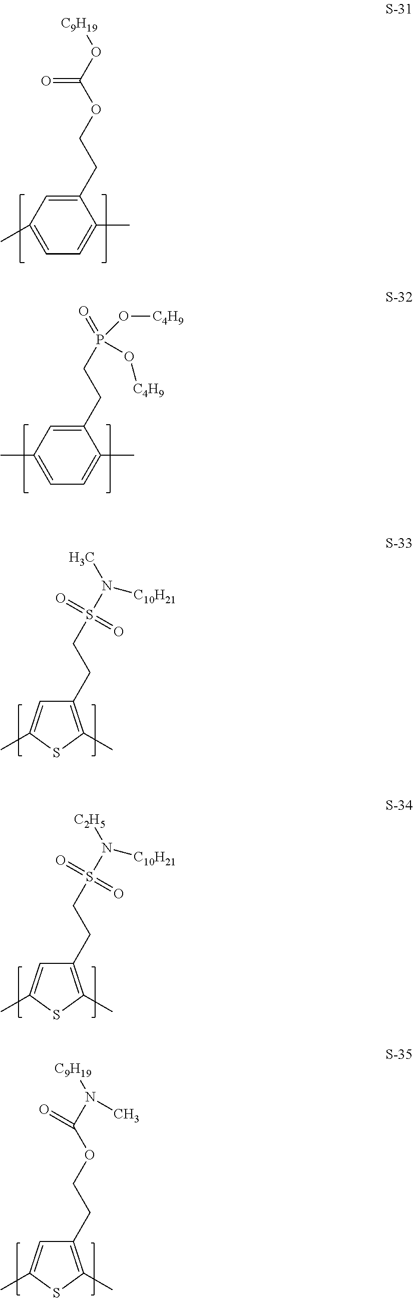

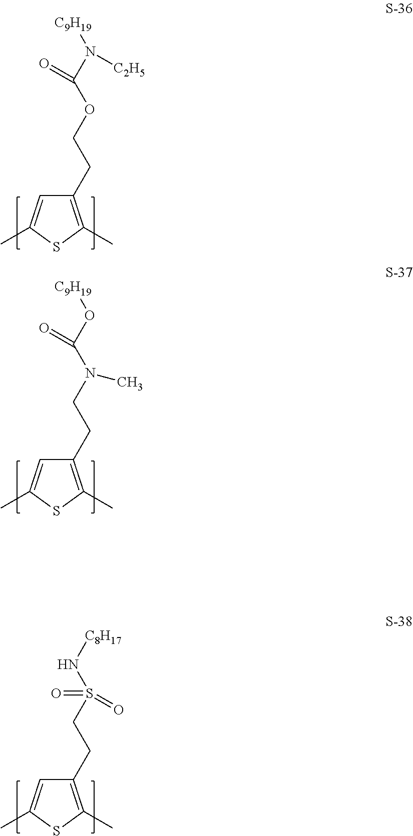

As shown above, the partial structure represented by the Chemical Formula 1 has a strong polar group in the side chain alkyl group, and thus a strong intermolecular interaction can be exhibited in the conjugated polymer compound containing the partial structure. Consequently, an element that is stable with respect to heat and light and excellent in durability can be obtained by forming an organic photoelectric conversion element using the conjugated polymer compound.

The conjugated polymer compound of the present embodiment, as long as the conjugated polymer compound contains at least one partial structure represented by the Chemical Formula 1, may be (1) a conjugated polymer compound consisting only of the partial structure represented by the Chemical Formula 1, (2) a copolymer containing one or more acceptor units, or (3) a copolymer (hereinafter, it is also referred to as the “D-A polymer”) containing one or more acceptor units and one or more donor units. Among them, (3) the D-A polymer is preferable in order to efficiently absorb radiant energy over a wide range of the solar spectrum. This is because it is possible to expand an absorption region to a longer wavelength region by alternately arranging the acceptor unit group and the donor unit group. Consequently, such a conjugated polymer compound can also absorb light in a long wavelength region (for example, 700 to 1000 nm) in addition to an absorption region (for example, 400 to 700 nm) of a conventional p-type organic semiconductor.

In more detail, (2) the copolymer containing one or more acceptor units is preferably a conjugated polymer compound having the partial structure represented by the following Chemical Formula 2.

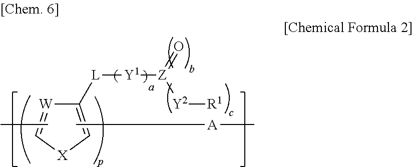

In the Chemical Formula 2, A independently represents an acceptor unit. An acceptor unit is generally a partial structure (unit) of which the LUMO level or HOMO level is deeper than a hydrocarbon aromatic ring having the same π electron number (such as benzene, naphthalene, and anthracene) with the acceptor unit. Preferred specific examples of the acceptor unit are shown below.

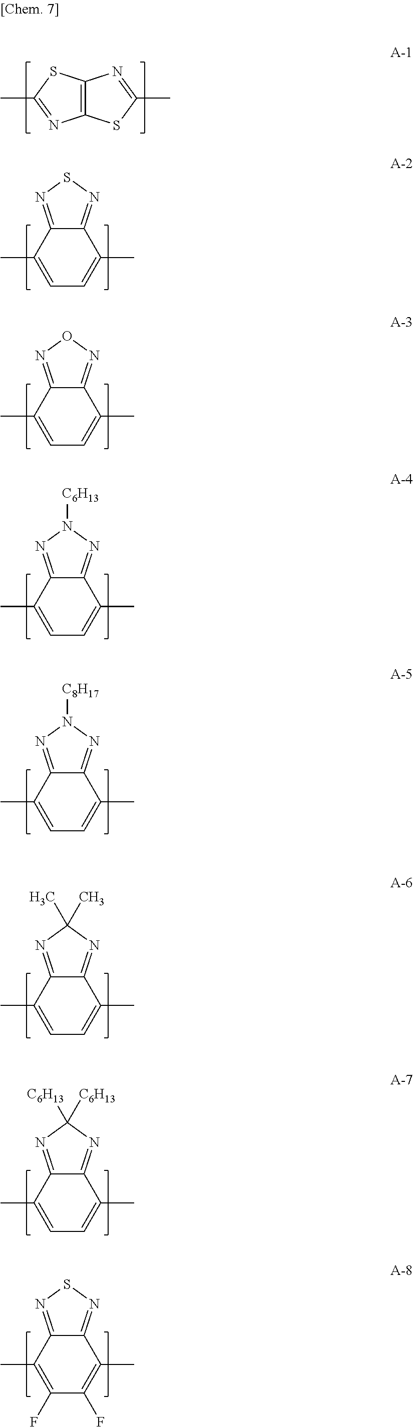

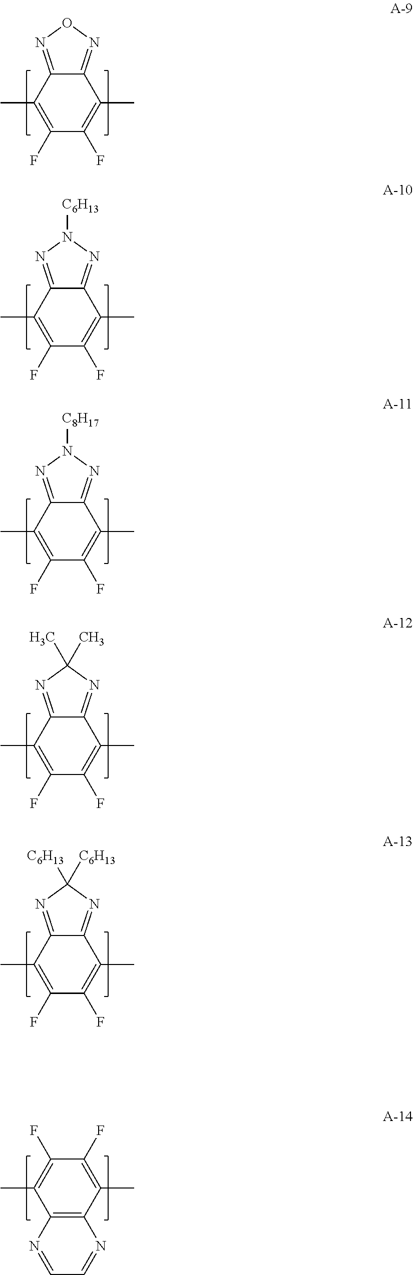

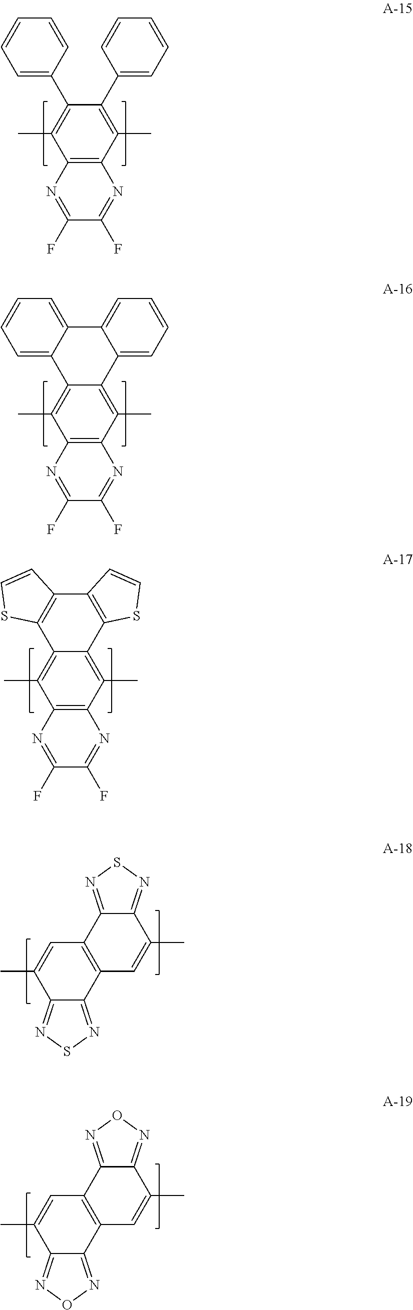

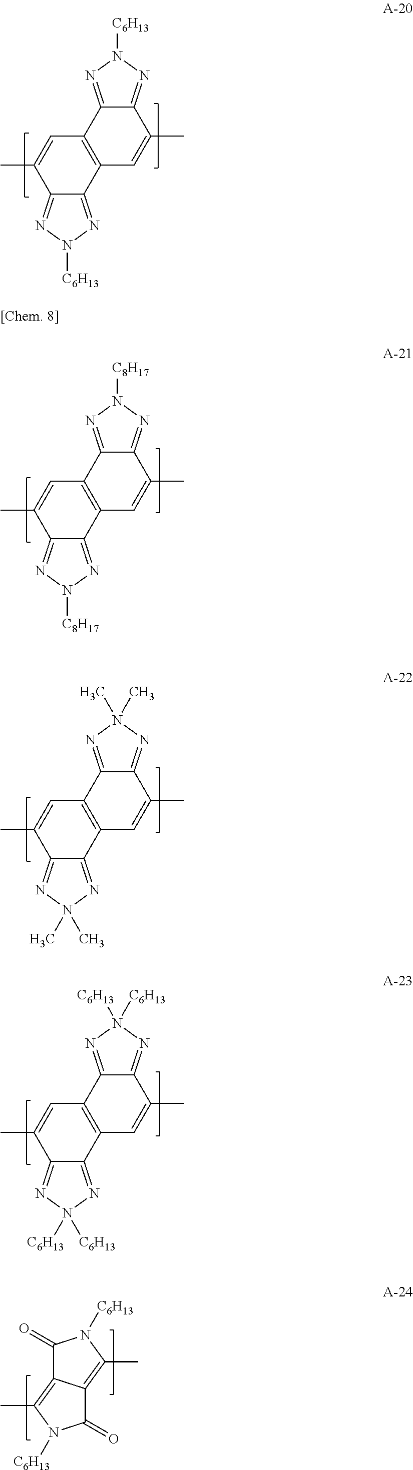

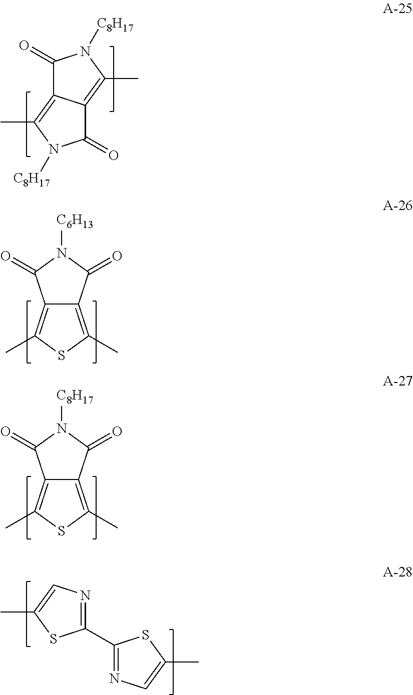

In addition, in the Chemical Formula 2, X, W, L, Y¹, Y², Z, R¹, a, b, and c are as defined in the Chemical Formula 1. p independently represents an integer from 1 to 5. Among them, p is preferably 1 from the viewpoints of mobility and solubility. Meanwhile, in the Chemical Formula 2, a binding position of adjacent units is not particularly limited.

Preferred specific examples of the acceptor unit are shown below in addition to those shown above or instead of those shown above.

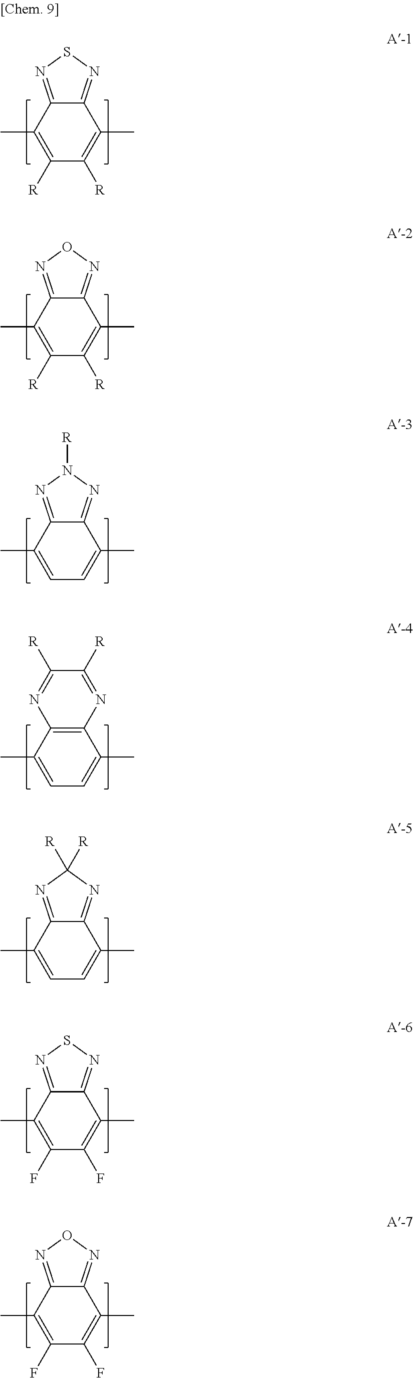

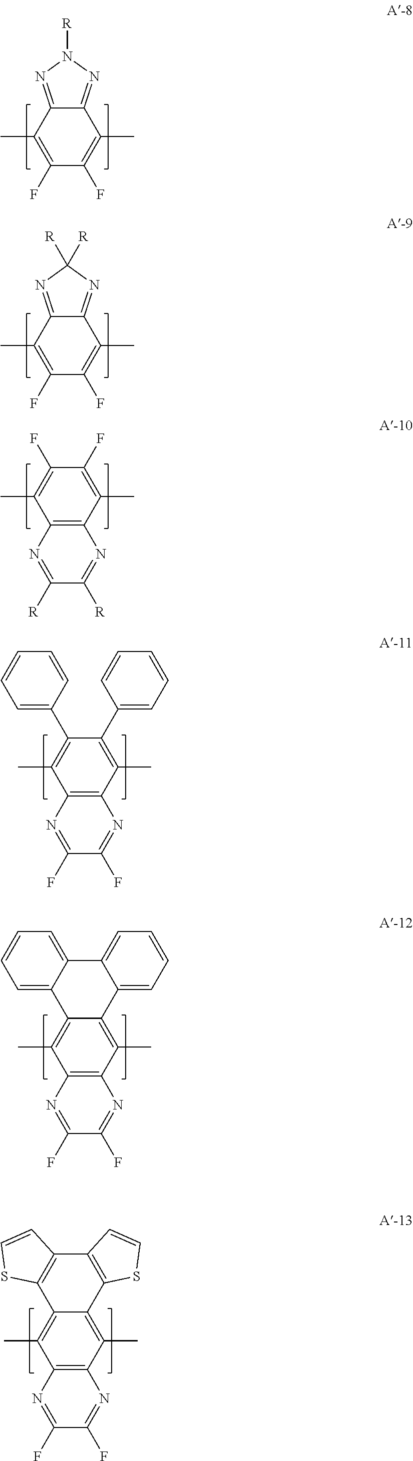

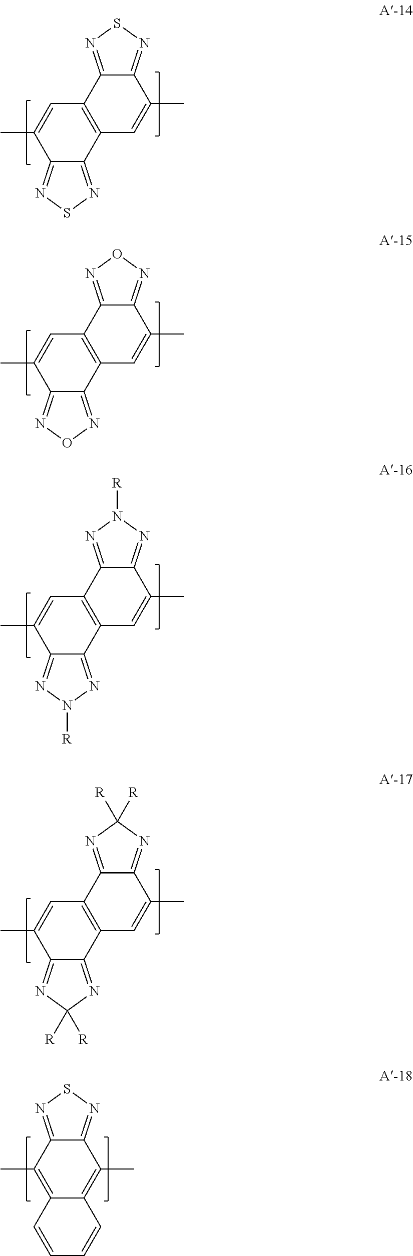

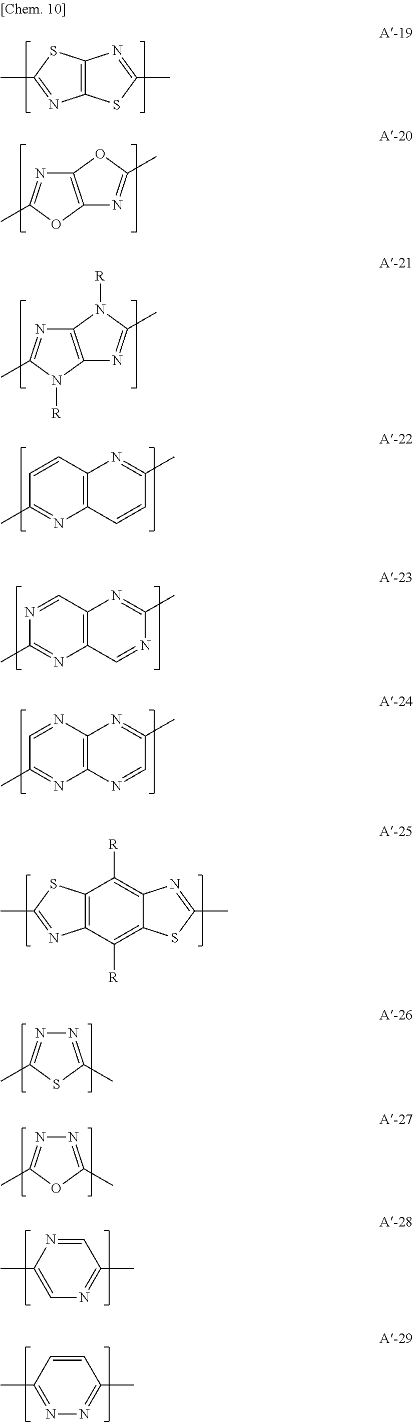

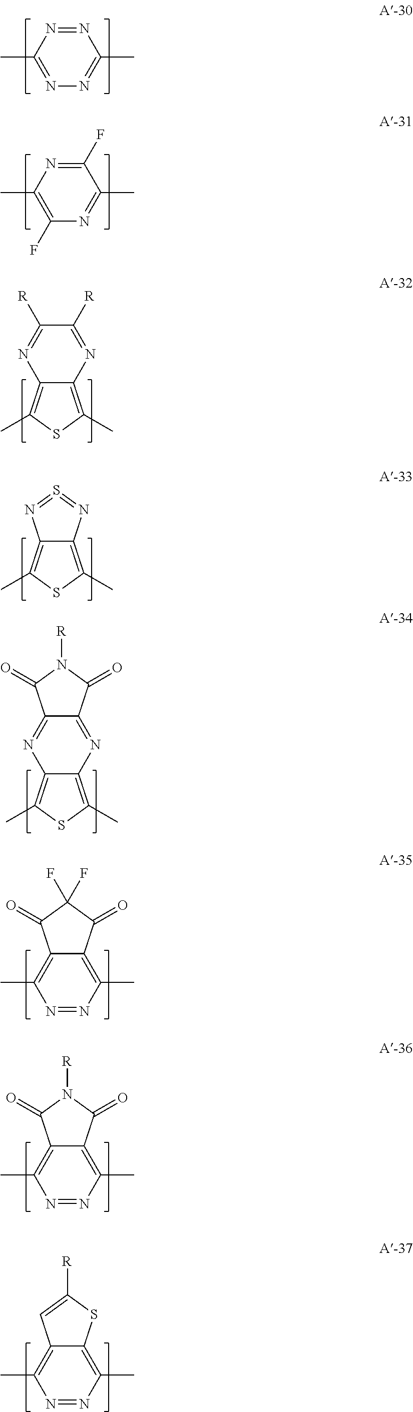

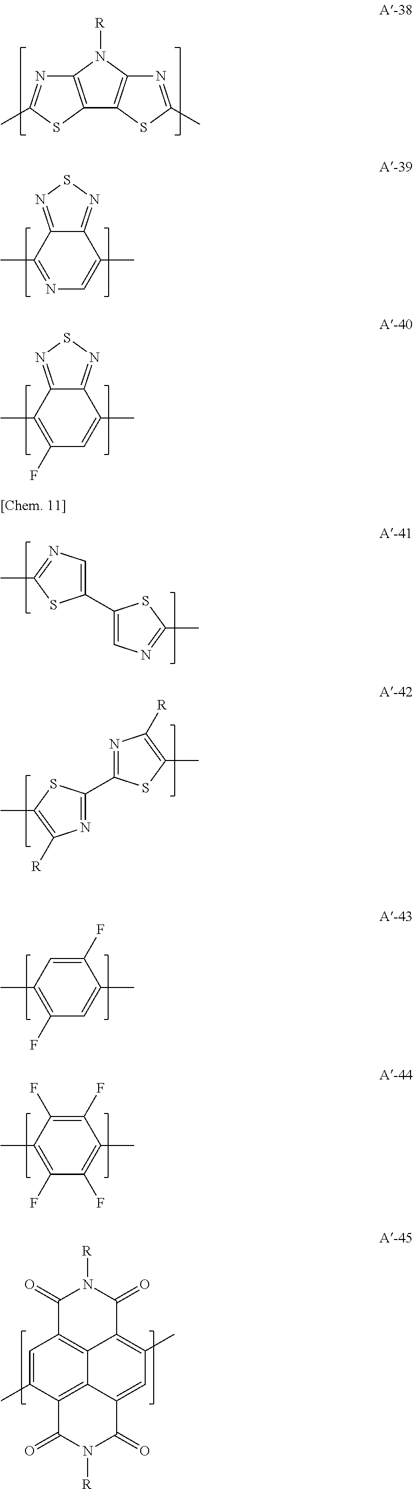

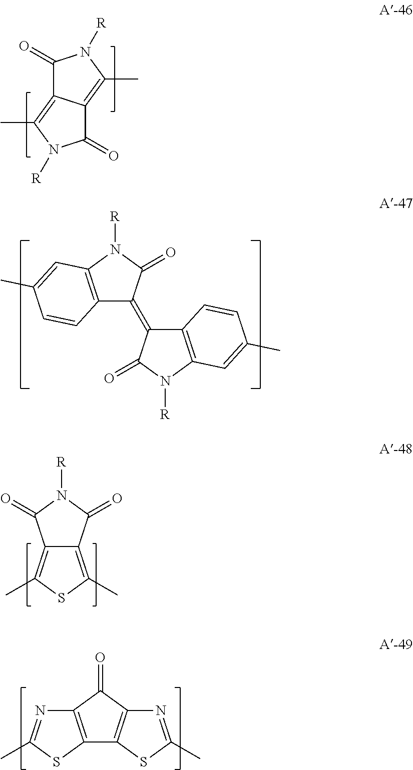

In the acceptor units A′-1 to A′-49, R independently represents a hydrogen atom (H), or an alkyl group having 1 to 24 carbon atoms, a fluorinated alkyl group having 1 to 24 carbon atoms, a cycloalkyl group having 3 to 24 carbon atoms, a fluorinated cycloalkyl group having 3 to 20 carbon atoms, an alkoxy group having 1 to 24 carbon atoms, a fluorinated alkoxy group having 1 to 24 carbon atoms, an alkylthio group having 1 to 24 carbon atoms, a fluorinated alkylthio group having 1 to 24 carbon atoms, an aryl group having 6 to 30 carbon atoms, a fluorinated aryl group having 6 to 30 carbon atoms, a heteroaryl group having 1 to 20 carbon atoms, or a fluorinated aryl group having 1 to 20 carbon atoms, which are substituted or unsubstituted. When plural R are contained in the unit, the plural R may be bound each other to form a ring that may have a substitute, or may form a condensed ring.

Among them, R is preferably a hydrogen atom, an alkyl group, a fluorinated alkyl group having 1 to 24 carbon atoms, an alkoxy group, or an alkylthio group, each of which has 1 to 24 carbon atoms, in terms of that both solubility and crystallinity are easily attained. The alkyl group having 1 to 24 carbon atoms, a cycloalkyl group having 3 to 20 carbon atoms, an aryl group having 6 to 30 carbon atoms, and a heteroaryl group having 1 to 20 carbon atoms are as defined in the Chemical Formula 1.

The fluorinated alkyl group having 1 to 24 carbon atoms is not particularly limited, and for example, a group obtained by substituting at least one of the hydrogen atoms contained in the alkyl group exemplified above with a fluorine atom is included. Specific examples thereof include a monofluoroalkyl group such as a fluoromethyl group, a 1-fluoroethyl group, a 1-fluoropropyl group, a 1-fluorobutyl group, a 1-fluorooctyl group, a 1-fluorodecyl group, a 1-fluorohexadecyl group, a 1-fluoro-2-ethylhexyl group, or a 1-fluoro-2-hexyldecyl group; a difluoroalkyl group such as a difluoromethyl group, a 1,1-difluoroethyl group, a 1,1-difluoropropyl group, a 1,1-difluorobutyl group, a 1,1-difluorooctyl group, a 1,1-difluorodecyl group, a 1,1-difluorohexadecyl group, a 1,1-difluoro-2-ethylhexyl group, or a 1,1-difluoro-2-hexyldecyl group; and a trifluoroalkyl group such as a trifluoromethyl group. In addition, a fluorinated alkyl group having from 1 to 3 carbon atoms is preferable from the viewpoint of maintaining coating property of upper layer. It is because a group having such a carbon number is sufficiently short (a group having 6 or more carbon atoms is generally used as a substituent for imparting solubility) compared to other soluble groups and thus the effect on the coating property of the upper layer is little. Among them, a trifluoromethyl group having one carbon atom is more preferable.

The fluorinated cycloalkyl group having 3 to 20 carbon atoms is not particularly limited, and for example, a group obtained by substituting at least one of the hydrogen atoms contained in the cycloalkyl group exemplified above with a fluorine atom, is included. Among these, a group obtained by substituting all of the hydrogen atoms contained in the cycloalkyl group exemplified above with fluorine atoms is preferable from the viewpoint of achieving a higher Voc (deeper HOMO level), but it is preferable to properly adjust the number and position of the fluorine atoms in consideration of balance with the coating property. In addition, a fluorinated cycloalkyl group having from 4 to 8 carbon atoms is preferable from the viewpoint of improving solubility.

The alkoxy group having 1 to 24 carbon atoms is not particularly limited, and examples thereof include a methoxy group, an ethoxy group, an isopropoxy group, a tert-butoxy group, an n-octyl group, an n-decyloxy group, an n-dodecyloxy group, an n-hexadecyloxy group, a 2-ethylhexyloxy group, a 2-hexyldecyloxy group, and a 2-decyltetradecyloxy group. Among them, from the viewpoint of attaining both solubility and crystallinity, an alkoxy group having from 1 to 16 carbon atoms is preferable, and an alkoxy group having from 6 to 12 carbon atoms is more preferable.

The fluorinated alkoxy group having 1 to 24 carbon atoms (fluorinated alkyloxy group) is not particularly limited, and for example, a group having an oxygen atom connected to a root of the fluorinated alkyl group exemplified above, is included. Among these, a group obtained by substituting all of the hydrogen atoms contained in the alkyl chain exemplified above with fluorine atoms is preferable from the viewpoint of achieving a higher Voc (deeper HOMO level), but it is preferable to properly adjust the number and position of the fluorine atoms in consideration of balance with coating property. Both solubility and deep HOMO level can be easily attained when a fluorinated alkoxy group has a fluorinated alkyl chain having fluorine atoms only near the carbon atom of the substitution site. In addition, from the viewpoint of maintaining coating property of upper layer, a group obtained by connecting an oxygen atom to a root of fluorinated alkyl group having from 1 to 3 carbon atoms is preferable, and a trifluoromethoxy group having one carbon atom is particularly preferable.

The alkylthio group having 1 to 24 carbon atoms is not particularly limited, and examples thereof include a methylthio group, an ethylthio group, a propylthio group, an n-butylthio group, a sec-butylthio group, a tert-butylthio group, an iso-propylthio group, and an n-dodecylthio group. Among these, from the viewpoint of attaining both solubility and crystallinity, an alkylthio group having from 1 to 16 carbon atoms is preferable, an alkylthio group having from 1 to 12 carbon atoms is more preferable, and an alkylthio group having from 6 to 12 carbon atoms is still more preferable.

The fluorinated alkylthio group having 1 to 24 carbon atoms is not particularly limited, and for example, a group obtained by connecting a sulfur atom to a root of fluorinated alkyl group exemplified above is included. Among these, a group obtained by substituting all of the hydrogen atoms contained in the alkyl chain exemplified above with fluorine atoms is preferable from the viewpoint of achieving a higher Voc (deeper HOMO level), but it is preferable to properly adjust the number and position of the fluorine atoms in consideration of balance with coating property. In addition, from the viewpoint of maintaining coating property of upper layer, a group obtained by connecting a sulfur atom to root of fluorinated alkyl group having from 1 to 12 carbon atoms is preferable, and a trifluoromethylthio group having one carbon atom is particularly preferable.

The fluorinated aryl group having 6 to 30 carbon atoms is not particularly limited, and for example, a group obtained by substituting at least one of the hydrogen atoms contained in the aryl group exemplified above with a fluorine atom is included. Among these, a group obtained by substituting all of the hydrogen atoms contained in the aryl group exemplified above with fluorine atoms is preferable from the viewpoint of achieving a higher Voc (deeper HOMO level), but it is preferable to properly adjust the number and position of the fluorine atoms in consideration of balance with coating property.

The fluorinated heteroaryl group having 1 to 20 carbon atoms is not particularly limited, and for example, a group obtained by substituting at least one of the hydrogen atoms contained in the heteroaryl group exemplified above with a fluorine atom is included. Among these, a group obtained by substituting all of the hydrogen atoms contained in the heteroaryl group exemplified above with fluorine atoms is preferable from the viewpoint of achieving a higher Voc (deeper HOMO level), but it is preferable to properly adjust the number and position of the fluorine atoms in consideration of balance with coating property.

The substituent optionally present in the R depending is not particularly limited, and examples thereof may include an alkyl group, a cycloalkyl group, an alkenyl group, an alkynyl group, an aryl group, a heteroaryl group, an acyl group, an alkoxycarbonyl group, an amino group, an alkoxy group, a cycloalkyloxy group, an aryloxy group, an aryloxycarbonyl group, an acyloxy group, an acylamino group, an alkoxycarbonylamino group, an aryloxycarbonylamino group, a sulfonylamino group, a sulfamoyl group, a carbamoyl group, an alkylthio group, an arylthio group, a silyl group, a sulfonyl group, a sulfinyl group, a ureido group, a phosphoric acid amide group, a halogen atom, a hydroxyl group, a mercapto group, a cyano group, a sulfo group, a carboxyl group, a nitro group, a hydroxamic acid group, a sulfino group, a hydrazino group, and an imino group which are substituted or unsubstituted. Meanwhile, in the above, the substituent is not substituted with the same substituent. In other words, the substituted alkyl group is not substituted with an alkyl group.

The acceptor unit contained in the conjugated polymer compound of the present embodiment may include other partial structures (structure having electron-withdrawing property) as well as the partial structures exemplified above. Provided that, in order to achieve higher photoelectric conversion efficiency, it is preferable as the proportion of the partial structures described above among the acceptor units contained in the conjugated polymer compound is great. Specifically, the number of the partial structure described above is preferably 50% or more, more preferably 70% or more, still more preferably 90% or more, particularly preferably 95% or more, and most preferably 100% with respect to the total number of acceptor units contained in the conjugated polymer compound.

In a preferred embodiment, the acceptor unit represented by A is a divalent group derived from a heteroaromatic condensed polycycle (heteroaromatic condensed polycycle) having two or more rings condensed. It is because the improvement in mobility due to an increase in the π plane area of the p-type organic semiconductor material is expected by adopting such a compound. Further preferably, a structure such as of A′-2 to A′-23, that is, a structure represented by the Chemical Formula A or Chemical Formula B is preferable since improvement in short circuit current due to shift of wavelength to a longer wavelength is expected.

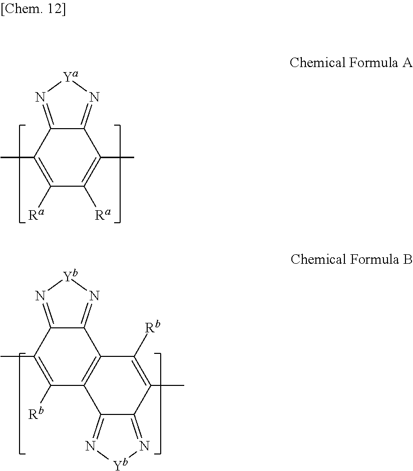

In the Chemical Formula A or B, Y^{a} and Y^{b} represent —O—, —NR^{c}—, —S—, —C(R^{d})═C(R^{e})—, —N═C(R^{f})—, or —CR^{g}R^{h}—. In the Chemical Formula B, each Y^{b}'s may be the same as or different from each other, but are preferably the same as each other in terms of increasing crystallinity and easily obtaining a material having high mobility.

Among them, Y^{a} and Y^{b} are more preferably —S—. With such compound, both deep HOMO level and high mobility can be attained.

In the formulas, R^{a} to R^{h} independently represent a hydrogen atom (H), a halogen atom (F, Cl, Br, or I), or an alkyl group having 1 to 24 carbon atoms, a fluorinated alkyl group having 1 to 24 carbon atoms, a cycloalkyl group having 3 to 20 carbon atoms, a fluorinated cycloalkyl group having 3 to 20 carbon atoms, an alkoxy group having from 1 to 24, a fluorinated alkoxy group having 1 to 24 carbon atoms, an alkylthio group having 1 to 24 carbon atoms, a fluorinated alkylthio group having 1 to 24 carbon atoms, an aryl group having 6 to 30 carbon atoms, a fluorinated aryl group having 6 to 30 carbon atoms, a heteroaryl group having 1 to 20 carbon atoms, or a fluorinated heteroaryl group having 1 to 20 carbon atoms, each of which is substituted or unsubstituted. In the Chemical Formula A or B, each R^{a}'s and R^{b}'s are the same as or different from each other, but are preferably the same as each other in terms of increasing crystallinity and easily obtaining a material having high mobility. Each R^{a} in the Chemical Formula A, or each of R^{d} and R^{e} or R^{g} and R^{h} in the Chemical Formula B may bond to each other to form a ring that may have a substituent or may form a condensed ring.

R^{a} or R^{b} is preferably a hydrogen atom (H), a halogen atom (F, Cl, Br, or I), or an alkyl group, a fluorinated alkyl group, an alkoxy group, or an alkylthio group, each of which has 1 to 24 carbon atoms, in terms of planarity (improved mobility) of the conjugated polymer main chain. More preferably, in terms of obtaining a conjugated polymer with a deeper HOMO (improved open circuit voltage), R^{a} or R^{b} is preferably a hydrogen atom (H) or a halogen atom (F, Cl, Br, or I).

R^{c} to R^{h} are preferably a hydrogen atom (H) or a halogen atom (F, Cl, Br, or I) in terms of solubility of the conjugated polymer, are preferably a hydrogen atom, or an alkyl group, a fluorinated alkyl group, an alkoxy group, or an alkylthio group, each of which has 1 to 24 carbon atoms in terms of easily attaining both solubility and the crystallinity, and are more preferably a hydrogen atom (H) or an alkyl group having 1 to 24 carbon atoms in terms of easy synthesis.

Specific groups of R^{a} to R^{h}, and substituents optionally present in R^{a} to R^{h} are as defined for R in the acceptor units A′-1 to A′-49 as described above.

Moreover, (2) the copolymer containing one or more acceptor units more preferably has a partial structure represented by the following Chemical Formula 3.

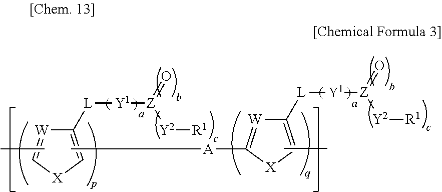

In the Chemical Formula 3, A independently represents an acceptor unit. The acceptor unit is as defined in the Chemical Formula 2. X, W, L, Y¹, Y², Z, R¹, a, b, and c as defined in the Chemical Formula 1.

p and q independently represent an integer from 1 to 5. Among these, p and q are preferably 1 (that is, both terminals of the acceptor unit has one partial structure represented by the Chemical Formula 1) from the viewpoints of mobility and solubility.

Meanwhile, in the Chemical Formula 3, the bonding positions of adjacent units are not particularly limited. In addition, in the Chemical Formula 3, when plural (when p or q is 2 or more) units represented by the Chemical Formula 1 are present on the right side or left side of A in the partial structure, the units in each of the partial structures may be the same as or different from each other. Moreover, the partial structures on the right and the left with respect to the acceptor units may be the same as or different from each other.

In addition, (3) the copolymer (D-A polymer) containing one or more acceptor units and one or more donor units is preferably a conjugated polymer compound having a partial structure represented by the following Chemical Formula 4 from the view point of orbital level and shift of absorption wavelength to a longer wavelength.

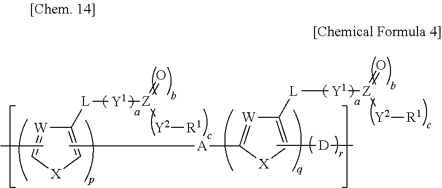

In the Chemical Formula 4, A independently represents an acceptor unit. The acceptor unit is as defined in the Chemical Formula 2. X, W, L, Y¹, Y², Z, R¹, a, b, and c are as defined in the Chemical Formula 1.

D independently represents a donor unit. A donor unit is generally a partial structure (unit) of which the LUMO level or HOMO level is shallower than a hydrocarbon aromatic ring having the same π electron number (benzene, naphthalene, and anthracene) with the donor unit. The structure of the donor unit is not particularly limited, and examples thereof include a 5-membered heterocycle such as a thiophene ring, a furan ring, a pyrrole ring, cyclopentadiene, or silacyclopentadiene, and a unit containing a condensed ring of these.

Specific examples thereof include thiophene, thienothiophene, bithiophene, fluorene, silafluorene, carbazole, dithienocyclopentadiene, dithienosilacyclopentadiene, dithienopyrrole, and benzodithiophene. Among these units, a unit having a thiophene structure capable of imparting high mobility is preferable, and photoelectric conversion efficiency can be further improved thereby. In addition, it is also possible to improve solubility or crystallinity by substituting the hydrogen atom bonded to the atom constituting the ring structure with a linear or branched alkyl group or alkoxy group having 1 to 20 carbon atoms.

p, q, and r independently represent an integer from 1 to 5. Among these, p and q are preferably 1 (that is, each of the both terminals of the acceptor unit has one partial structure represented by the Chemical Formula 1) from the viewpoints of mobility and solubility. In addition, r is preferably 1 from the viewpoints of easy synthesis and suppressing deterioration in crystallinity.

Meanwhile, in the Chemical Formula 4, the bonding positions of adjacent units are not particularly limited. In addition, in the Chemical Formula 4, when plural (when p or q is 2 or more) units represented by the Chemical Formula 1 are present on the right side or left side of A in the partial structure, the units in each of the partial structures may be the same as or different from each other. Moreover, the partial structures on the right and the left with respect to the acceptor units may be the same as or different from each other.

Preferred specific examples of the donor unit are shown below. Meanwhile, D-32 and D-33 shown below represent a partial structure including three donor units.

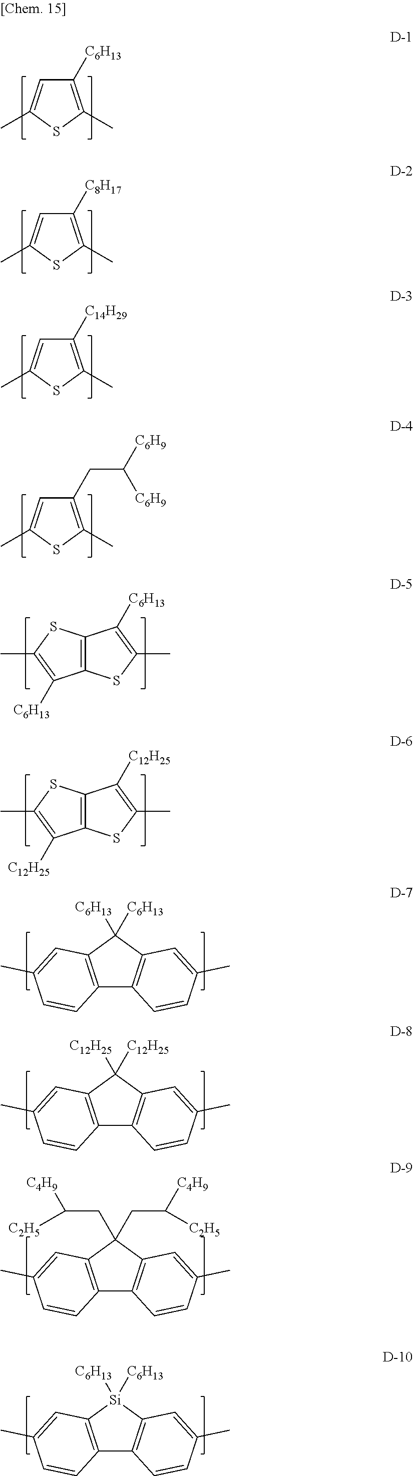

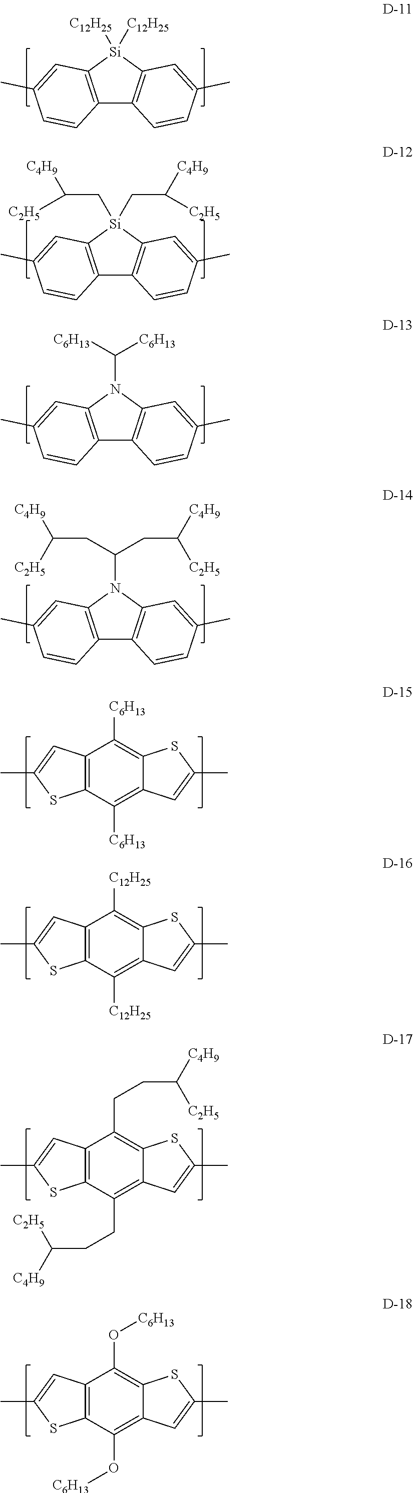

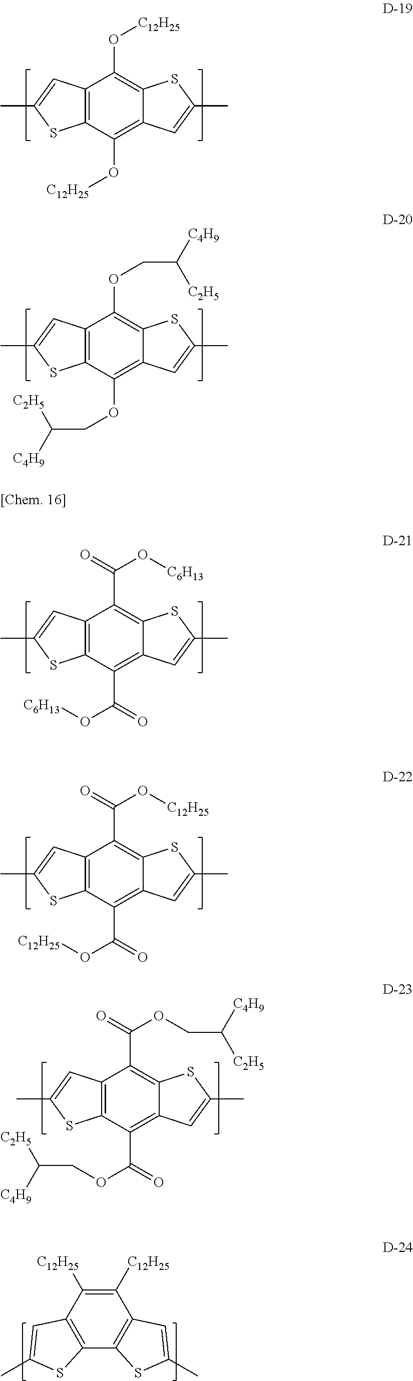

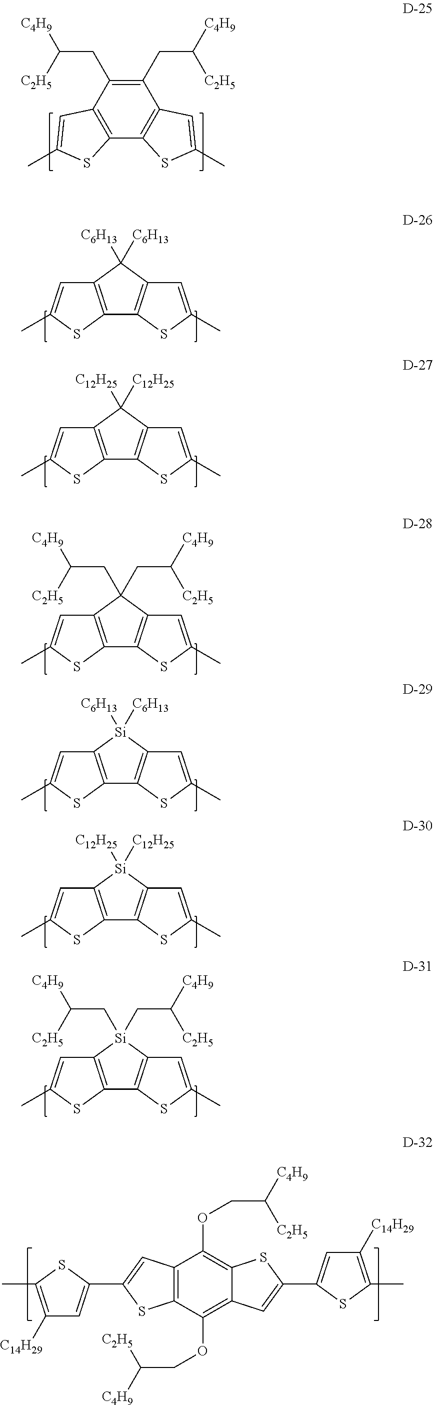

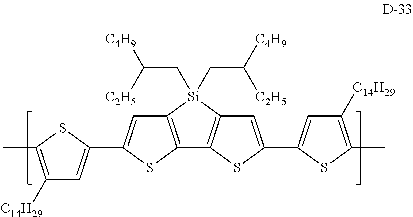

Meanwhile, in the examples shown above, a specific alkyl group is described as a side chain of each of the donor units, but the side chain is not limited thereto, and a linear or branched alkyl group having 1 to 24 carbon atoms (preferably 1 to 20 carbon atoms) or an alkyl group having a specific polar group shown in the Chemical Formula 1 may be substituted as the side chain.

In addition, in the Chemical Formula 4, X, W, L, Y¹, Y², Z, R¹, a, b, and c are as defined in the Chemical Formula 1.

p, q, and r independently represent an integer from 1 to 5. Among these, it is preferably p, q, r are 1 (that is, the unit group having one partial structure represented by the Chemical Formula 1 connected to the both terminals of the acceptor unit is has connected to the donor unit) from the viewpoint of that the absorption region can be shifted to a longer wavelength region. Meanwhile, in the Chemical Formula 4, the bonding positions of the adjacent units are not particularly limited.

Meanwhile, in the present embodiment, the combination of the partial structure represented by the Chemical Formula 1, the acceptor unit, and the donor unit is not particularly limited, and a conjugated polymer compound can be synthesized and used in an arbitrary combination. In Examples to be described below, a conjugated polymer compound in the combination represented below is synthesized and the performance thereof is evaluated, but the technical scope of the present invention is not limited to only these Examples. Preferred specific examples of the D-A polymer are shown below.

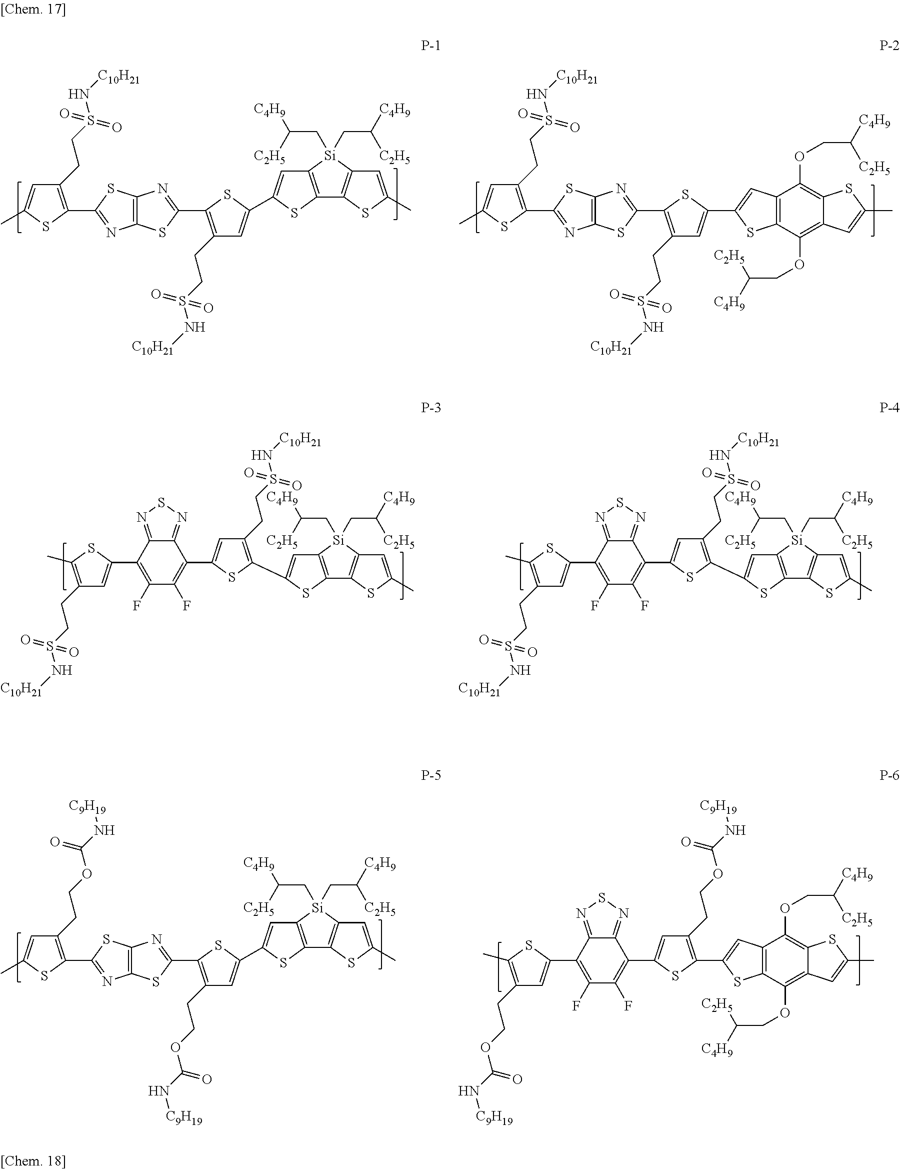

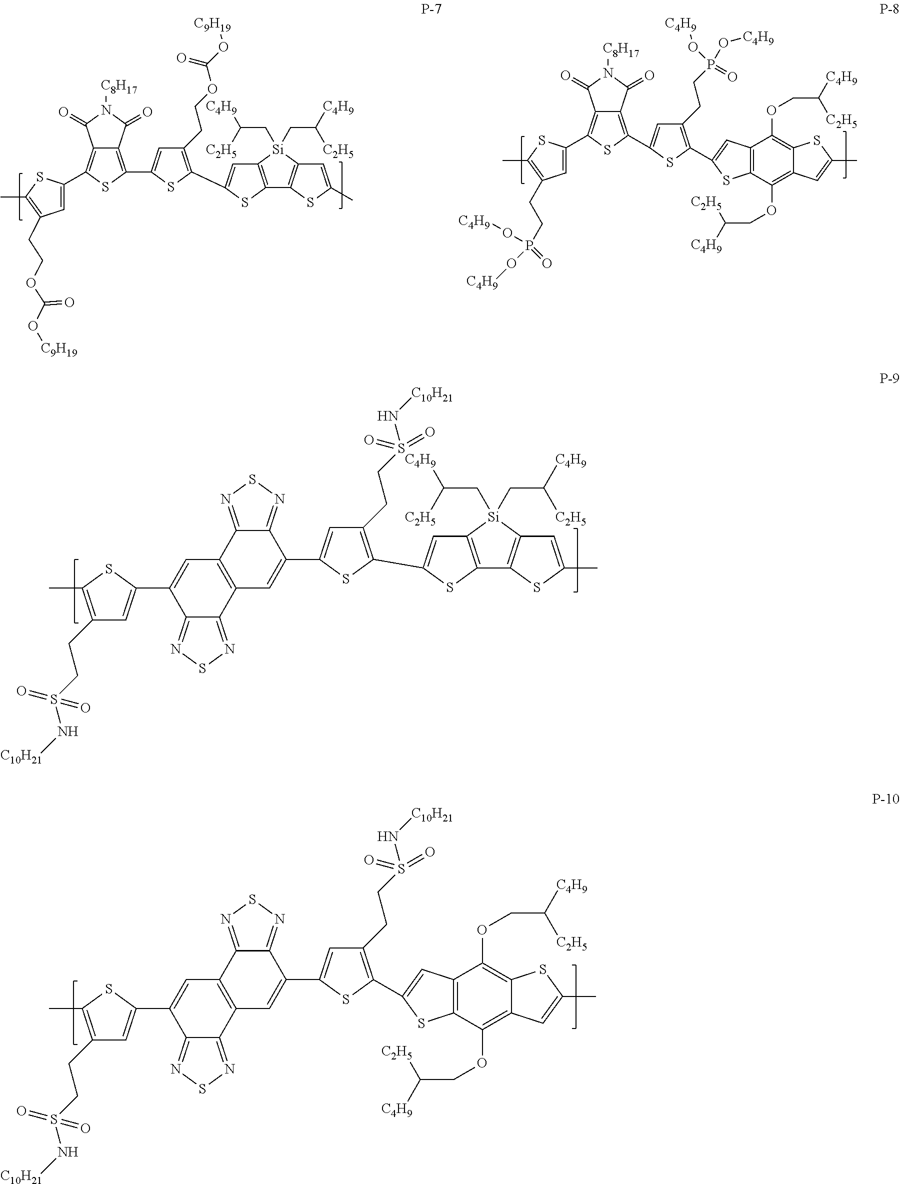

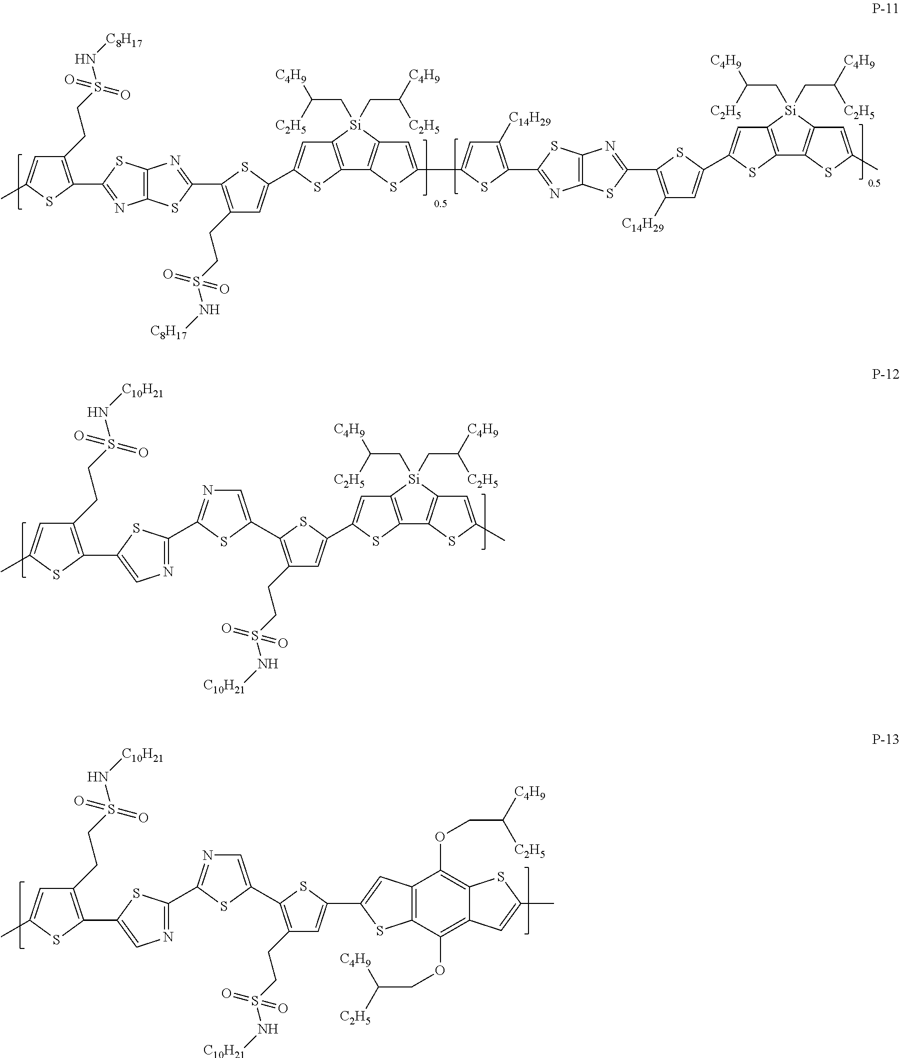

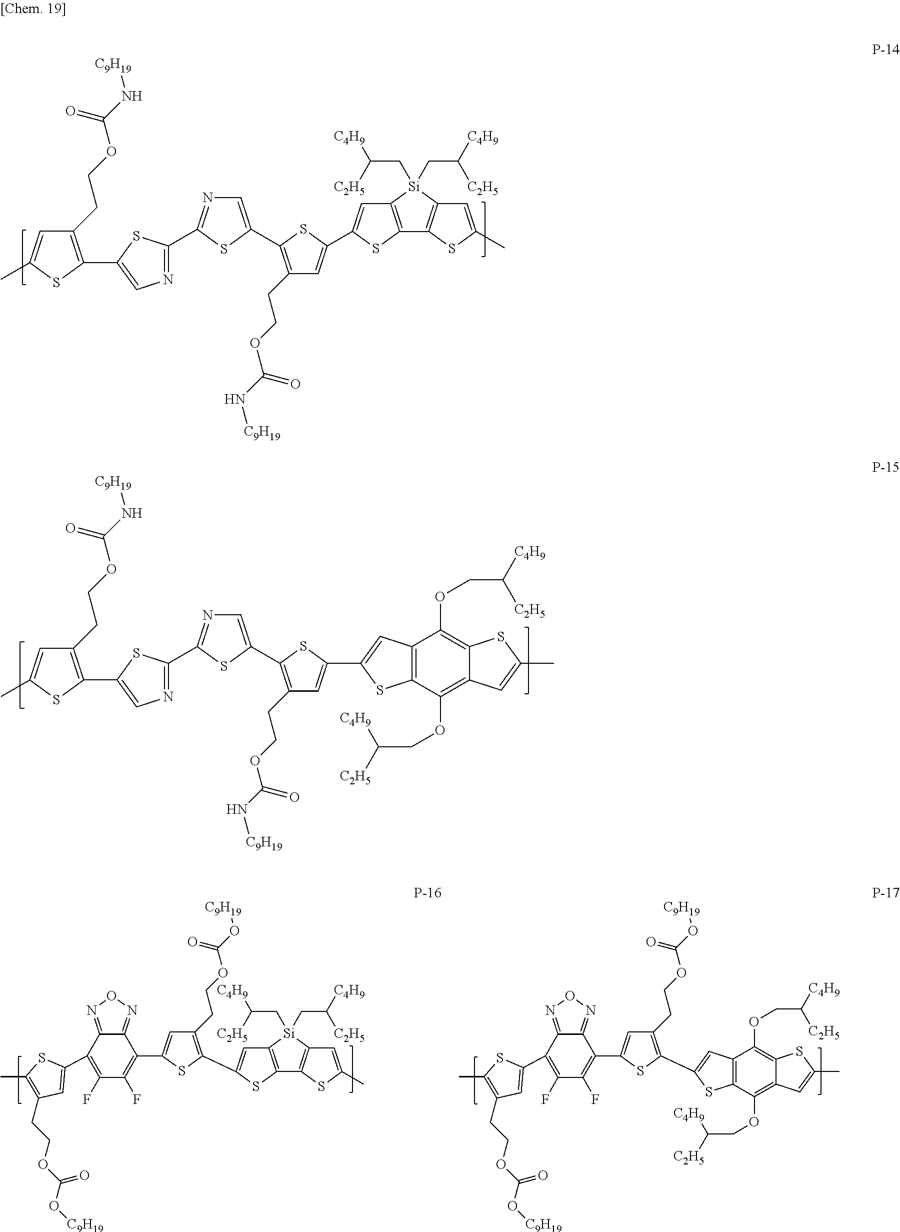

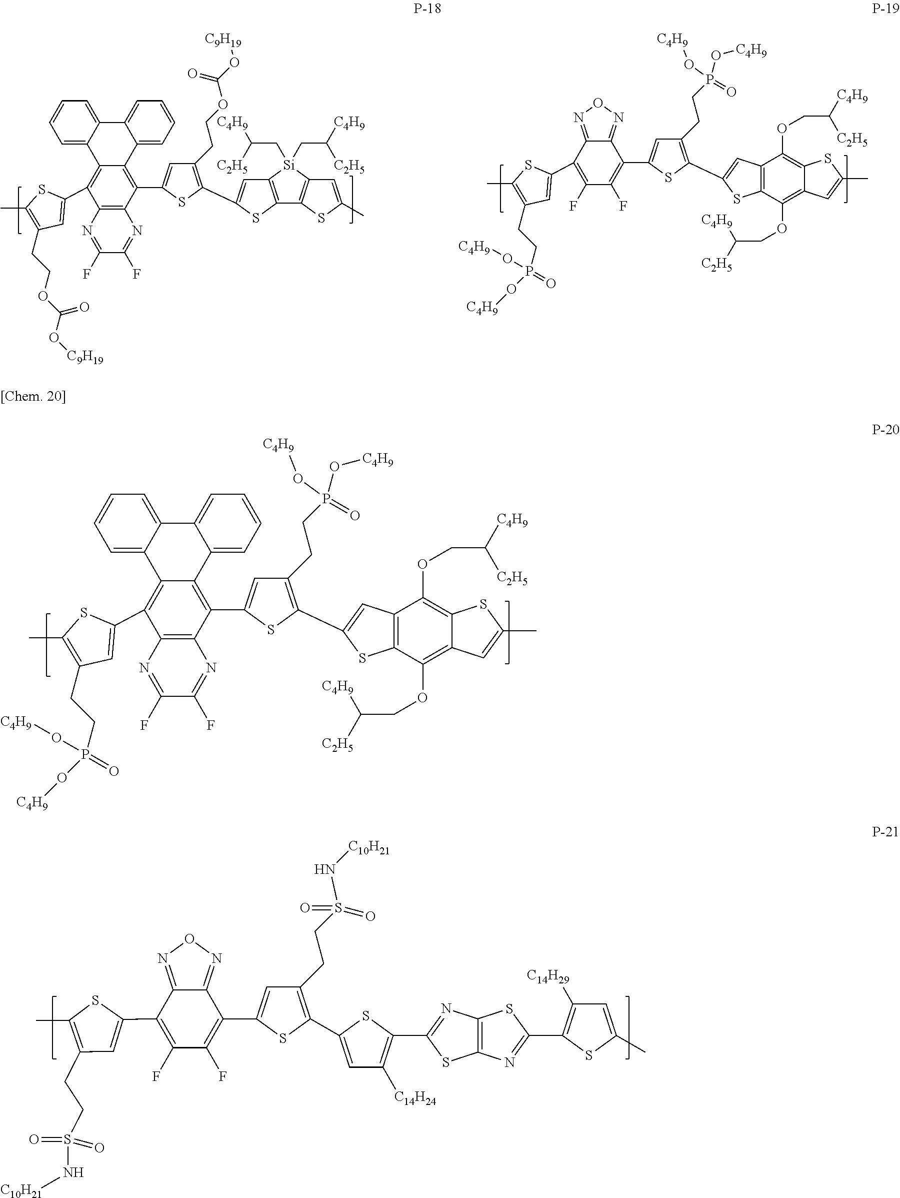

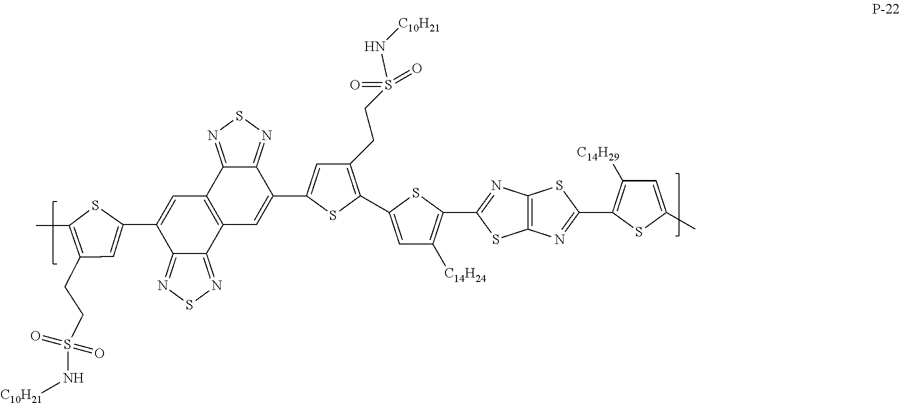

TABLE 1

| Conjugated | Partial structure represented | | | |
|---|---|---|---|---|
| polymer | by Chemical Formula 1 | | | |
| compound | Aromatic | | Acceptor | Another |
| (D-A polymer) | ring | Polar group | unit | donor unit |
| P-1 | Thiophene | Sulfonamide group | A-1 | D-31 |
| P-2 | Thiophene | Sulfonamide group | A-1 | D-20 |
| P-3 | Thiophene | Sulfonamide group | A-8 | D-31 |
| P-4 | Thiazole | Sulfonamide group | A-8 | D-31 |
| P-5 | Thiophene | Carbamate group | A-1 | D-31 |
| P-6 | Thiophene | Carbamate group | A-6 | D-20 |
| P-7 | Thiophene | Carbonate group | A-27 | D-31 |
| P-8 | Thiophene | Phosphoric acid | A-27 | D-20 |
| | | ester group | | |
| P-9 | Thiophene | Sulfonamide group | A-18 | D-31 |
| P-10 | Thiophene | Sulfonamide group | A-18 | D-20 |
| P-11 | Thiophene | Sulfonamide group | A-1 | D-31, |
| | | | | D-33 |
| P-12 | Thiophene | Sulfonamide group | A-28 | D-31 |
| P-13 | Thiophene | Sulfonamide group | A-28 | D-20 |
| P-14 | Thiophene | Carbamate group | A-28 | D-31 |
| P-15 | Thiophene | Carbamate group | A-28 | D-20 |
| P-16 | Thiophene | Carbonate group | A-9 | D-31 |
| P-17 | Thiophene | Carbonate group | A-9 | D-20 |
| P-18 | Thiophene | Carbonate group | A-16 | D-31 |
| P-19 | Thiophene | Phosphoric acid | A-9 | D-20 |
| | | ester group | | |
| P-20 | Thiophene | Phosphoric acid | A-16 | D-20 |
| | | ester group | | |
| P-21 | Thiophene | Sulfonamide group | A-1, A-8 | D-3 |
| P-22 | Thiophene | Sulfonamide group | A-1, A-8 | D-3 |

The molecular weight of the conjugated polymer compound of the present embodiment is not particularly limited, but it is preferable to have appropriate molecular weight in order to provide a conjugated polymer compound with a favorable morphology. Specifically, the number average molecular weight of the conjugated polymer compound is more preferably from 13,000 to 50,000, still more preferably from 15,000 to 35,000, and particularly preferably from 15,000 to 30,000. Particularly, a low molecular compound (for example, a fullerene derivative) has been widely used as an n-type organic semiconductor when a bulk heterojunction type photoelectric conversion layer is constituted using the conjugated polymer compound of the present embodiment as a p-type organic semiconductor. A microphase-separated structure is favorably formed when the molecular weight of the conjugated polymer compound used as the p-type organic semiconductor is within the range described above, and thus a carrier path carrying holes and electrons generated in the p-n junction interface can easily formed. The number average molecular weight in the present specification can be measured by gel permeation chromatography (GPC; standard reference material: polystyrene).

An element exhibiting excellent durability and sufficient photoelectric conversion efficiency can be obtained using the conjugated polymer compound of the present embodiment at least partially in the organic photoelectric conversion element. In particular, the conjugated polymer compound is preferably used as a p-type organic semiconductor used in the photoelectric conversion layer. Specifically, the organic photoelectric conversion element according to a preferred embodiment of the present invention comprises a first electrode, a second electrode, and a photoelectric conversion layer containing an n-type organic semiconductor and a p-type organic semiconductor, and provided between the first electrode and the second electrode, wherein the p-type organic semiconductor contains the conjugated polymer compound as described above. The organic photoelectric conversion element uses the conjugated polymer compound described above as the p-type organic semiconductor, and thus it is possible to form and maintain a favorable morphology with the n-type organic semiconductor in the photoelectric conversion layer, and to exhibit excellent durability and sufficient photoelectric conversion efficiency.

Hereinafter, the present embodiment will be described with reference to the accompanying drawings. However, the technical scope of the present invention is defined in the appended claims, but is not limited to only the following embodiments. Meanwhile, the same reference numerals are given to the same elements, and overlapping description will be omitted in the description of the drawings. In addition, dimensional ratios of the drawings are enlarged for the convenience of explanation, and may be different from the actual ratios.

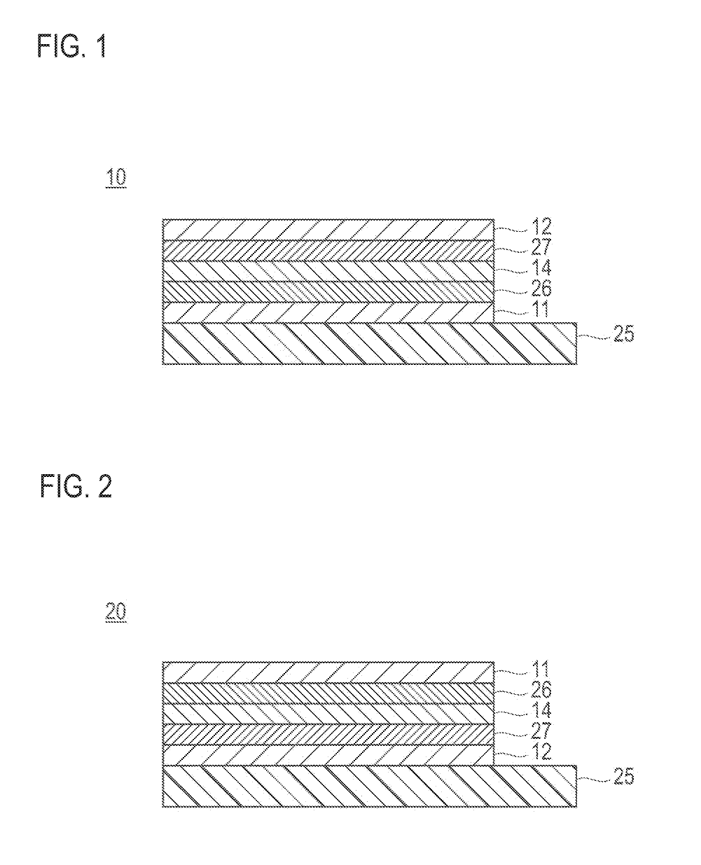

FIG. 1 is a schematic cross-sectional view schematically illustrating a forward layered type organic photoelectric conversion element according to an embodiment of the present invention. In specific, an organic photoelectric conversion element 10 of FIG. 1 has a configuration in which an anode (transparent electrode) 11, a hole transport layer 26, a photoelectric conversion layer 14, an electron transport layer 27, and a cathode (counter electrode) 12 are laminated on a substrate 25 in this order. Meanwhile, the substrate 25 is a member arbitrarily provided in order to facilitate mainly the formation of the anode (transparent electrode) 11 thereon by a coating method.

Light is irradiated from the substrate 25 side at the time of the operation of the organic photoelectric conversion element 10 illustrated in FIG. 1. In the present embodiment, the anode (transparent electrode) 11 is formed of a transparent electrode material (for example, ITO) in order to allow the light irradiated to reach the photoelectric conversion layer 14. The light irradiated from the substrate 25 side reaches the photoelectric conversion layer 14 by passing through the transparent anode (transparent electrode) 11 and the hole transport layer 26.

The hole transport layer 26 is formed of a material exhibiting high mobility of holes, and serves to efficiently transport holes generated at the p-n junction interface of the photoelectric conversion layer 14 to the anode (transparent electrode) 11. On the other hand, the electron transport layer 27 is formed of a material having high mobility of electrons, and serves to efficiently transport electrons generated at the p-n junction interface of the photoelectric conversion layer 14 to the cathode (counter electrode) 12.

FIG. 2 is a schematic cross-sectional view schematically illustrating a reverse layered type organic photoelectric conversion element according to another embodiment of the present invention. An organic photoelectric conversion element 20 of FIG. 2 is different from the organic photoelectric conversion element 10 of FIG. 1 in that a cathode 12 and anode 11 are disposed at the opposite position, and a hole transport layer 26 and an electron transport layer 27 are disposed at the opposite position. In other words, the reverse layered type organic photoelectric conversion element has a feature in that the first electrode is a cathode (transparent electrode) 12, the second electrode is an anode (counter electrode) 11, a hole transport layer 26 is provided between the second electrode and a photoelectric conversion layer 14. The organic photoelectric conversion element 20 of FIG. 2 has a configuration in which the cathode (transparent electrode) 12, the electron transport layer 27, the photoelectric conversion layer 14, the hole transport layer 26, and the anode (counter electrode) 11 are laminated on a substrate 25 in this order. By having such a configuration, electrons generated at the p-n junction interface of the photoelectric conversion layer 14 is transported to the cathode (transparent electrode) 12 through the electron transport layer 27, and holes are transported to the anode (counter electrode) 11 through the hole transport layer 26.

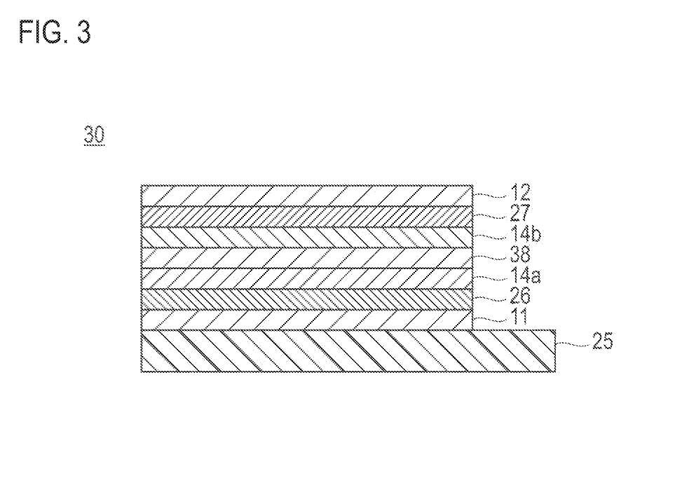

FIG. 3 is a schematic cross-sectional view schematically illustrating an organic photoelectric conversion element comprising a tandem type (multijunction type) photoelectric conversion layer according to still another embodiment of the present invention. An organic photoelectric conversion element 30 of FIG. 3 is different from the organic photoelectric conversion element 10 of FIG. 1 in that a laminated body of the first photoelectric conversion layer 14a, the second photoelectric conversion layer 14b, and a charge recombination layer 38 interposed between these two layers is disposed instead of the photoelectric conversion layer 14. In the organic photoelectric conversion element 30 of FIG. 3, it is possible to efficiently convert light in a wider wavelength region into electricity by using photoelectric conversion materials (a p-type organic semiconductor and an n-type organic semiconductor) having different absorption wavelengths for the first photoelectric conversion layer 14a and the second photoelectric conversion layer 14b, respectively.

Hereinafter, individual parts of the organic photoelectric conversion element according to the present invention will be described in detail.

[Electrode]

The organic photoelectric conversion element according to the present embodiment essentially comprises the first electrode and the second electrode. Each of the first electrode and the second electrode functions as an anode or a cathode. The terms “first” and “second” in the present specification are a term used to distinguish the function as an anode or a cathode. Hence, the first electrode functions as an anode and the second electrode functions as a cathode in some cases, and on the contrary, the first electrode functions as a cathode, the second electrode functions as an anode in other cases. As described above, carriers (holes and electrons) generated in the photoelectric conversion layer 14 move between the electrodes, and the holes reach the anode 12 and the electrons reach the cathode 16. Meanwhile, the electrode, to which holes mainly flow, is called the anode, and the electrode, to which electrons mainly flow, is called the cathode in the present invention. In addition, it is possible to achieve a tandem configuration using the charge recombination layer (intermediate electrode) in the case of adopting a tandem configuration. Moreover, an electrode that has light transmitting property is called a transparent electrode and an electrode that does not have light transmitting property is called a counter electrode in some cases from the functional aspect of whether or not the electrode has light transmitting property. In the case of forward layered structure, generally, the anode is a transparent electrode that has light transmitting property and the cathode is a counter electrode that does not have light transmitting property.

The material used for the electrode of the present embodiment is not particularly limited as long as a material drives as a photoelectric conversion element, and an electrode material usable in the related art can be appropriately adopted. Among them, the anode is preferably formed of a material having a relatively greater work function compared to the cathode. On the contrary, the cathode is preferably formed of a material having a relatively smaller work function compared to the anode.

The anode 11 of the forward layered type organic photoelectric conversion element 10 illustrated in FIG. 1 is preferably formed of an electrode material that has a relatively great work function and is transparent (capable of transmitting light of from 380 to 800 nm). On the other hand, the cathode 12 can be generally formed of an electrode material that has a relatively small work function (for example, 4 eV or less) and low light transmitting property.

In such a forward layered type organic photoelectric conversion element 10, examples of the electrode material used for the anode (transparent electrode) include a metal such as gold, silver, and platinum; a transparent conductive metal oxide such as indium tin oxide (ITO), SnO₂, and ZnO; a metal nanowire, and a carbon material such as a carbon nanotube. In addition, a conductive polymer can also be used as an electrode material of the anode. Examples of the conductive polymer usable for the anode include PEDOT: PSS, polypyrrole, polyaniline, polythiophene, polythienylenevinylene, polyazulene, polyisothianaphthene, polycarbazole, polyacetylene, polyphenylene, polyphenylene vinylene, polyacene, polyphenylacetylene, polydiacetylene, polynaphthalene, and any derivative thereof. One kind of these electrode materials may be used singly, or two or more kinds thereof may be used by mixing together. In addition, an electrode can also be constituted by laminating two or more kinds of the layers formed of respective materials. A thickness of the anode (transparent electrode) is not particularly limited, and is generally from 10 nm to 10 μm and preferably from 100 to 1000 nm.

On the other hand, in a forward layered type organic photoelectric conversion element, examples of the electrode material used for the cathode (counter electrode) may include a metal, an alloy, an electron conductive compound, and a mixture thereof. Specific examples thereof include a metal such as sodium, sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture, a rare earth metal, gold, silver, and platinum. Among these, a mixture of the first metal having a low work function and the second metal having a greater work function and stabler than the first metal, for example, a magnesium/silver mixture, a magnesium/aluminum mixture, a magnesium/indium mixture, an aluminum/aluminum oxide (Al₂O₃) mixture, and a lithium/aluminum mixture, or aluminum of a stable metal is preferably used from the viewpoint of electron extraction performance and durability with respect to oxidation or the like. In addition, a metal among these materials is also preferably used, and by virtue of this, the light, which is incident from the first electrode side and is not absorbed by the photoelectric conversion layer but passed therethrough, can be reflected from the second electrode and reused for the photoelectric conversion, and thus the photoelectric conversion efficiency can be improved. One kind of these electrode materials may be used singly, or two or more kinds thereof may be used by mixing together. In addition, an electrode can also be constituted by laminating two or more kinds of the layers formed of respective materials. A thickness of the cathode (counter electrode) is not particularly limited, and is generally from 10 nm to 5 μm and preferably from 50 to 200 nm.

In addition, in the reverse layered type organic photoelectric conversion element illustrated in FIG. 2, the cathode 12 is positioned on the substrate 25 side from which light is incident, and the anode 11 is positioned on the opposite side. Hence, the anode 11 in the form of reverse layered type illustrated in FIG. 2 is preferably formed of an electrode material having a relatively great work function and generally low light transmitting property. On the other hand, the cathode 12 is preferably formed of an electrode material having a relatively small work function and transparent.

In the reverse layered type organic photoelectric conversion element, examples of the electrode material used for the cathode (transparent electrode) include a metal, a metal compound, and an alloy such as gold, silver, copper, platinum, rhodium, ruthenium, aluminum, magnesium, or indium; and a carbon material such as carbon nanoparticles, a carbon nanowire, or a carbon nanostructure. Among these, a transparent conductive metal oxide such as indium tin oxide (ITO) is preferably used. One kind of these electrode materials may be used singly, or two or more kinds thereof may be used by mixing together. In addition, an electrode can also be constituted by laminating two or more kinds of the layers formed of respective materials. Among these, it is preferable to use a carbon nanowire since a transparent and highly conductive cathode can be formed by a coating method. In addition, when a metal-based material is used, a cathode (transparent electrode) can be formed by preparing an auxiliary electrode having a thickness of about 1 to 20 nm on the side facing the anode (counter electrode) using, for example, aluminum, an aluminum alloy, silver, or a silver compound, and then providing with a film of the conductive polymer exemplified as the anode (transparent electrode) material of the forward layered type organic photoelectric conversion element described above. Meanwhile, the thickness of the cathode (transparent electrode) is not particularly limited, and generally from 10 nm to 10 μm and preferably from 100 nm to 1 μm.

On the other hand, in the reverse layered type organic photoelectric conversion element, the electrode material used for the anode (counter electrode) is preferably an electrode material having a relatively greater work function than the cathode (transparent electrode). As an example, the anode (counter electrode) may be formed using a metal material such as silver, nickel, molybdenum, gold, platinum, tungsten, or copper. A thickness of the anode (counter electrode) is not particularly limited, and is generally from 10 nm to 5 μm and preferably from 100 to 1000 nm.

As described above, in the present invention, a reverse layered type photoelectric conversion element of FIG. 2, in which a material that is hardly degraded by such as oxygen or moisture can be used for both the anode and the cathode, is preferable. As described above, the degradation of the element due to the oxidation of the counter electrode can be significantly suppressed by adopting a reverse layered type organic photoelectric conversion element, and thus higher stability than the forward layered type element can be provided. To be specific, the organic photoelectric conversion element of the present invention is preferably a reverse layered type organic photoelectric conversion element comprising a transparent electrode as the first electrode, a counter electrode as the second electrode, and a hole transport layer between the photoelectric conversion layer and the second electrode. Examples of the preferred combination of the anode and the cathode in the reverse layered configuration may include the followings:

1) The first electrode (cathode): ITO and the second electrode (anode): silver
2) The first electrode (cathode): PEDOT: PSS and the second electrode (anode): silver
3) The first electrode (cathode): ITO and the second electrode (anode): copper
4) The first electrode (cathode): PEDOT: PSS and the second electrode (anode): gold, and
5) The first electrode (cathode): ITO and the second electrode (anode): PEDOT: PSS

[Photoelectric Conversion Layer]

The photoelectric conversion layer has a function of converting light energy into electrical energy using a photovoltaic effect. The organic photoelectric conversion element of the present embodiment has a feature in that the photoelectric conversion layer essentially contains an n-type organic semiconductor and the conjugated polymer compound as a p-type organic semiconductor. When light is absorbed by these photoelectric conversion materials, an exciton is generated, and is charge-separated into a hole and an electron at the p-n junction interface.

The photoelectric conversion layer of the present embodiment essentially contains the conjugated polymer compound, and may include another p-type organic semiconductor material if necessary. An example of another p-type organic semiconductor material includes the following.

Examples of condensed polycyclic aromatic low-molecular compound include a compound such as anthracene, tetracene, pentacene, hexacene, heptacene, chrysene, picene, fulminene, pyrene, peropyrene, perylene, terylene, quaterrylene, coronene, ovalene, circamanthracene, bisantene, zethrene, heptazethrene, pyranthrene, violanthrene, isoviolanthrene, circobiphenyl, or anthradithiophene, porphyrin or copper phthalocyanine, a tetrathiafulvalene (TTF)-tetracyanoquinodimethane (TCNQ) complex, a bisetylendithiotetrathiafulvalene (BEDTTTF)-perchloric acid complex, and any derivative or precursor thereof.

In addition, examples of the derivative having the condensed polycycle include a pentacene derivative with a substituent, which is disclosed in WO 03/16599 A, WO 03/28125 A, US Patent Application Publication No. 6,690,029, Japanese Patent Application Laid-Open No. 2004-107216, and the like, a pentacene precursor disclosed in US Patent Application Publication No. 2003/136964, and an acene-based compound substituted with trialkylsilylethynyl group, which is disclosed in J. Amer. Chem. Soc., Vol. 127, No. 14, p. 4986, J. Amer. Chem. Soc., Vol. 123, p. 9482, J. Amer. Chem. Soc., Vol. 130 (2008), No. 9, p. 2706, and the like.

Examples of conjugated polymer include a polymer material including a polythiophene such as poly(3-hexylthiophene) (P3HT) or an oligomer thereof, a polythiophene having a polymerizable group, which is disclosed in Technical Digest of the International PVSEC-17, Fukuoka, Japan, 2007, p. 1225, a polythiophene copolymer such as a polythiophene-thienothiophene copolymer disclosed in Nature Material, (2006) vol. 5, p. 328, a polythiophene-diketopyrrolopyrrole copolymer disclosed in WO 2008/000664, a polythiophene-thiazolothiazole copolymer disclosed in Adv. Mater., 2007, p. 4160, or PCPDTBT disclosed in NatureMat. vol. 6 (2007), p. 497, and σ-conjugated polymer such as polypyrrole and an oligomer thereof, polyaniline, polyphenylene and an oligomer thereof, polyphenylenevinylene and an oligomer thereof, polythienylenevinylene and an oligomer thereof, polyacetylene, polydiacetylene, polysilane, or polygermane.

In addition, as the oligomer material but not the polymer material, an oligomer such as α-sexithiophene, α,ω-dihexyl-α-sexithiophene, α,ω-dihexyl-α-quinquethiophene, α,ω-bis(3-butoxypropyl)-α-sexithiophene, each of which is a hexamer thiophene, can be suitably used.

Among these compounds, a compound exhibiting high solubility in an organic solvent so as to be subjected to solution process, forming a crystalline thin film after drying, and capable of achieving high mobility is preferable. More preferably, a compound exhibiting proper compatibility with a fullerene derivative as an n-type organic semiconductor material preferably usable in the present invention (a compound capable of forming a proper phase-separated structure) is preferable.

In addition, when an electron transport layer or a hole blocking layer is further formed on the bulk heterojunction layer by a solution process, laminating can be easily performed when coating can be further performed on a coated layer, but generally there is a problem that the base layer is dissolved when a layer is further laminated on the layer including a material with high solubility by a solution process and used, and thus laminating cannot be performed. Hence, a material capable of being insolubilized after coating by a solution process is preferable.

Examples of such a material include a material, such as a polythiophene having a polymerizable group, which can be insolubilized by polymerization crosslinking the coating film after coating and is disclosed in Technical Digest of the International PVSEC-17, Fukuoka, Japan, 2007, p. 1225, or a material, which is insolubilized (pigmentated) by reacting with a soluble substituent by applying energy such as heat and disclosed in US Patent Application Publication No. 2003/136964, Japanese Patent Application Laid-Open No. 2008-16834, and the like.

A content of another p-type organic semiconductor material is not particularly limited as long as the conjugated polymer compound is contained in the p-type organic semiconductor contained in the photoelectric conversion layer of the present embodiment. Provided that, it is preferable as the proportion of the conjugated polymer compound described above is great with respect to the total amount of p-type organic semiconductor contained in the photoelectric conversion layer (the total amount of all layers when two or more photoelectric conversion layer are contained) in order to achieve higher photoelectric conversion efficiency. Specifically, a proportion of the conjugated polymer compound with respect to the total amount of p-type organic semiconductor is preferably 50% by mass or more, more preferably 70% by mass or more, still more preferably 90% by mass or more, particularly preferably 95% by mass or more, and most preferably 100% by mass.

On the other hand, the n-type organic semiconductor used in the photoelectric conversion layer of the present embodiment is not also particularly limited as long as an n-type organic semiconductor is an acceptor (electron accepting) organic compound with respect to the p-type organic semiconductor, and a material usable in the related art can be appropriately adopted. Examples of such a compound include fullerene, a carbon nanotube, octaazaporphyrin, a perfluoro compound obtained by substituting the hydrogen atoms of the p-type organic semiconductor with a fluorine atom (for example, perfluoro-pentacene, perfluoro-phthalocyanine, or the like), an aromatic carboxylic anhydride such as naphthalenetetracarboxylic anhydride, naphthalenetetracarboxylic diimide, perylenetetracarboxylic anhydride, or perylenetetracarboxylic diimide, and a polymer compound containing an imide of the aromatic carboxylic anhydride as the backbone.

Among these, a fullerene or a carbon nanotube, or a derivative thereof is preferably used from the viewpoint of performing charge separation with the p-type organic semiconductor fast (to 50 fs) and efficiently. Specific examples thereof include fullerene C60, fullerene C70, fullerene C76, fullerene C78, fullerene C84, fullerene C240, fullerene C540, a mixed fullerene, a fullerene nanotube, a multilayer carbon nanotube, a single-layer carbon nanotube, or a carbon nanohorn (conical), and a fullerene derivative, in which part of these is substituted with a hydrogen atom, a halogen atom (a fluorine atom, a chlorine atom, a bromine atom, an iodine atom), or an alkyl group, an alkenyl group, an alkynyl group, an aryl group, a heteroaryl group, a cycloalkyl group, a silyl group, an ether group, a thioether group, and an amino group which are substituted or unsubstituted.

Particularly, a fullerene derivative improved in solubility by a substituent such as [6,6]-phenylC61-butyric acid methyl ester (abbreviation: PCBM, PC61BM), [6,6]-phenylC61-butyric acid n-butyl ester (PCBnB), [6,6]-phenylC61-butyric acid isobutyl ester (PCBiB), [6,6]-phenylC61-butyric acid n-hexyl ester (PCBH), [6,6]-phenylC71-butyric acid methyl ester (abbreviation: PC71BM), bis-PCBM disclosed in Adv. Mater., Vol. 20 (2008), p. 2116, an aminated fullerene disclosed in Japanese Patent Application Laid-Open No. 2006-199674, or metallocene fullerene disclosed in Japanese Patent Application Laid-Open No. 2008-130889, fullerene having a cyclic ether group disclosed in US Patent Application Publication No. 7,329,709 is preferably used. Meanwhile, in the present embodiment, one kind of n-type organic semiconductor may be used singly, or two or more kinds thereof may be concurrently used.

A junction form of n-type organic semiconductor with p-type organic semiconductor in the photoelectric conversion layer of the present embodiment is not particularly limited, and may be a planar heterojunction or a bulk heterojunction. A planar heterojunction is a junction form, in which a p-type organic semiconductor layer containing a p-type organic semiconductor and an n-type organic semiconductor layer containing an n-type organic semiconductor are laminated and the surface, at which these two contact, is the p-n junction interface. On the other hand, a bulk heterojunction is formed by coating a mixture of an n-type organic semiconductor and a p-type organic semiconductor, the domain of the p-type organic semiconductor and the domain of the n-type organic semiconductor are in a microphase-separated structure in this single layer. Hence, a large number of p-n junction interfaces are present over the entire layer in the bulk heterojunction compared to the planar heterojunction. Consequently, a large number of excitons generated by light absorption can reach the p-n junction interface, and thus the efficiency leading to charge separation can be increased. For this reason, the junction between the p-type organic semiconductor and the n-type organic semiconductor in the photoelectric conversion layer of the present embodiment is preferably a bulk heterojunction.

In addition, the bulk heterojunction layer may have a three-layer structure (p-i-n structure) including the i layer sandwiched between the p-layer formed of a p-type organic semiconductor and the n-layer formed of an n-type organic semiconductor in some cases in addition to the single layer (i layer) formed by mixing the p-type organic semiconductor material and the n-type organic semiconductor layer as ordinal case. In this p-i-n structure, the rectification of holes and electrons is higher, the loss due to such as recombination of the holes and electrons which are charge separated is reduced, and thus higher photoelectric conversion efficiency can be obtained.

In the present invention, a mixing ratio of p-type organic semiconductor and n-type organic semiconductor contained in the photoelectric conversion layer is preferably in the range of from 20:80 to 80:20, more preferably in the range of from 30:70 to 50:50, and the most preferred ratio is from 33:67 to 40:60 by mass ratio. In addition, a thickness of one layer of the photoelectric conversion layer is preferably from 50 to 400 nm, more preferably from 80 to 300 nm, particularly preferably from 100 to 250 nm, and most preferably from 150 to 200 nm. In general, it is preferable as the thickness of the photoelectric conversion layer is thick from the viewpoint of absorbing more light, but there is a tendency that the photoelectric conversion efficiency decreases due to decreased extraction efficiency of carriers (holes and electrons) when the film thickness increases. However, when the photoelectric conversion layer is formed using the conjugated polymer of the present embodiment as a p-type organic semiconductor material, high photoelectric conversion efficiency can be maintained since extraction efficiency of carriers (holes and electrons) hardly decreases even when a film thickness is 100 nm or more, as compared to the photoelectric conversion layer using a conventional p-type organic semiconductor material.

(Substrate)

The organic photoelectric conversion element of the present invention may include a substrate if necessary. The substrate has a role as a member to be coated with a coating solution in the formation of an electrode by a coating method.

The substrate is preferably a member capable of transmitting light to be photoelectrically converted, that is, a transparent member with respect to light to be photoelectrically converted, when the light to be photoelectrically converted is incident from the substrate side. As the substrate, for example, a glass substrate or a resin substrate is suitably included, and it is desirable to use a transparent resin film from the viewpoints of light weight and flexibility.

There is no particular limitation on the transparent resin film which can be preferably used as the transparent substrate in the present invention, and the material, shape, structure, and thickness thereof can be appropriately selected from those have been well-known in the art. Examples of the transparent resin film include a polyester resin film such as of polyethylene terephthalate (PET), polyethylene naphthalate (PEN), or modified polyester, a polyolefin resin film such as polyethylene (PE) resin film, a polypropylene (PP) resin film, a polystyrene resin film, or of cyclic olefin-based resin, a vinyl resin film such as of polyvinyl chloride or polyvinylidene chloride, a polyetheretherketone (PEEK) resin film, a polysulfone (PSF) resin film, a polyether sulfone (PES) resin film, a polycarbonate (PC) resin film, a polyamide resin film, a polyimide resin film, an acrylic resin film, and a triacetyl cellulose (TAC) resin film. A resin film having a transmittance of 80% or more in a visible wavelength range (380 to 800 nm) can be preferably applied to the transparent resin film according to the present invention. Among them, a biaxially oriented polyethylene terephthalate film, a biaxially oriented polyethylene naphthalate film, a polyether sulfone film, or a polycarbonate film is preferable, and a biaxially oriented polyethylene terephthalate film or a biaxially oriented polyethylene naphthalate film is more preferable, in terms of transparency, heat resistance, easy handling, strength and cost.

The transparent substrate used in the present invention can be subjected to surface treatment or provided with an easy adhesion layer in order to secure wettability of a coating solution and adhesiveness. Conventional techniques can be used for the surface treatment or easy adhesion layer. Examples of the surface treatment may include surface activation treatment such as corona discharge treatment, flame treatment, ultraviolet treatment, high frequency treatment, glow discharge treatment, active plasma treatment, and laser treatment. In addition, examples of the easy adhesion layer may include polyester, polyamide, polyurethane, vinyl copolymer, butadiene copolymer, acrylic copolymer, vinylidene copolymer, and epoxy-based copolymer.

In addition, a barrier coating may be formed in advance on the transparent substrate, or a hard coating may be formed in advance on the opposite side of a transferred transparent conductive layer, for the purpose of suppressing permeation of oxygen and steam.

[Hole Transport Layer]

The organic photoelectric conversion element of the present embodiment may include a hole transport layer if necessary. The hole transport layer serves to transport holes and has property that ability to transport electrons is significantly low (for example, equal or less than one-tenth of hole mobility). The hole transport layer is provided between a photoelectric conversion layer and an anode, and prevents movement of electrons while transporting holes to the anode, and thus the recombination of electrons and holes can be prevented.

A hole transport material used in the hole transport layer is not particularly limited, and a material usable in the related art can be appropriately adopted. As an example, PEDOT:PSS such as BaytronP (trade name) manufactured by Starck NV-Tech Co., Ltd., polythienothiophenes disclosed in EP 1647566 B, sulfonated polythiophenes, and polyanilines and doped material thereof disclosed in Japanese Patent Application Laid-Open No. 2010-206146, or a cyano compound disclosed in WO 2006/019270 A is included.

In addition, a triazole derivative, an oxadiazole derivative, an imidazole derivative, a polyarylalkane derivative, a pyrazoline derivative, and a pyrazolone derivative, a phenylenediamine derivative, an arylamine derivative, an amino-substituted chalcone derivative, an oxazole derivative, a styryl anthracene derivative, a fluorenone derivative, a hydrazone derivative, a stilbene derivative, a silazane derivative, an aniline copolymer, or a conductive polymer oligomer, particularly a thiophene oligomer, and the like can also be used.

In addition, a porphyrin compound, an aromatic tertiary amine compound, and a styrylamine compound can be used in addition to these, and an aromatic tertiary amine compound is preferably used among these. Meanwhile, a hole transport layer may be formed using an inorganic compound such as a metal oxide of molybdenum, vanadium, or tungsten, or a mixture thereof in some cases.

Moreover, a polymer material, in which a structural unit contained in the compound exemplified above is introduced into the polymer chain, or the compound exemplified above is the main chain of the polymer, can also be used as the hole transport material. In addition, a p-type hole transport material disclosed in Japanese Patent Application Laid-Open No. 11-251067, or J. Huang et al., Applied Physics Letters, 80 (2002), p. 139 can also be used. Further, a hole transport material that is doped with an impurity and has high p property can also be used. As an example, a material disclosed in Japanese Patent Application Laid-Open No. 4-297076, Japanese Patent Application Laid-Open No. 2000-196140, Japanese Patent Application Laid-Open No. 2001-102175, and J. Appl. Phys., 95, 5773 (2004) is included. Meanwhile, one kind of these hole transport materials may be used singly, or two or more kinds thereof may be concurrently used. In addition, the hole transport layer can also be constituted by laminating two or more layers formed of respective materials.

A thickness of the hole transport layer is not particularly limited, and is usually from 1 to 2000 nm. The thickness is preferably 5 nm or more from the viewpoint of increasing leakage-preventing effect. In addition, the thickness is preferably 1000 nm or less and more preferably 200 nm or less from the viewpoint of maintaining high transmittance and low resistance.

A conductivity of the hole transport layer is generally preferably to be high. However, too high conductivity deteriorates ability to prevent electrons from moving, to deteriorate rectification. Hence, the conductivity of the hole transport layer is preferably from 10⁻⁵ to 1 S/cm and more preferably from 10⁻⁴ to 10⁻² S/cm.

[Electron Transport Layer]

The organic photoelectric conversion element of the present embodiment may include an electron transport layer if necessary. The electron transport layer serves to transport electrons and has property that ability to transport holes is significantly low. The electron transport layer is provided between a photoelectric conversion layer and a cathode, and prevents movement of holes while transporting electrons to the cathode, and thus the recombination of electrons and holes can be prevented.

A electron transport material used in the electron transport layer is not particularly limited, and a material usable in the related art can be appropriately adopted. For example, octaazaporphyrin and a perfluoro compound of a p-type organic semiconductor (perfluoropentacene, perfluorophthalocyanine, or the like) can be used, but in the same manner, a hole blocking function having a rectifying effect that holes generated in the photoelectric conversion layer do not flow to the cathode side, is imparted to the electron transport layer having a deeper HOMO level than a HOMO level of a p-type organic semiconductor used in a photoelectric conversion layer. Accordingly, a material having a deeper HOMO level than a HOMO level of a n-type organic semiconductor is more preferably used as the electron transport material. As such an electron transport material, a phenanthrene-based compound such as bathocuproin, an n-type organic semiconductor such as naphthalenetetracarboxylic anhydride, naphthalenetetracarboxylic diimide, perylenetetracarboxylic anhydride, and perylenetetracarboxylic diimide, an n-type inorganic oxide such as titanium oxide, zinc oxide, and gallium oxide, and an alkali metal compound such as lithium fluoride, sodium fluoride, and cesium fluoride may be used. In addition, it is also possible to use a layer formed soley of n-type organic semiconductor used in the photoelectric conversion layer. Meanwhile, one kind of these electron transport materials may be used singly, or two or more kinds thereof may be concurrently used. In addition, the electron transport layer can also be constituted by laminating two or more layers formed of respective materials

Meanwhile, a compound, which is insoluble in a coating liquid containing a photoelectric conversion material, is preferable as the electron transport material, since the photoelectric conversion layer is formed after the formation of the electron transport layer on the first electrode in the case of a reverse layered type element that is advantageous from the viewpoint of durability as described above. From such a viewpoint, the electron transport material is preferably an inorganic compound such as titanium oxide or zinc oxide, and a crosslinkable organic compound such as polyethyleneimine or an amino silane coupling agent disclosed in WO 2008-134492 A. Among them, an amino silane coupling agent (as an example, 3-(2-aminoethyl)-aminopropyltrimethoxysilane) is preferably used.

In addition, as the material insoluble in a solvent used in the coating of a photoelectric conversion layer, a π-conjugated polymer soluble in an alcohol can be exemplified, and a polyfluorene and a polythiophene disclosed in APPLIED PHYSICS LETTERS 95 (2009), p. 043301, Adv. Funct. Mat., 2010, p. 1977, Adv. Mater., 2011, 23, 3086, J. Am. Chem. Soc., 2011, p. 8416, and Advanced Materials, 2011 (Vol. 23, no. 40), p. 4636-4643, and a polyfluorene described below may also be used. These polymers are preferable since these polymers can also be used in the forward layered configuration, that is, can also be formed on the photoelectric conversion layer unlike the silane coupling agent described above. In addition, these polymers are preferable since these polymers can function as an electron transport layer and a hole blocking layer with respect to not only a metal oxide such as ITO but also a metal electrode such as of gold, silver, or copper, and thus a metal stable to oxidation can be used as the cathode even in the forward layered configuration.

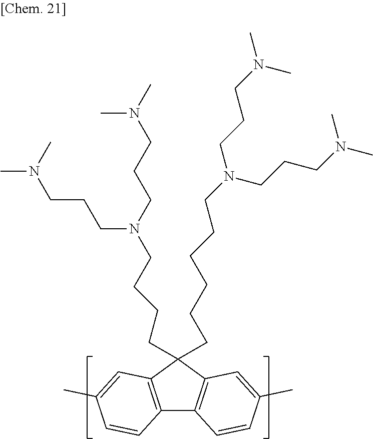

A thickness of the electron transport layer is not particularly limited, and is generally from 1 to 2000 nm. The thickness is preferably 3 nm or more from the viewpoint of increasing leakage-preventing effect. In addition, the thickness is preferably 100 nm or less, more preferably 20 nm or less, and most preferably from 5 to 10 nm from the viewpoint of maintaining high transmittance and low resistance.

[Charge Recombination Layer; Intermediate Electrode]

In the tandem type (multijunction type) organic photoelectric conversion element having two or more photoelectric conversion layers as illustrated in FIG. 3, a charge recombination layer (intermediate electrode) is disposed between the photoelectric conversion layers.

A material used for the charge recombination layer (intermediate electrode) is not particularly limited as long as it exhibits both conductivity and light transmitting property. A transparent metal oxide such as ITO, AZO, FTO, or titanium oxide, a metal such as Ag, Al, or Au, a carbon material such as carbon nanoparticles or carbon nanowires, and a conductive polymer compound such as PEDOT:PSS or polyaniline, which are exemplified as the electrode materials described above, can be used. One kind of these materials may be used singly, or two or more kinds thereof may be concurrently used. In addition, the charge recombination layer can also be constituted by laminating two or more layers formed of respective materials.

A conductivity of the charge recombination layer is preferred to be high from the viewpoint of obtaining high conversion efficiency, and specifically, the conductivity is preferably from 5 to 50,000 S/cm and more preferably from 100 to 10,000 S/cm. In addition, a thickness of the charge recombination layer is not particularly limited, and is preferably from 1 to 1000 nm and more preferably from 5 to 50 nm. It is possible to smooth the film surface by setting the thickness to 1 nm or more. On the other hand, it is possible to reduce decrease in short circuit current density J_{sc} (mA/cm²) by setting the thickness to 1000 nm or less.

[Other Layers]

The organic photoelectric conversion element of the present embodiment may be further provided with another member (another layer) in addition to the respective members (respective layers) described above, in order to improve photoelectric conversion efficiency or life of element. As the another member, for example, a hole injection layer, an electron injection layer, an exciton blocking layer, a UV absorbing layer, a light reflecting layer, and a wavelength conversion layer are included. A layer such as a silane coupling agent may also be provided in order to stabilize metal oxide fine particles localized in the upper layer. Moreover, a metal oxide layer may also be laminated adjacent to the photoelectric conversion layer of the present invention.

In addition, the organic photoelectric conversion element of the present invention may have various kinds of optical functional layers for the purpose of more efficient receiving of solar light. As the optical functional layer, an antireflective film, a light condensing layer such as a microlens array, a light diffusing layer capable of scattering light reflected from a cathode to cause re-incidence to the power generation layer, are exemplified.

As the antireflective layer, various kinds of conventional antireflective layers can be provided. For example, when the transparent resin film is a biaxially oriented polyethylene terephthalate film, the transmittance can be improved by adjusting a refractive index of an easy adhesion layer adjacent to the film to from 1.57 to 1.63 to reduce an interfacial reflection between the film substrate and the easy adhesion layer, which is more preferable. The method for adjusting the refractive index can be carried out by appropriately adjusting a ratio of a binder resin and an oxide sol, such as tin oxide sol or cerium oxide sol, which has a relatively high refractive index, and then coating. The easy adhesion layer may be a single layer, or may consist of two or more layers in order to improve adhesiveness.

The light condensing layer can be provided, for example, by processing a support substrate so as to be equipped with a structure of microlens array on the solar light receiving side, or by combining a support substrate with a so-called light condensing sheet. Hence, a amount of light received from a specific direction can be increased, or on the contrary, incident angle dependence of solar light can be reduced.

As the microlens array, for example, quadrangular pyramids are two-dimensionally arranged on a light extraction side of the substrate such that a length of one side is 30 μm and a vertical angle is 90 degrees. A length of one side is preferably from 10 to 100 μm. If the length is lower than the lower limit, coloring due to generation of diffraction effect would occur. If the length is too large, a thickness would be increased, which is not preferable.

In addition, as the light scattering layer, various antiglare layers, a layer having nanoparticles or nanowires, such as of metal or various inorganic oxides, dispersed in a colorless transparent polymer, and the like can be exemplified.

<Production Method of Organic Photoelectric Conversion Element>

The production method of the organic photoelectric conversion element of the present embodiment described above is not particularly limited, and can be produced by appropriately referring to a conventionally well-known method. Hereinafter, a preferred production method of the organic photoelectric conversion element of the present embodiment will be described by taking the production method of the reverse layered type organic photoelectric conversion element as illustrated in FIG. 2 as an example. Provided that, each process in the production method is applicable to the production of not only the reverse layered type organic photoelectric conversion element but also the forward layered type organic photoelectric conversion element as illustrated in FIG. 1 and the tandem type as illustrated in FIG. 3.

The production method of the organic photoelectric conversion element of the present embodiment comprises a step of forming a cathode, a step of forming a photoelectric conversion layer containing a p-type organic semiconductor material and an n-type organic semiconductor material on the cathode, and a step of forming an anode on the photoelectric conversion layer. Hereinafter, individual steps of the production method of the organic photoelectric conversion element of the present embodiment will be described in detail.

In the production method of the present embodiment, first, the cathode is formed. A method of forming a cathode is not particularly limited, but a method, which comprises coating a liquid containing a material constituting the cathode on a substrate and then drying the coating, is preferable in terms of easy operation or capability of producing by a roll-to-roll method using a device such as a die coater. A thin film of commercially available electrode material may also be used as it is.

After forming the cathode, an electron transport layer can be formed on the cathode if necessary. As a means for forming the electron transport layer may be either a vapor deposition method or a solution coating method, and the solution coating method is preferable. In the formation of the electron transport layer using a solution coating method, a solution prepared by dissolving and dispersing the electron transport material described above in an appropriate solvent may be coated on a cathode by an appropriate coating method prior to drying.

As the coating method used for the solution coating method, it is possible to use a common method such as a casting method, a spin coating method, a blade coating method, a wire bar coating method, a gravure coating method, a spray coating method, a dipping (immersing) coating method, a bead coating method, an air knife coating method, a curtain coating method, an inkjet method, a printing method such as a screen printing method, a relief printing method, an intaglio printing method, an offset printing method, or a flexographic printing method, and Langmuir-Blodgett (LB) method. Among them, a blade coating method is particularly preferably used. Meanwhile, a solid content of the solution used for the coating method may vary depending on the coating method or the film thickness, but is preferably from 1 to 15% by mass and more preferably from 1.5 to 10% by mass. Meanwhile, a solution concentration of the solution used for coating method may vary depending on the coating method or the film thickness, but is preferably from 0.01 to 5% by mass and more preferably from 0.03 to 0.3% by mass. In addition, a temperature of the coating liquid and/or the coating surface in the coating is not particularly limited, but is preferably from 30 to 120° C. and more preferably from 50 to 110° C. from the viewpoint of preventing precipitation and irregularity due to the temperature fluctuation in the coating and drying. Moreover, a specific form of drying is not also particularly limited, and conventionally well-known knowledge can be appropriately referred. As an example of the drying conditions, a condition of a temperature of about from 90 to 140° C. and a time of about from several minutes to several tens of minutes is exemplified, and a condition of drying at a temperature of 120° C. and for one minute is more preferably exemplified. Examples of the device used for drying include a hot plate, hot-air drying, an infrared heater, a microwave, and a vacuum dryer. It is of course possible to use a drying device other than these.

Subsequently, a photoelectric conversion layer containing a p-type organic semiconductor and an n-type organic semiconductor is formed on the cathode or the electron transport layer formed thereon. The production method of the present embodiment essentially comprises use of the conjugated polymer compound of the present invention as the p-type organic semiconductor. A specific method for forming the photoelectric conversion layer is not particularly limited, but preferably, a solution obtained by separately or collectively dissolving and dispersing the p-type organic semiconductor and the n-type organic semiconductor in an appropriate solvent may be coated on the cathode or the electron transport layer using an appropriate coating method (specific form is as described above), and then dried. Preferably, a solution obtained by collectively dissolving and dispersing the p-type organic semiconductor and the n-type organic semiconductor in a solvent is coated by a coating method. Thereafter, removal of residual solvent, moisture and gas, and heating for the improvement in mobility by crystallization of the semiconductor material and the shift of absorption wavelength to a longer wavelength are preferably performed. When an annealing treatment is performed at a predetermined temperature during the manufacturing process, aggregation or crystallization is microscopically promoted at a part of the photoelectric conversion layer, and thus the photoelectric conversion layer can be in a properly phase-separated structure. As a result, the mobility of holes and electrons (carriers) in the photoelectric conversion layer can be improved, to attain high efficiency. In this manner, the p-type organic semiconductor and the n-type organic semiconductor are uniformly mixed, to yield a bulk heterojunction type organic photoelectric conversion element.

On the other hand, when a photoelectric conversion layer (for example, a p-i-n structure) including plural layers having different mixing ratios of the p-type organic semiconductor and the n-type organic semiconductor is formed, the photoelectric conversion layer can be formed by coating one layer, insolubilizing (pigmentating) the coated layer, and then coating another layer thereon.

Meanwhile, the subsequent steps following the forming step of the photoelectric conversion layer are preferably performed in a glove box under a nitrogen atmosphere in order to avoid exposure to oxygen or moisture. Hence, the degradation of the p-type organic semiconductor by oxygen or moisture in the air can be prevented by performing the steps under a nitrogen atmosphere, and the durability of the element can be improved. Specifically, a concentration of oxygen and moisture in the glove box is preferably 1000 ppm or less, more preferably 100 ppm or less, and most preferably 10 ppm or less.

Next, an anode is formed on the photoelectric conversion layer. A means for forming the anode is also not particularly limited, and may be either a vapor deposition or a solution coating method. The vapor deposition method (for example, a vacuum deposition method) is preferably used.

Meanwhile, when a hole transport layer is provided between the photoelectric conversion layer and the anode, the hole transport layer is formed using either a vapor deposition method or a solution coating method, preferably using a solution coating method. The step of forming the hole transport layer is preferably performed in a glove box under a nitrogen atmosphere as the step of forming the photoelectric conversion layer. Hence, the degradation of the p-type organic semiconductor by oxygen or moisture in the air can be prevented by performing the step under a nitrogen atmosphere, and thus the durability of the element can be improved. In addition, the conjugated polymer compound according to the present invention has a polar group, and thus exhibits a high affinity for the solvent. Consequently, it is possible to effectively prevent a coating solution containing a hole transport material from being repelled on the surface of the photoelectric conversion layer in the forming of the hole transport layer using a solution coating method, and thus the film forming property of the hole transport layer can be improved.

Moreover, when a layer other than the various layers described above is included, the step of forming these layers can be appropriately added and performed using a solution coating method or a vapor deposition method.

The electrodes (cathode and anode), the photoelectric conversion layer, the hole transport layer, the electron transport layer, or the like may be patterned if necessary. A method of patterning is not particularly limited, and a well-known method can be appropriately applied. For example, in the case of patterning a soluble material used in a bulk heterojunction type photoelectric conversion layer or a hole transport layer and an electron transport layer, only unnecessary portions may be wiped off after coating the entire surface by a die coating or a dip coating, or patterning may be directly performed at the time of coating using an inkjet method or a screen printing method. On the other hand, in the case of insoluble material used in the electrode, a mask vapor deposition can be performed during deposition by vacuum deposition method, or patterning can be performed by a well-known method such as etching or lift-off. In addition, a pattern can also be formed by transferring the pattern formed on a separate substrate.

The organic photoelectric conversion element of the present embodiment may be sealed if necessary in order to prevent degradation due to oxygen, moisture, or the like in the environment. A sealing method is not particularly limited, and the sealing may be conducted by a well-known method used in an organic photoelectric conversion element or an organic electroluminescence element. Examples thereof include (1) a method of sealing by adhering a cap made of aluminum or glass with an adhesive; (2) a method of bonding a plastic film formed with a gas barrier layer such as aluminum, silicon oxide, or aluminum oxide on the organic photoelectric conversion element with an adhesive; (3) a method of spin coating an organic polymer material (polyvinyl alcohol, or the like) having high gas barrier property; (4) a method of depositing an inorganic thin film (silicon oxide, aluminum oxide, or the like) or organic film (parylene or the like) having high gas barrier property under vacuum; and (5) a method of laminating using these methods in combination.

<Application of Organic Photoelectric Conversion Element>

According to another embodiment of the present invention, a solar cell comprising the organic photoelectric conversion element described above is provided. The organic photoelectric conversion element of the present embodiment exhibits excellent durability and is possible to achieve sufficient photoelectric conversion efficiency, and thus can be suitably used in a solar cells using this as a power generating element.

In addition, according to still another embodiment of the present invention, an optical sensor array, in which the organic photoelectric conversion element described above is arranged in an array, is provided. Specifically, the organic photoelectric conversion element of the present embodiment can also be used as an optical sensor array, in which an image projected onto the optical sensor array is converted into an electrical signal using the photoelectric conversion function thereof.

### EXAMPLES

The effects by the present invention will be described with reference to the following Examples and Comparative Examples. However, the technical scope of the present invention is not limited to Examples below.

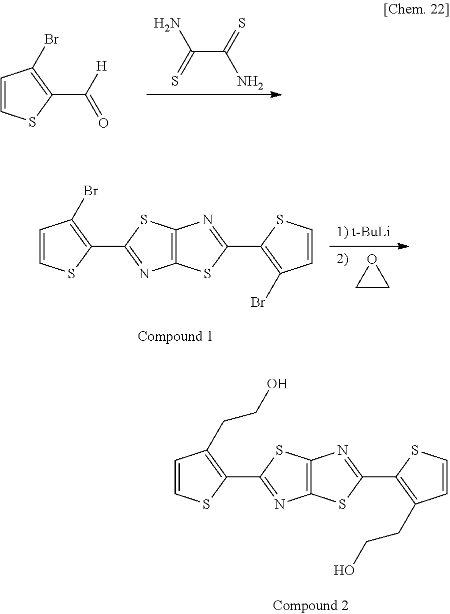

### Synthesis of Compound 1

Compound 1 was synthesized with reference to US Patent Application Publication No. 2010/137611.

5.1 g (27 mmol) of 3-bromothiophene-2-carboxyaldehyde and 0.73 g (6.8 mmol) of rubeanic acid were weighed and dissolved in 100 ml of N,N-dimethylformamide (DMF), and the solution was stirred at 150° C. for 5 hours. The reaction was stopped and the temperature was returned to room temperature (25° C., the same applies hereinafter), and then pure water was added thereto and stirred for 30 minutes. The solid precipitate was filtered and collected, and the collected solid was washed with methanol and then dried in a vacuum at 60° C. for 10 hours. The resultant solid was dissolved in tetrahydrofuran (THF), and purified by silica gel column chromatography, thereby obtaining 1.2 g (38% of yield) of Compound 1.

### Synthesis of Compound 2

Compound 2 was synthesized with reference to J. Org. Chem., 1997, 62, 1376-1387.

In 300 ml of dehydrated tetrahydrofuran (THF), 1.0 g (2.2 mmol) of Compound 1 was dissolved, the solution was cooled to −78° C., and then 6.1 ml (9.7 mmol) of a solution of 1.6 M t-butyl lithium (t-BuLi) in hexane was added dropwise thereto and stirred for 1 hour. Thereafter, 1.5 ml (2.4 mmol) of a solution of 5.0 Methylene oxide in ether was added dropwise thereto, and stirred for 12 hours while gradually returning to room temperature. After the reaction was completed, saline solution and ethyl acetate were added to the reaction product to perform a liquid separation operation, and an organic layer was extracted and dried over magnesium sulfate, and then the solvent was removed therefrom by distillation. Thereafter, the resultant was purified by silica gel column chromatography, thereby obtaining 0.72 g (83% of yield) of Compound 2.

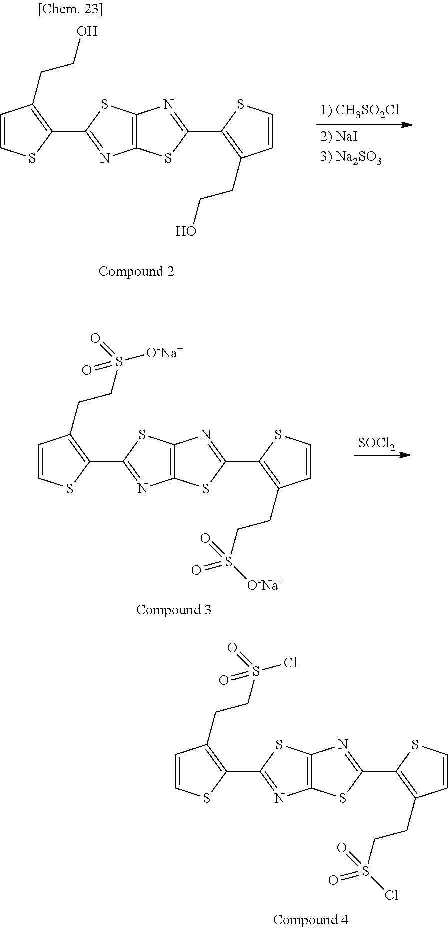

### Synthesis of Compound 3

Compound 3 was synthesized with reference to J. Am. Chem. Soc., 1987, 109, 1858-1859.

In 300 ml of acetone, 2.5 g (6.4 mmol) of Compound 2, 2.6 ml (32 mmol) of methanesulfonyl chloride, 2.5 g (16 mmol) of sodium iodide, and 2.0 g (16 mmol) of sodium sulfite were dissolved and the solution was stirred at room temperature for 3 hours. After stopping the reaction, the reaction product was purified by ion-exchange chromatography, thereby obtaining 2.9 g (80% of yield) of Compound 3.

### Synthesis of Compound 4

Compound 4 was synthesized with reference to Tetrahedron Letters, 2009, 50, 7028-7031.

In 100 ml of DMF, 2.5 g (4.4 mmol) of Compound 3 and 5.5 ml (75 mmol) of thionyl chloride were dissolved, and the solution was stirred at 60° C. for 5 hours. After stopping the reaction, water was added, and a solid precipitated was filtered, thereby obtaining 2.0 g (83% of yield) of Compound 4.

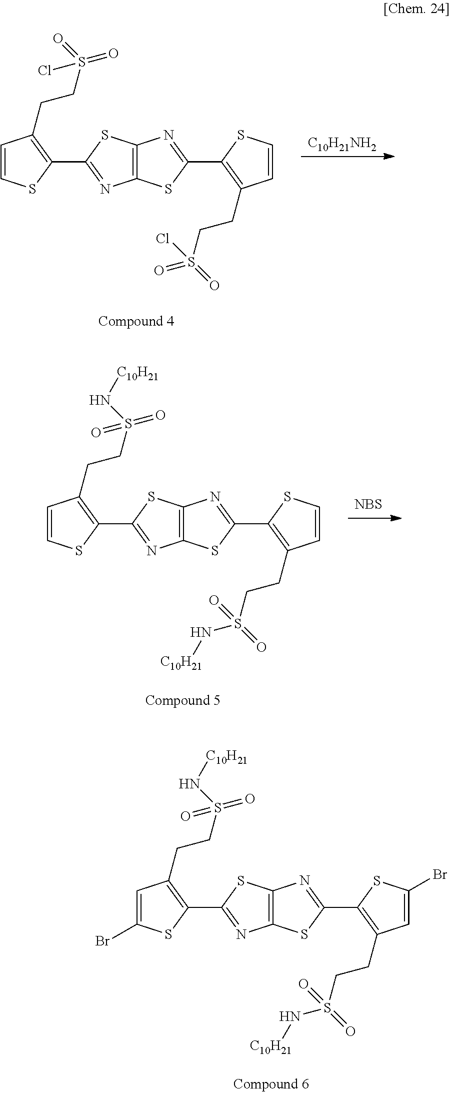

### Synthesis of Compound 5

Compound 5 was synthesized with reference to Org. Lett. 2004, 6, 4285-4288.

In 200 ml of THF, 2.5 g (4.5 mmol) of Compound 4 was dissolved and the solution was cooled in ice. To the reaction container, 1.7 g (11 mmol) of n-decylamine, 0.054 mg (0.45 mmol) of N,N-dimethyl-4-aminopyridine (DMAP), 50 ml of THF solution of 1.5 ml (11 mmol) of triethylamine were added, and stirred for 24 hours while gradually returning to room temperature. After stopping the reaction, ethyl acetate, an aqueous solution of ammonium chloride, and saturated saline solution were added to the reaction product to perform a liquid separation operation, and an organic phase was extracted therefrom and dried over magnesium sulfate, and then the solvent was removed therefrom by distillation. The resultant was purified by silica gel column chromatography, thereby obtaining 2.5 g (70% of yield) of Compound 5.

### Synthesis of Compound 6

In 150 ml of THF, 2.0 g (2.5 mmol) of Compound 5 and 1.3 g (7.5 mmol) of N-bromosuccinimide (NBS) were dissolved, and the solution was refluxed at 70° C. for 6 hours under nitrogen. After the reaction was completed, saline solution and ethyl acetate were added to the reaction product to perform a liquid separation operation, and an organic layer was extracted and dried over magnesium sulfate, and then the solvent was removed therefrom by distillation. An oil component thus obtained was purified by silica gel column chromatography, thereby obtaining 2.0 g (84% of yield) of Compound 6.

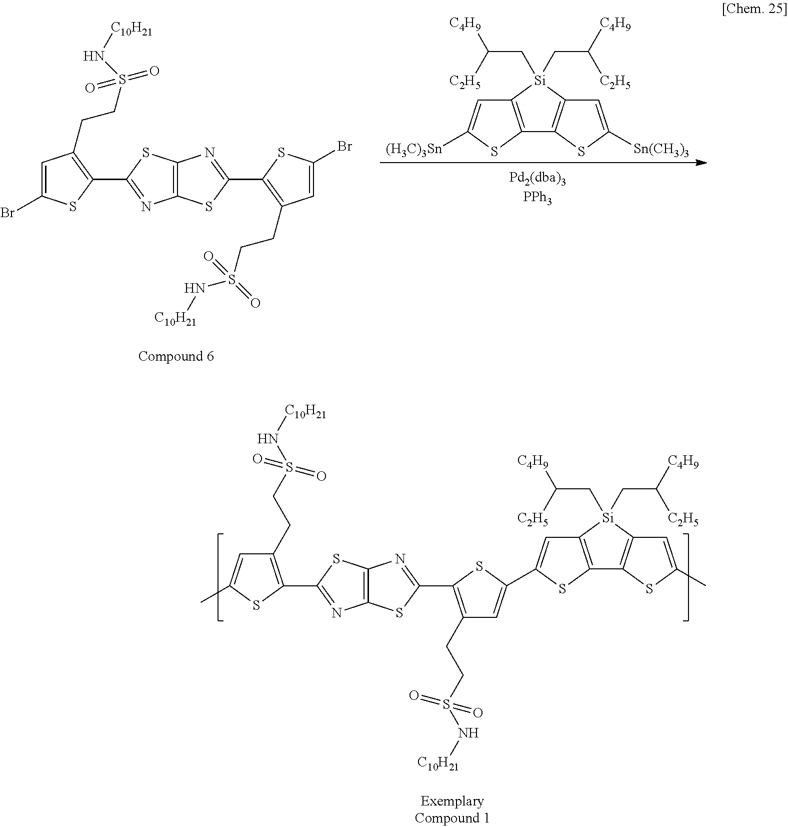

### Synthesis of Exemplary Compound 1 (P-1)

Bis-(5,5′-trimethylstannyl)-3,3′-di-(2-ethylhexyl)-silylene-2,2′-dithiophene was synthesized with reference to JP-T-2010-507233 and Adv. Mater., 2010, p-E63.

In 20 ml of anhydrous toluene, 479 mg (0.5 mmol) of Compound 6 and 372 mg (0.5 mmol) of bis-(5,5′-trimethylstannyl)-3,3′-di-(2-ethylhexyl)-silyl ene-2,2′-dithiophene were dissolved. This solution was purged with nitrogen, and then 12.55 mg (0.014 mmol) of tris(dibenzylideneacetone)dipalladium (0) and 28.80 mg (0.11 mmol) of triphenylphosphine were added thereto. This solution was further purged with nitrogen for 15 minutes. Thereafter, the solution was heated to from 110 to 120° C., and reacted for 40 hours. Moreover, 2-tributyltinthiophene (11 mg, 0.03 mmol) was added thereto and refluxed for 10 hours in order to perform the end cap. Furthermore, 2-bromothiophene (10 mg, 0.06 mmol) was added thereto and refluxed for 10 hours. After the reaction was completed, the residue obtained by removing the solvent by distillation was washed with methanol (50 ml, three times), and then washed with acetone (50 ml, three times). A soluble component was extracted from the polymer product thus recovered by Soxhlet extraction using heptane, chloroform, and then o-dichlorobenzene, and then reprecipitated from methanol, thereby obtaining 145 mg of a pure polymer (Mn=20100) (Exemplary Compound 1). Exemplary Compound 1 thus obtained was used in Example 1 of the present invention.

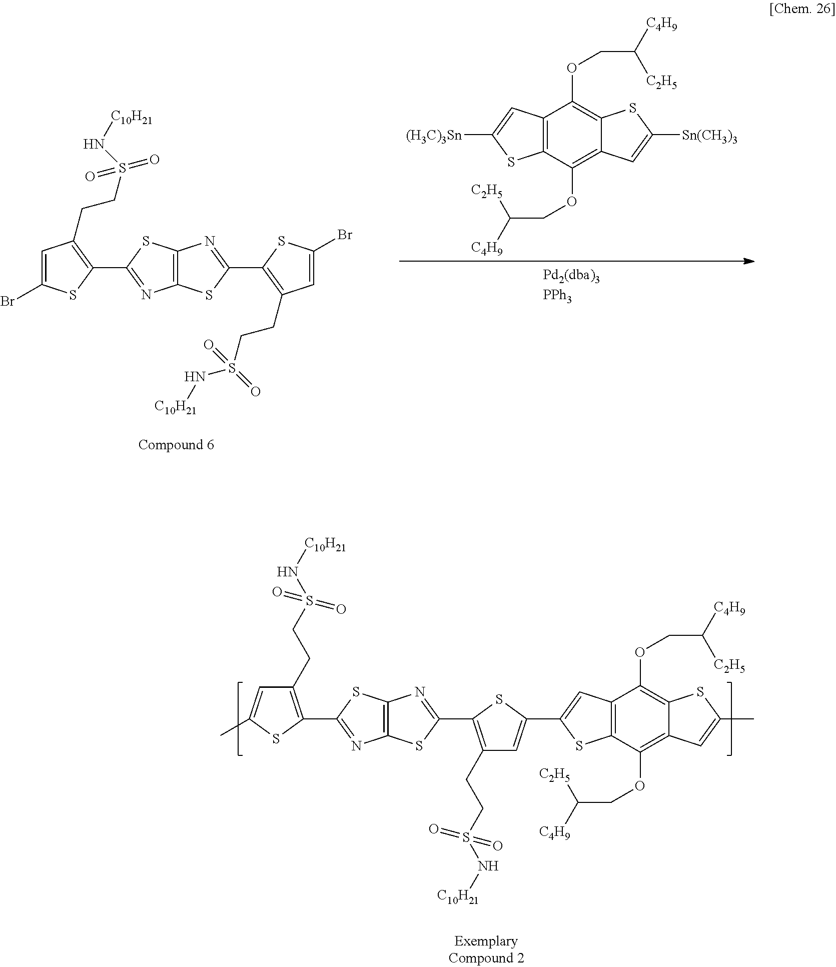

### Synthesis of Exemplary Compound 2 (P-2)

The synthesis of Exemplary Compound 2 was performed in the same manner except that the starting materials, Compound 6 and bis-(5,5′-trimethylstannyl)-3,3′-di-(2-ethylhexyl)-silyl ene-2,2′-dithiophene in the synthesis of Exemplary Compound 1, were changed to the starting material, 1,5-bis(trimethyltin)-4,8-bis(2-ethylhexyloxy)-benzo[1,2-b:4,5-b′]dithiophene (synthesized with reference to J. Am. Chem. Soc., 2009, 22, 7792, 0.5 mmol, 387 mg).

From a Soxhlet extraction component with o-dichlorobenzene, 200 mg of Exemplary Compound 2 (Mn=15400) was obtained and used in Example 2 of the present invention.

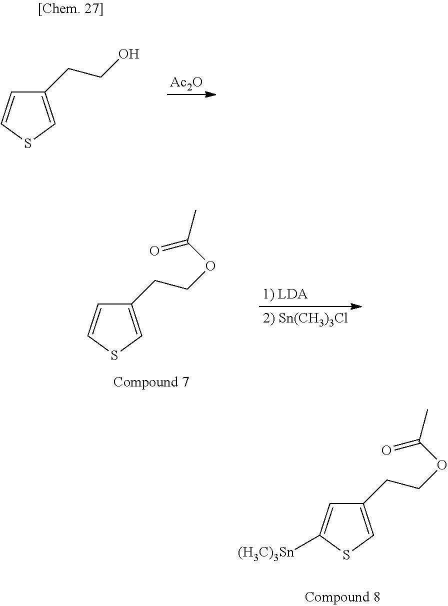

### Synthesis of Compound 7

Compound 7 was synthesized with reference to WO 2011/069554 A.

In 100 ml of pyridine, 8.0 g (38 mmol) of 3-thiopheneethanol and 5.0 g (49 mmol) of acetic anhydride (Ac₂O) were dissolved, and the solution was stirred for five hours. After the reaction was completed, saline solution and ethyl acetate were added to the reaction product to perform a liquid separation operation, and an organic layer was extracted and dried over magnesium sulfate, and then the solvent was removed therefrom by distillation, thereby obtaining 6.3 g (97% of yield) of Compound 7.

### Synthesis of Compound 8

In 100 ml of dehydrated THF, 6.0 g (35 mmol) of Compound 7 was dissolved, and the solution was cooled to −78° C. Thereafter, 19.3 ml (38.5 mmol) of a solution of 2.0 M lithium diisopropylamide (LDA) in heptane was added dropwise thereto and stirred for one hour, and then 38.5 ml (38.5 mmol) of a solution of 1.0 M trimethyltin chloride in hexane was added dropwise thereto and further stirred for one hour, and then the temperature of the resultant was raised to room temperature and stirred for three hours. After the reaction was completed, saline solution and ethyl acetate were added to the reaction product to perform a liquid separation operation, and an organic layer was extracted and dried over magnesium sulfate, and then the solvent was removed therefrom by distillation. An oil component thus obtained was dissolved in a mixture of hexane:triethylamine=9:1, and the resultant was purified by passing through silica gel immersion which had been treated with triethylamine in advance, thereby obtaining 11.1 g (95% of yield) of Compound 8.

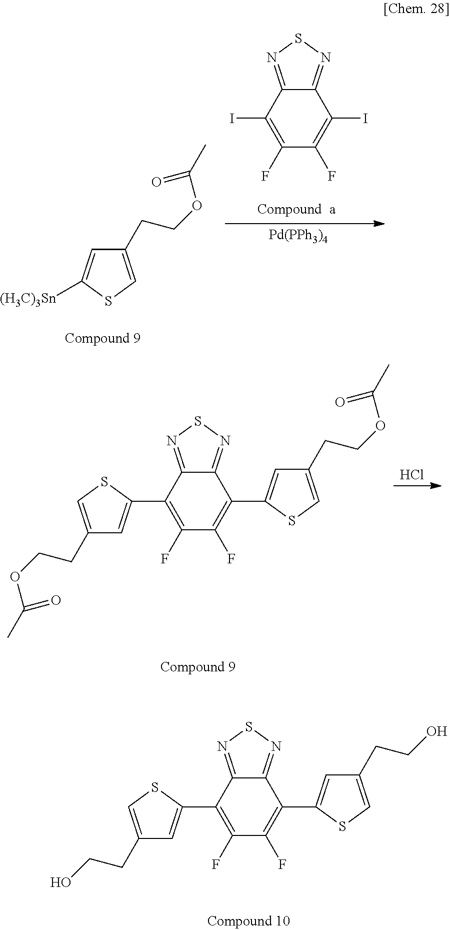

### Synthesis of Compound 9

Compound a was synthesized with reference to Angewandte Chemie International Edition Volume 50, Issue 13, 2995-2998.

In 100 ml of toluene, 10.0 g (29.9 mmol) of Compound 8, 4.1 g (9.7 mmol) of Compound a, and 1.1 g (0.97 mmol) of tetrakis(triphenylphosphine)palladium were dissolved, and the solution was refluxed at 120° C. for three hours under nitrogen. After the reaction was completed, the reaction solution was directly purified by silica gel column chromatography, thereby obtaining 3.89 g (79% of yield) of Compound 9.

### Synthesis of Compound 10

In 50 ml of THF, 3.89 g (7.7 mmol) of Compound 9 was dissolved, and 3 ml of 2M hydrochloric acid was added thereto and stirred for five hours. After the reaction was completed, saline solution and ethyl acetate were added to the reaction product to perform a liquid separation operation, and an organic layer was extracted and dried over magnesium sulfate, and then the solvent was removed therefrom by distillation, thereby obtaining 2.6 g (80% of yield) of Compound 10.

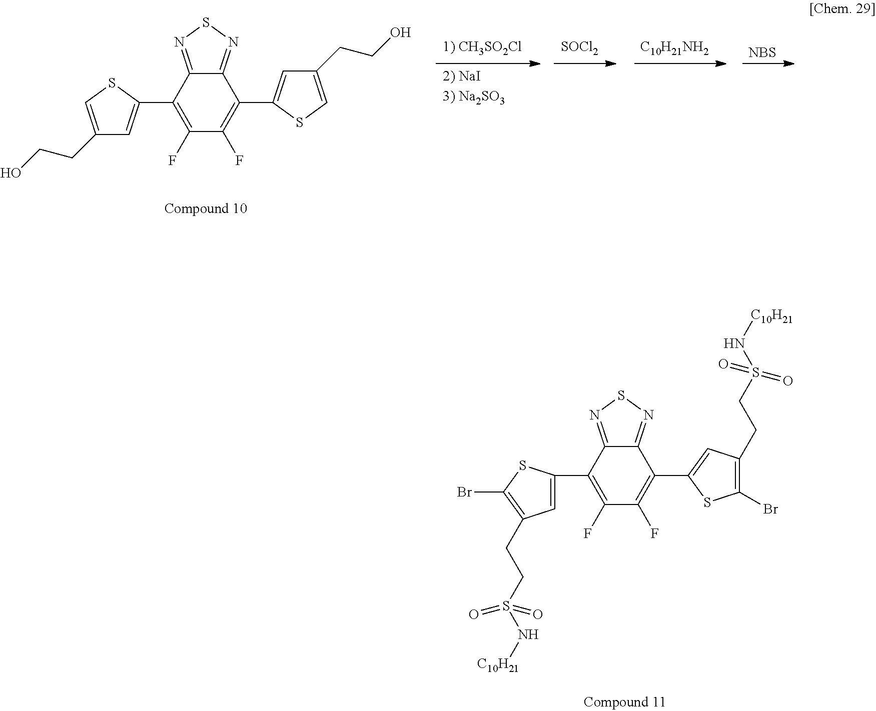

### Synthesis of Compound 11

The Compound 11 was obtained in the same manner as the synthesis of a series of Compounds 3, 4, 5, and 6 except changing the starting material to Compound 10.

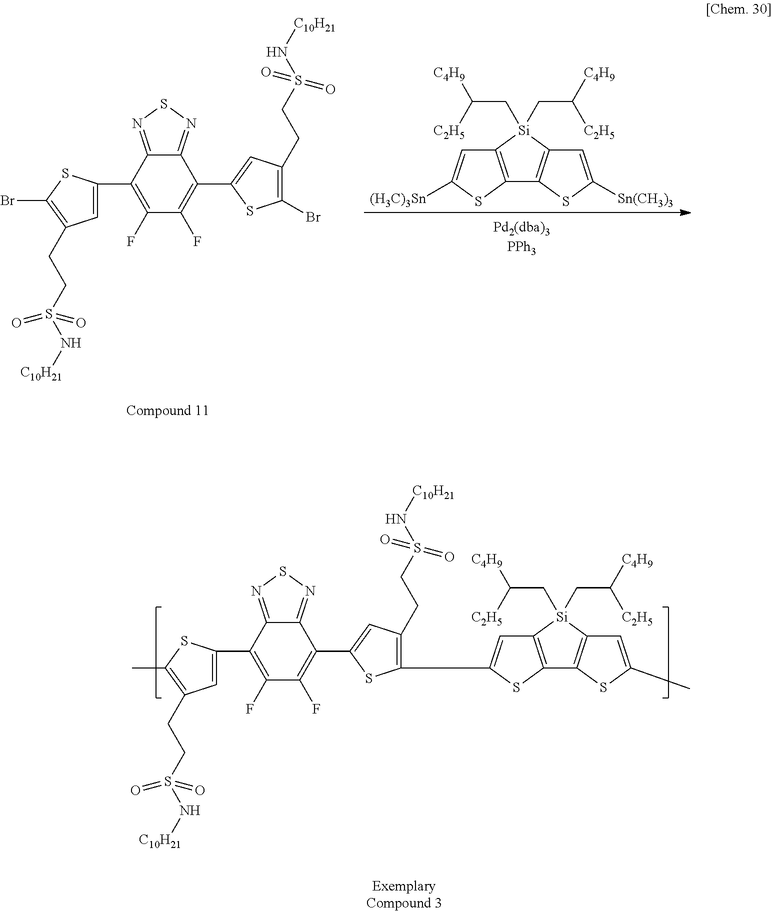

### Synthesis of Exemplary Compound 3 (P-3)

The synthesis of Exemplary Compound 3 was performed in the same manner as the synthesis of Exemplary Compound 1 except changing as the starting material Compound 6 to Compound 11 (0.5 mmol, 495 mg). From a Soxhlet extraction component with o-dichlorobenzene, 220 mg of Exemplary Compound 3 (Mn=21000) was obtained and used in Example 3 of the present invention.

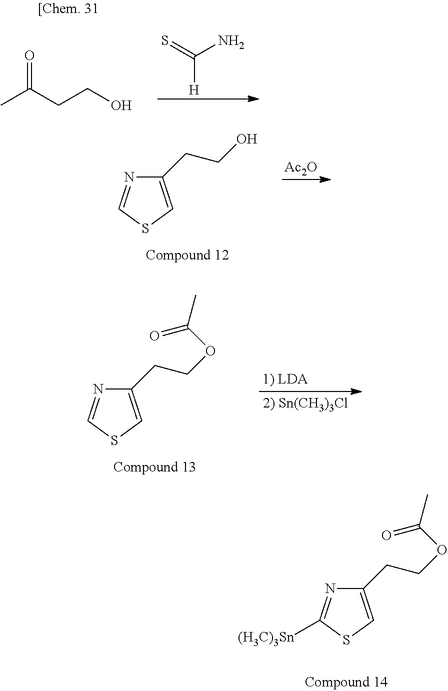

### Synthesis of Compound 12

Compound 12 was synthesized with reference to J. Am. Chem. Soc., 1945, 67, 400-403.

In 350 ml of ethanol, 9.5 g (108 mmol) of 4-hydroxy-2-butanone and 6.6 g (108 mmol) of thioformamide were dissolved, and the solution was stirred at 0° C. for 24 hours, and then the resultant was returned to room temperature and further stirred for 48 hours. The reaction was stopped and the solvent was removed from the reaction product by distillation, thereby obtaining 3.5 g (25% of yield) of Compound 12.

### Synthesis of Compound 13

The synthesis of Compound 13 was performed in the same manner as the synthesis of Compound 7 except changing the starting material to Compound 12, thereby obtaining Compound 13.

### Synthesis of Compound 14

The synthesis of Compound 14 was performed in the same manner as the synthesis of Compound 8 except changing the starting material to Compound 13, thereby obtaining Compound

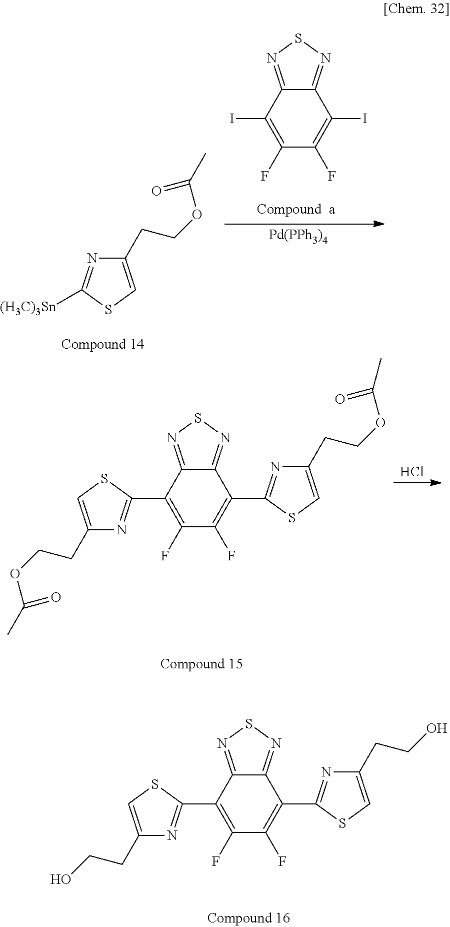

### Synthesis of Compound 15

The synthesis of Compound 15 was performed in the same manner as the synthesis of Compound 9 except changing the starting material to Compound 14, thereby obtaining Compound 15.

### Synthesis of Compound 16

The synthesis of Compound 16 was performed in the same manner as the synthesis of Compound 10 except changing the starting material to Compound 15, thereby obtaining Compound 16.

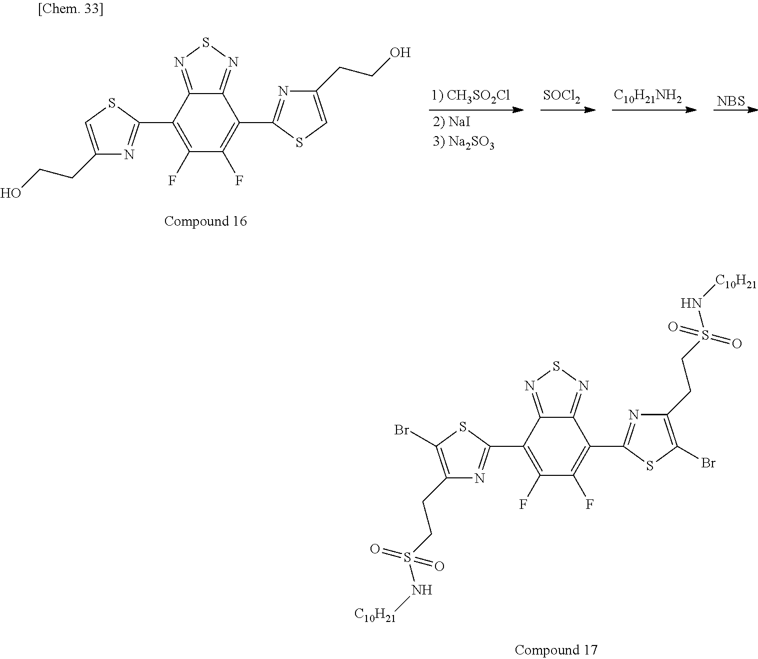

### Synthesis of Compound 17

The synthesis of Compound 17 was performed in the same manner as the synthesis of a series of Compounds 3, 4, 5, and 6 except changing the starting material to Compound 16, thereby obtaining Compound 17.

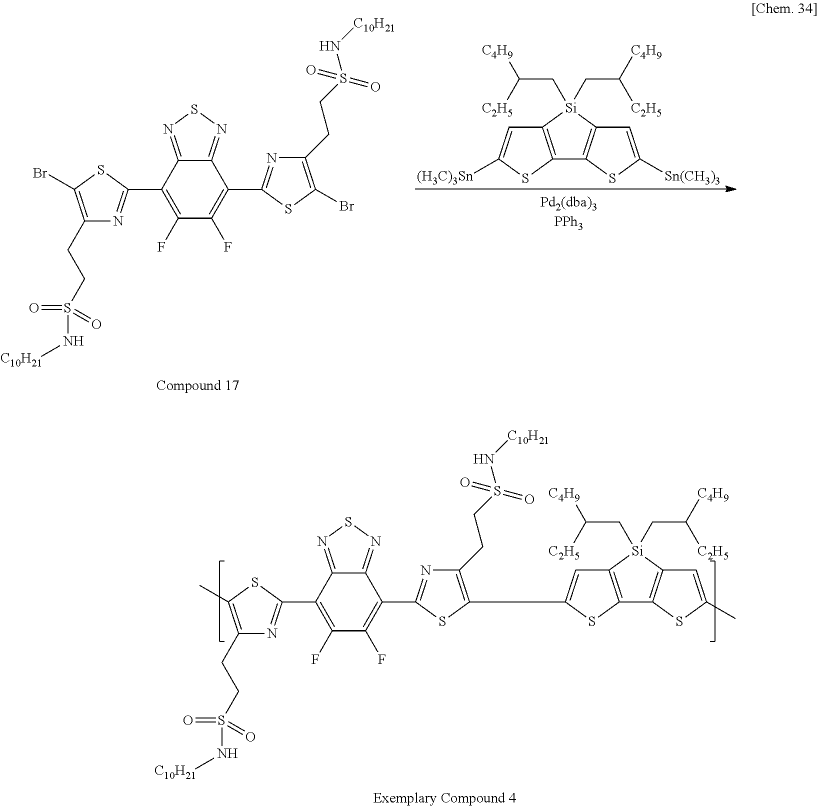

### Synthesis of Exemplary Compound 4 (P-4)

The synthesis of Exemplary Compound 4 was performed in the same manner as the synthesis of Exemplary Compound 1 except changing as the starting material Compound 6 to Compound 17 (0.5 mmol, 495 mg). From a Soxhlet extraction component with o-dichlorobenzene, 190 mg of Exemplary Compound 4 (Mn=19000) was obtained and used in Example 4 of the present invention.

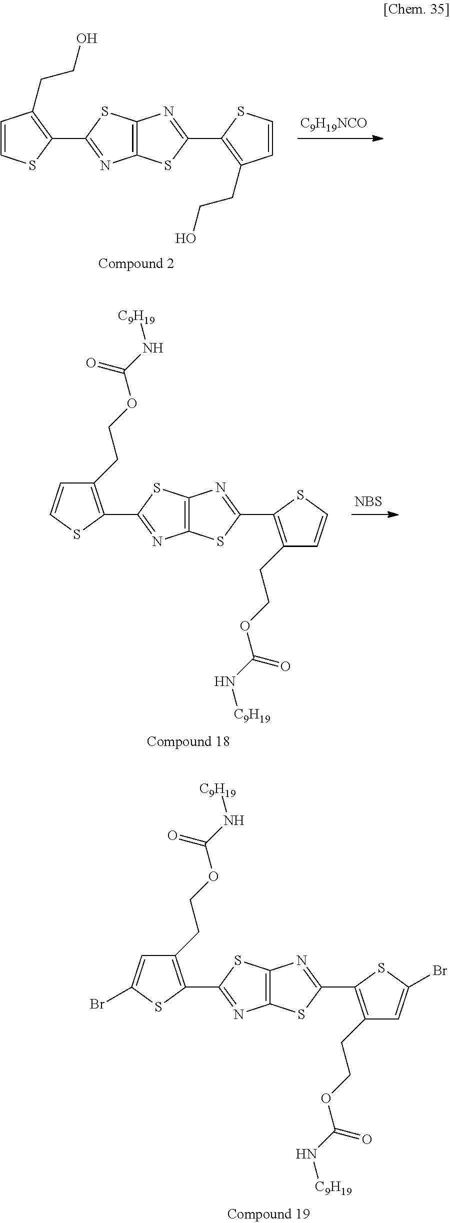

### Synthesis of Compound 18

Compound 18 was synthesized with reference to J. Med. Chem., 1984, 27, 1559-1565.

In 100 ml of dichloromethane, 1.5 g (3.8 mmol) of Compound 2, 2.0 g (12 mmol) of nonyl isocyanate, and 1 ml of triethylamine were dissolved, and the solution was stirred at room temperature for 12 hours. After the reaction was completed, the reaction solution was directly purified by silica gel column chromatography, thereby obtaining 3.0 g (80% of yield) of Compound 18.

### Synthesis of Compound 19

The synthesis of Compound 19 was performed in the same manner as the synthesis of Compound 6 except changing the starting material to Compound 18, thereby obtaining Compound

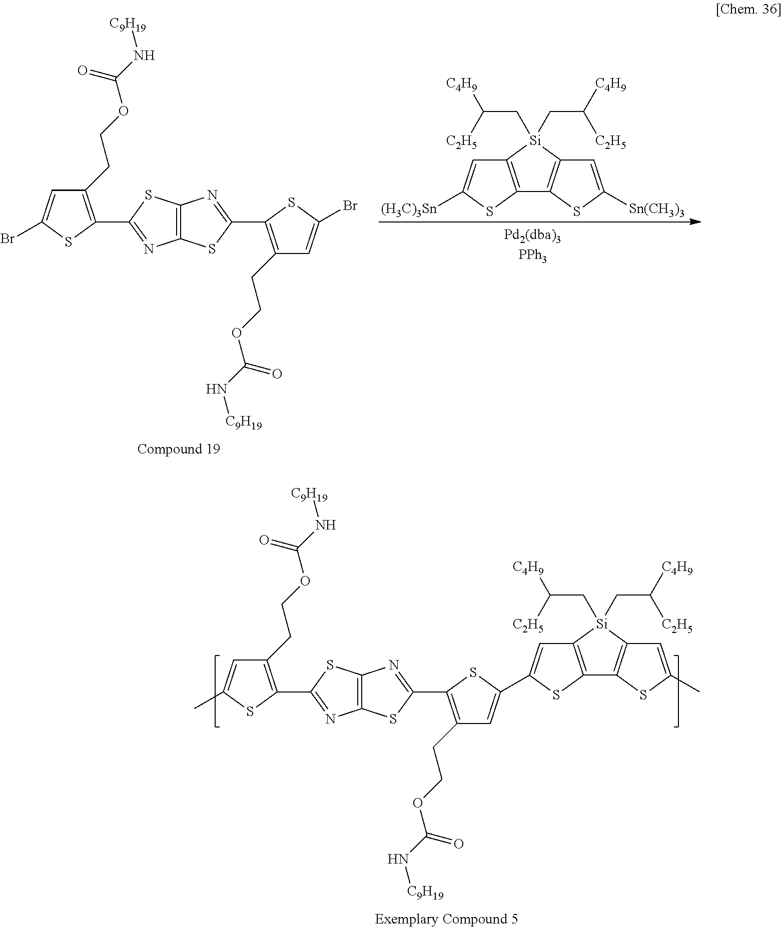

### Synthesis of Exemplary Compound 5 (P-5)

The synthesis of Exemplary Compound 5 was performed in the same manner as the synthesis of Exemplary Compound 1 except changing as the starting material Compound 6 to Compound 19 (0.5 mmol, 445 mg). From a Soxhlet extraction component with o-dichlorobenzene, 200 mg of Exemplary Compound 5 (Mn=16500) was obtained and used in Example 5 of the present invention.

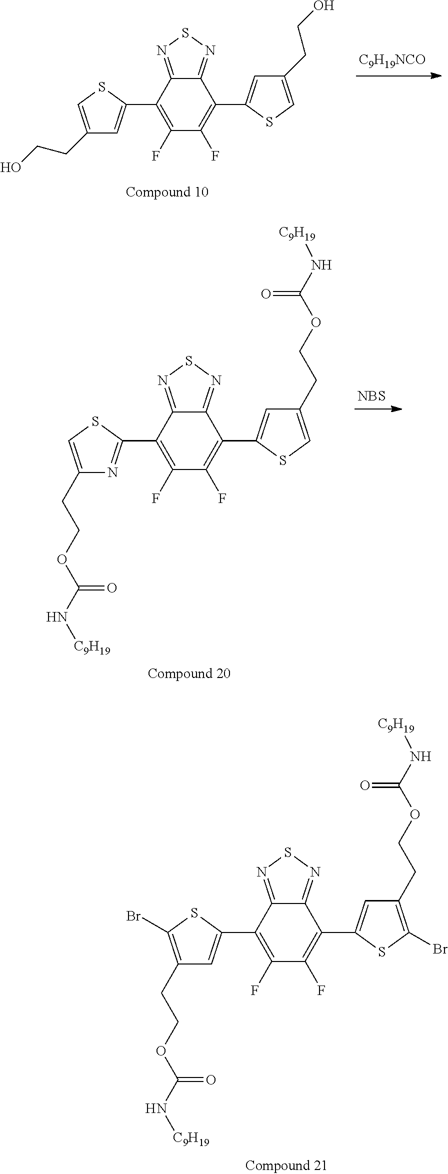

### Synthesis of Compound 20

The synthesis of Compound 20 was performed in the same manner as the synthesis of Compound 18 except changing the starting material to Compound 10, thereby obtaining Compound 20.

### Synthesis of Compound 21

The synthesis of Compound 21 was performed in the same manner as the synthesis of Compound 6 except changing the starting material to Compound 20, thereby obtaining Compound 21.

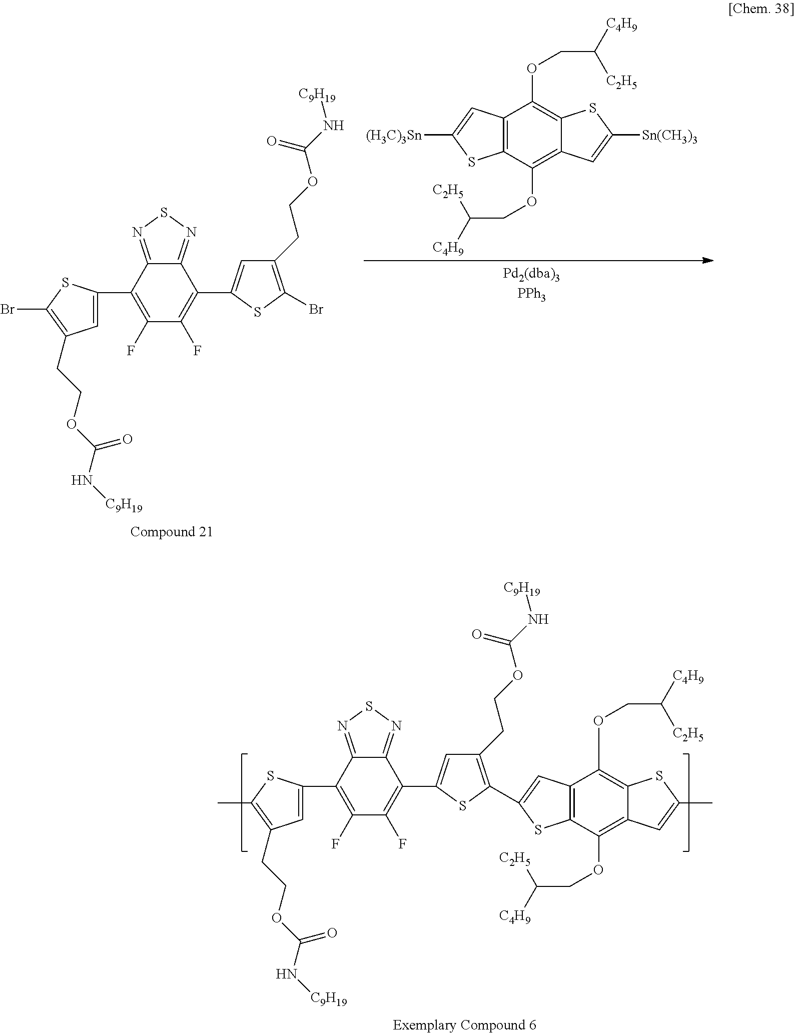

### Synthesis of Exemplary Compound 6 (P-6)

The synthesis of Exemplary Compound 6 was performed in the same manner as the synthesis of Exemplary Compound 2 except changing as the starting material Compound 6 to Compound 21 (0.5 mmol, 460 mg). From a Soxhlet extraction component with o-dichlorobenzene, 240 mg of Exemplary Compound 6 (Mn=15000) was obtained and used in Example 6 of the present invention.

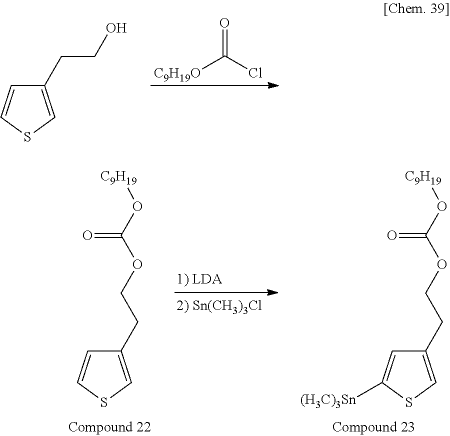

### Synthesis of Compound 22

Compound 22 was synthesized with reference to Org. Lett. 2005, 5: P945-947.

In 150 ml of dichloromethane, 1.5 g (11 mmol) of 3-thiopheneethanol, 2.3 g (11 mmol) of nonyl chloroformate, and 1.5 ml (11 mmol) of triethylamine were dissolved, and the solution was stirred at room temperature for 12 hours. After the reaction was completed, the reaction solution was directly purified by silica gel column chromatography, thereby obtaining 2.1 g (63% of yield) of Compound 22.

### Synthesis of Compound 23

The synthesis of Compound 23 was performed in the same manner as the synthesis of Compound 8 except changing the starting material to Compound 22, thereby obtaining Compound 23.

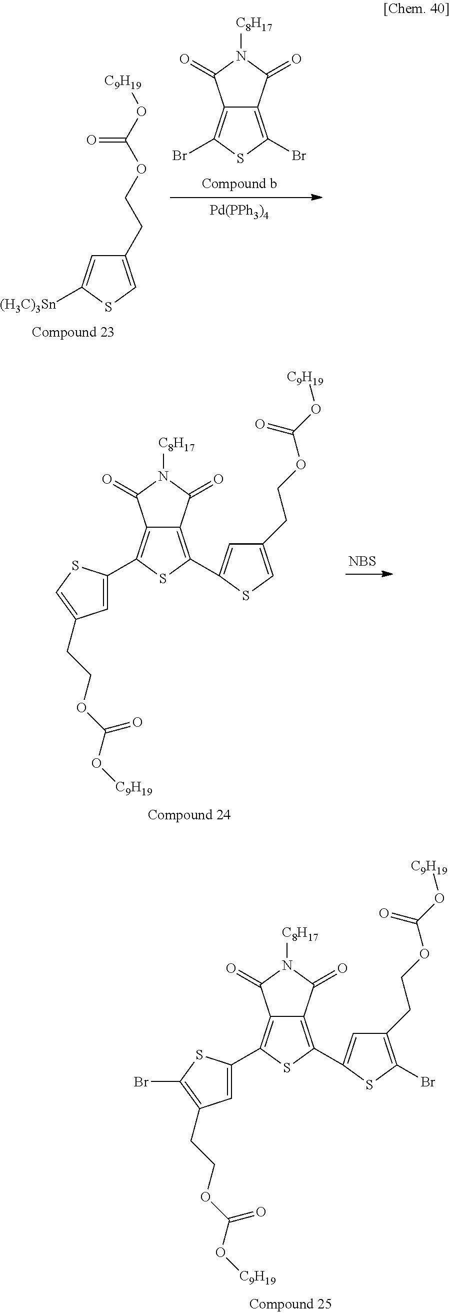

### Synthesis of Compound 24

Compound b was synthesized with reference to J. Am. Chem. Soc., 1997, 119, 5065-5066.

The synthesis of Compound 24 was performed in the same manner as the synthesis of Compound 9 except changing the starting materials to Compound 23 and Compound b, thereby obtaining Compound 24.

### Synthesis of Compound 25

The synthesis of Compound 25 was performed in the same manner as the synthesis of Compound 6 except changing the starting material to Compound 24, thereby obtaining Compound 25.

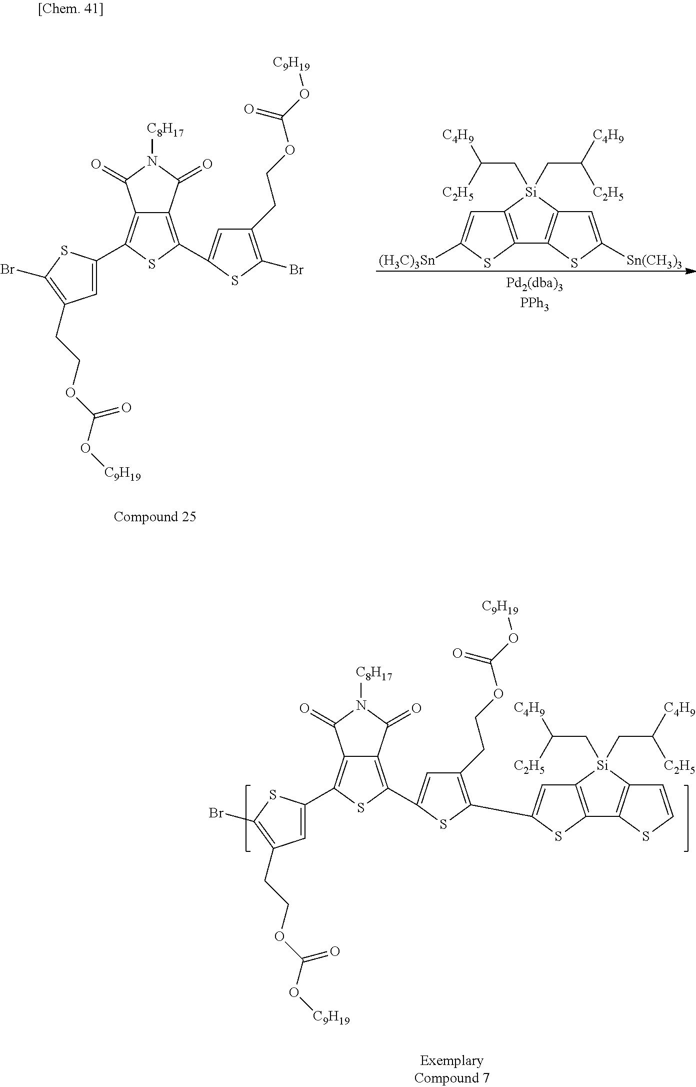

### Synthesis of Exemplary Compound 7 (P-7)

The synthesis of Exemplary Compound 7 was performed in the same manner as the synthesis of Exemplary Compound 1 except changing as the starting material Compound 6 to Compound 25 (0.5 mmol, 508 mg). From a Soxhlet extraction component with o-dichlorobenzene, 160 mg of Exemplary Compound 7 (Mn=23000) was obtained and used in Example 7 of the present invention.

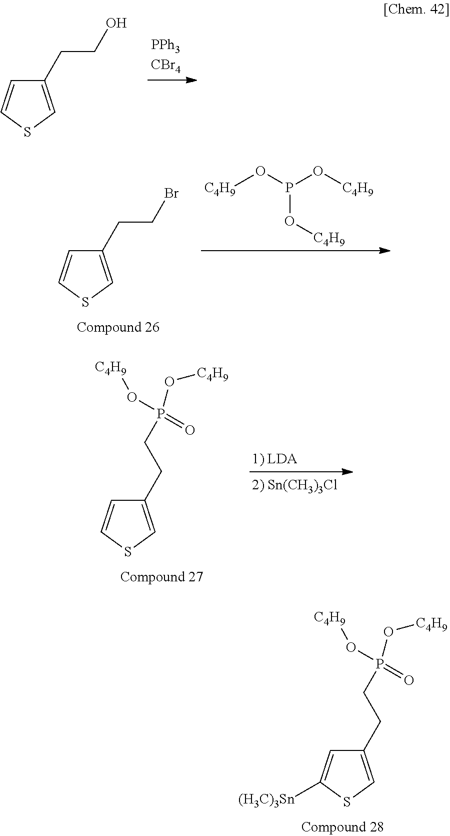

### Synthesis of Compound 26

Compound 26 was synthesized with reference to Macromolecules., 2005, 38, 3679-3687.

In 100 ml of THF, 1.5 g (11 mmol) of 3-thiopheneethanol and 2.9 g (11 mmol) of triphenylphosphine were dissolved and the solution was cooled in ice. To this solution, a solution of 3.0 g (9 mmol) tetrabromomethane in THF was added dropwise, and stirred at 0° C. for six hours. After the reaction was completed, the solvent was removed from the reaction product by distillation, and then the residue was dissolved in methylene chloride, an aqueous solution of sodium hydroxide was added thereto to perform a liquid separation operation, and an organic layer was extracted therefrom and dried over sodium sulfate, and then the solvent was removed therefrom by distillation. The resultant was purified by silica gel column chromatography, thereby obtaining 1.8 g (85% of yield) of Compound 26.

### Synthesis of Compound 27

Compound 27 was synthesized with reference to Macromolecules, 2003, 36, 7114-7118.

1.6 g (8.3 mmol) of Compound 26 and 9.0 g (36 mmol) of tributoxyphosphine were mixed and stirred at 150° C. for 24 hours. After the reaction was completed, excessive tributoxyphosphine was removed from the reaction product by distillation, thereby obtaining 2.0 g (80% of yield) of Compound 27.

### Synthesis of Compound 28

The synthesis of Compound 28 was performed in the same manner as the synthesis of Compound 8 except changing the starting material to Compound 27, thereby obtaining Compound 28.

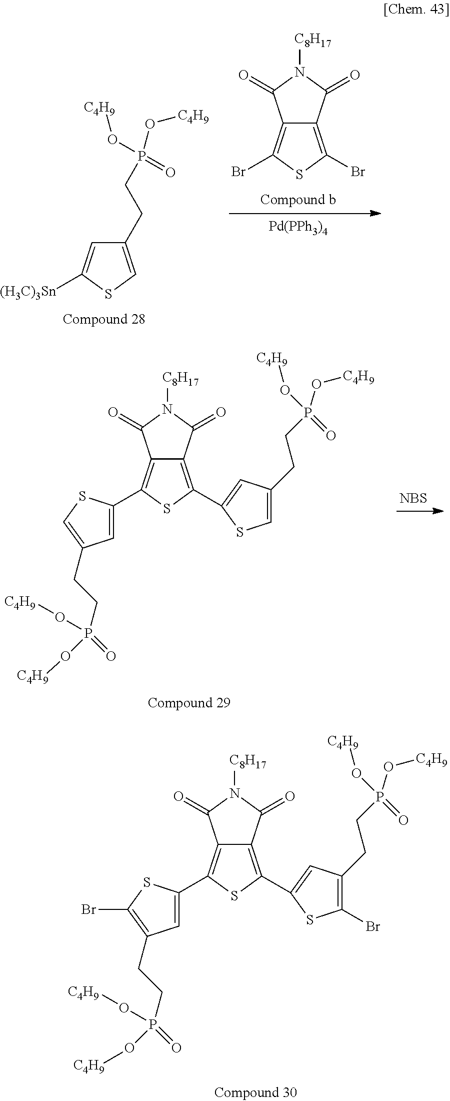

### Synthesis of Compound 29

The synthesis of Compound 29 was performed in the same manner as the synthesis of Compound 9 except changing the starting materials to Compound 28 and Compound b, thereby obtaining Compound 29.

### Synthesis of Compound 30

The synthesis of Compound 30 was performed in the same manner as the synthesis of Compound 6 except changing the starting material to Compound 29, thereby obtaining Compound 30.

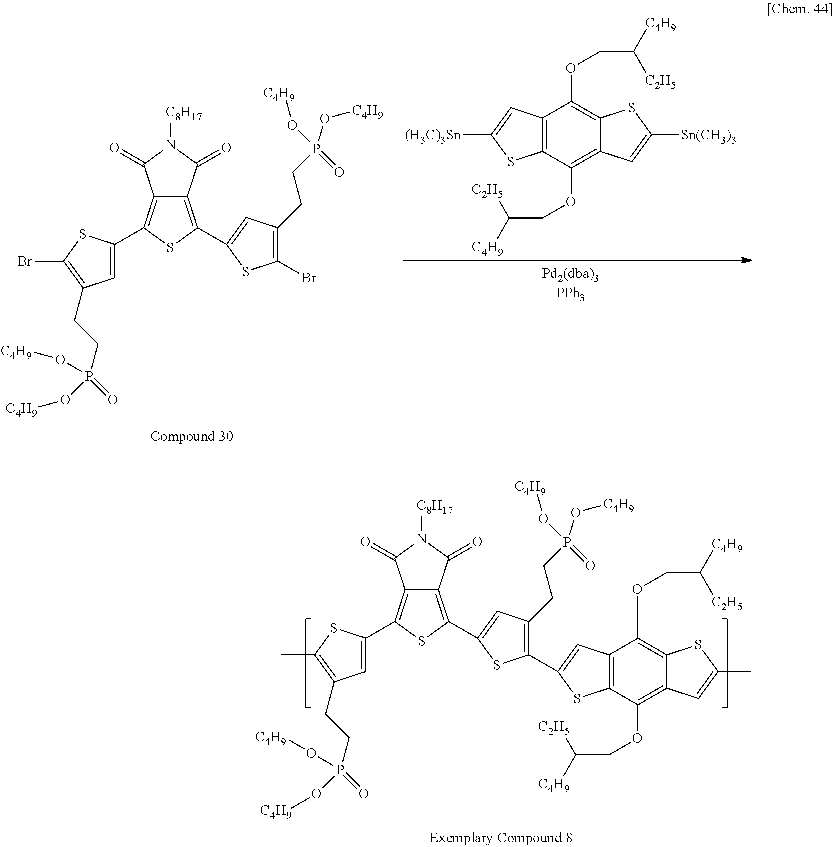

### Synthesis of Exemplary Compound 8 (P-8)

The synthesis of Exemplary Compound 8 was performed in the same manner as the synthesis of Exemplary Compound 2 except changing as the starting material Compound 6 to Compound 30 (0.5 mmol, 514 mg). From a Soxhlet extraction component with o-dichlorobenzene, 230 mg of Exemplary Compound 8 (Mn=21600) was obtained and used in Example 8 of the present invention.

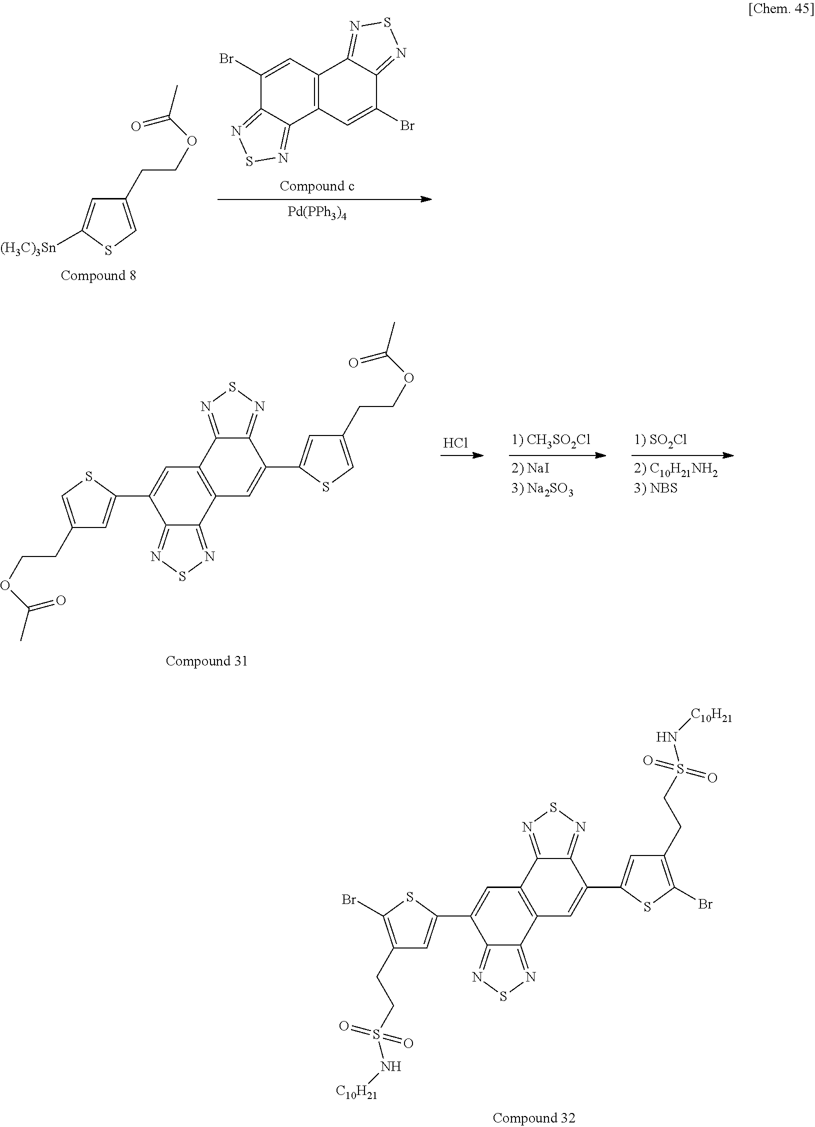

### Synthesis of Compound 31

Compound c was synthesized with reference to Bull. Chem. Soc. Jpn., 1991, 64, 68-73.

The synthesis of Compound 31 was performed in the same manner as the synthesis of Compound 9 except changing the starting materials to Compound 8 and Compound c, thereby obtaining Compound 31.

### Synthesis of Compound 32

The synthesis of Compound 32 was performed in the same manner as the synthesis of a series of Compounds 10 and 17 except changing the starting material to Compound 31, thereby obtaining Compound 32.

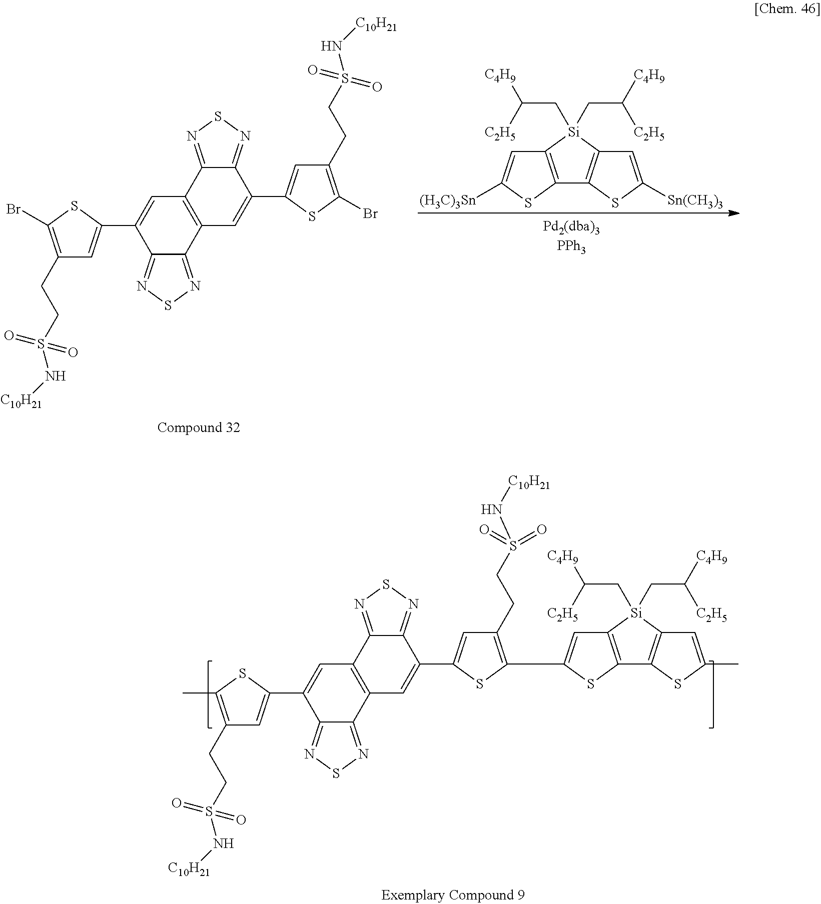

### Synthesis of Exemplary Compound 9 (P-9)

The synthesis of Exemplary Compound 9 was performed in the same manner as the synthesis of Exemplary Compound 1 except changing as the starting material Compound 6 to Compound 32 (0.5 mmol, 530 mg). From a Soxhlet extraction component with o-dichlorobenzene, 240 mg of Exemplary Compound 9 (Mn=20000) was obtained and used in Example 9 of the present invention.

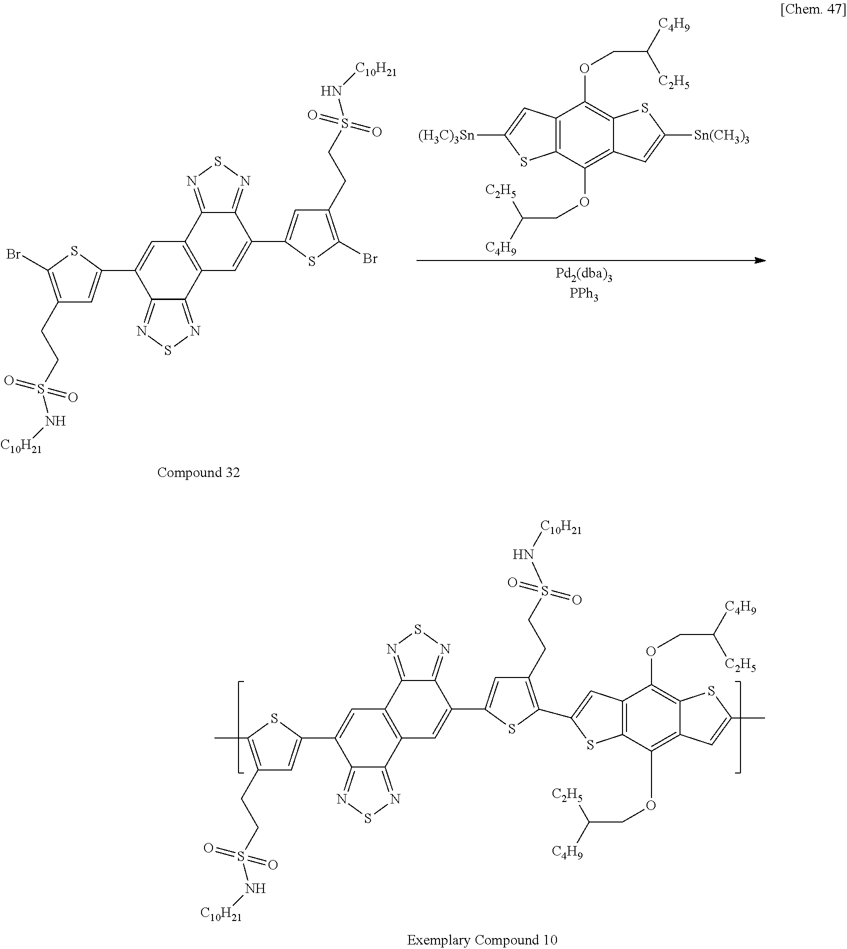

### Synthesis of Exemplary Compound 10 (P-10)

The synthesis of Exemplary Compound 10 was performed in the same manner as the synthesis of Exemplary Compound 2 except changing as the starting material Compound 6 to Compound 32 (0.5 mmol, 530 mg). From a Soxhlet extraction component with o-dichlorobenzene, 210 mg of Exemplary Compound 10 (Mn=19800) was obtained and used in Example 10 of the present invention.

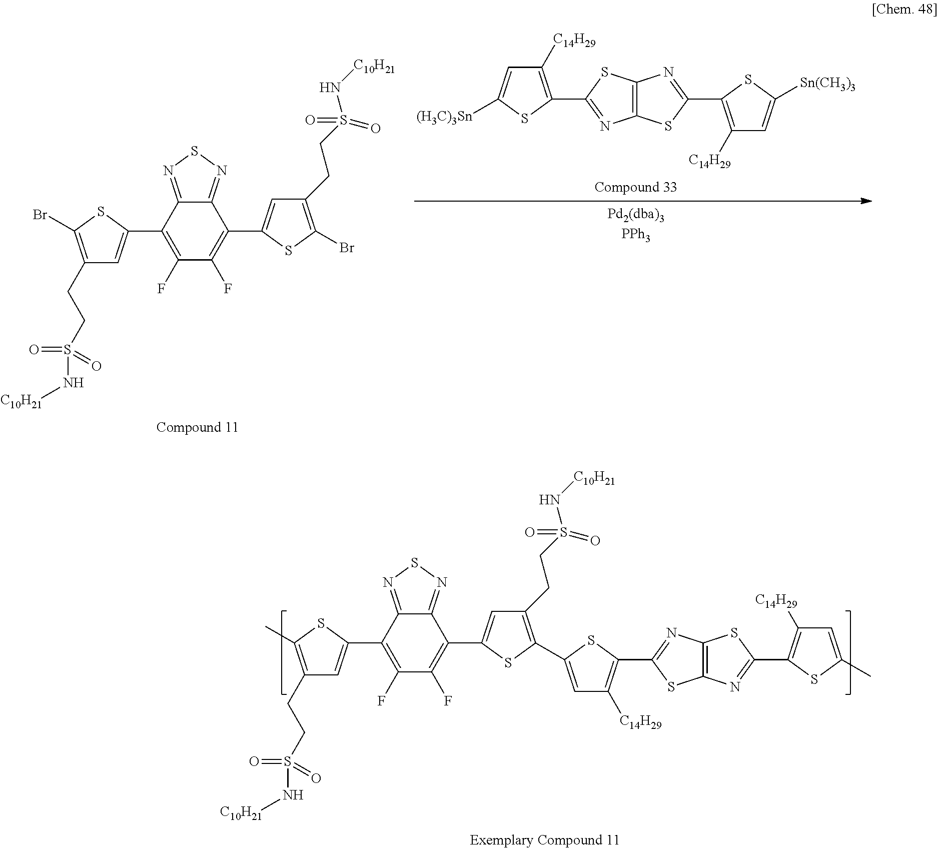

### Synthesis of Exemplary Compound 21 (P-21)

The synthesis of Exemplary Compound 21 was performed in the same manner as the synthesis of Exemplary Compound P-2 except changing bis-(5,5′-trimethylstannyl)-3,3′-di-(2-ethylhexyl)-silyl ene-2,2′-dithiophene to Compound 33 (0.5 mmol, 512 mg) synthesized according to the description of WO 2011/85004 A, whereby 350 mg of dark blue Exemplary Compound 21 (Mn=31000) was obtained and used in Example 11 of the present invention.

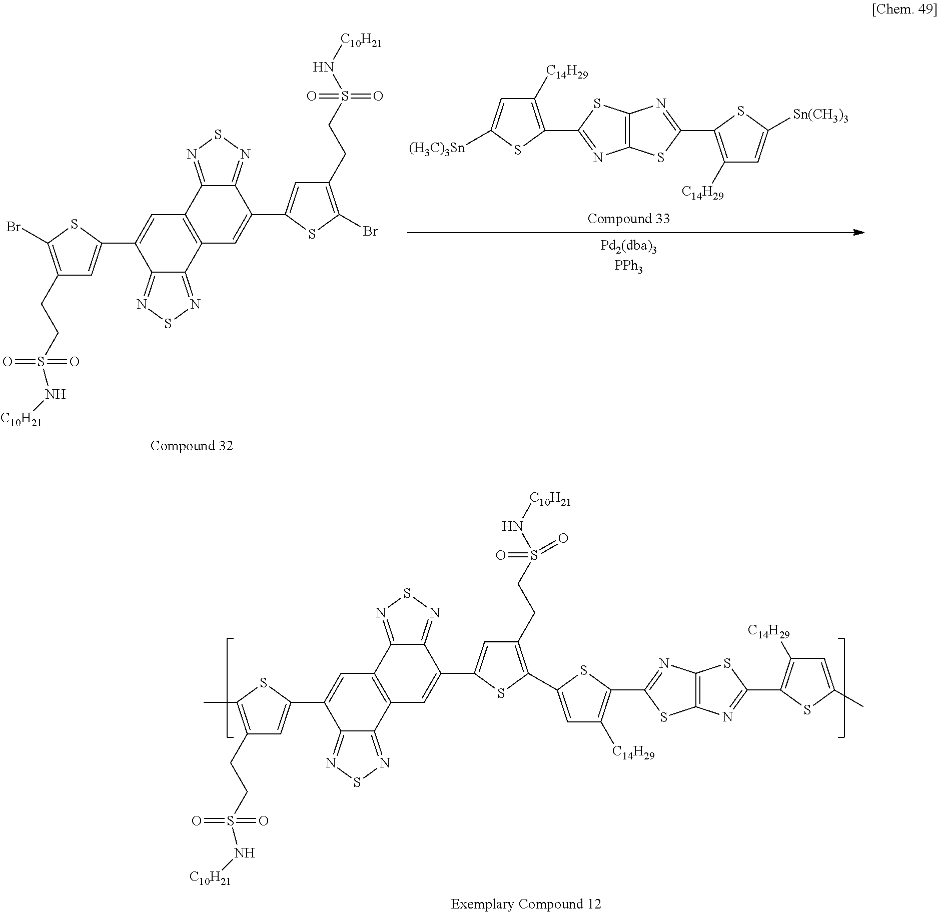

### Synthesis of Exemplary Compound 22 (P-22)

The synthesis of Exemplary Compound 22 was performed in the same manner as the synthesis of Exemplary Compound P-9 except changing bis-(5,5′-trimethylstannyl)-3,3′-di-(2-ethylhexyl)-silyl ene-2,2′-dithiophene to Compound 33 (0.5 mmol, 512 mg) synthesized according to the description of WO 2011/85004 A, whereby 490 mg of dark blue Exemplary Compound 21 (Mn=340000) was obtained and used in Example 12 of the present invention.

### Synthesis of Comparative Compounds 1 to 4

Comparative Compounds 1 and 2 (synthesized based on Patent Literature 2), Comparative Compound 3 (synthesized based on Non-Patent Literature 4), and Comparative Compound 4 (synthesized based on J. Phys. C., 2010, 114: P17989-17994) were respectively synthesized. The structures of the respective Comparative Compounds are shown in the following Chemical Formula 7.

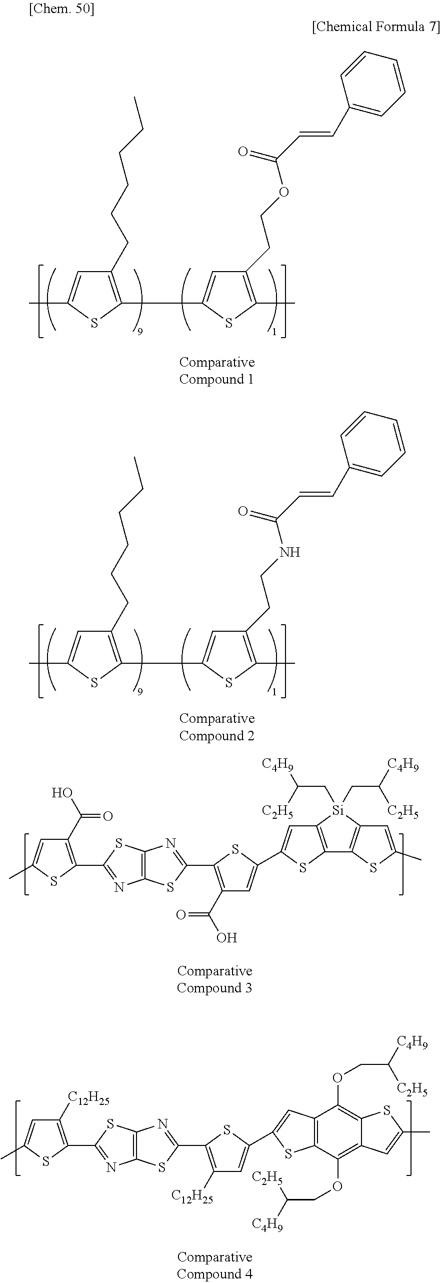

<Preparation of Reverse Layered Type Organic Photoelectric Conversion Element>

A reverse layered type organic photoelectric conversion element was prepared in the following manner with reference to the description of WO 2008-134492 A.

### Example 1

A sheet (sheet resistance 12 Ω/cm²) obtained by depositing 150 nm of a transparent conductive film of indium tin oxide (ITO) as the first electrode (cathode) on a PET substrate was patterned into 10 mm width using a common photolithography technique and wet etching, thereby forming the first electrode. The first electrode pattern formed was subjected to cleaning in order of ultrasonic cleaning with a surfactant and ultrapure water and then ultrasonic cleaning with ultrapure water. Thereafter, the electrode was dried by nitrogen blowing and finally subjected to ultraviolet ozone cleaning. Hereafter, the substrate was brought into a glove box, and the following operations were performed under a nitrogen atmosphere.

A methoxy ethanol solution of 0.05% by mass 3-(2-aminoethyl)-aminopropyltrimethoxysilane manufactured by Sigma-Aldrich Co. LLC. was coated on this first electrode using a blade coater so as to have a dry film thickness of about 5 nm, and dried. Thereafter, the resultant coating was heat treated at 120° C. for 1 minute on a hot plate, thereby forming an electron transport layer.

Subsequently, a solution (p-type organic semiconductor material:n-type organic semiconductor material=33:67 (mass ratio)) was prepared by mixing Exemplary Compound 1 as p-type organic semiconductor material and PC61BM (nanom spectra E100H manufactured by Frontier Carbon Co., Ltd.) as n-type organic semiconductor material in o-dichlorobenzene so as to give concentrations of 0.8% by mass of 1.6% by mass, respectively, and the solution was stirred all night and all day while heating at 110° C. in an oven to be dissolved. Thereafter, the solution thus obtained was coated using a blade coater so as to have a dry film thickness of about 200 nm, and dried at 80° C. for 2 minutes, thereby forming a photoelectric conversion layer.

After drying of the photoelectric conversion layer was completed, the substrate was taken out in the air again, subsequently, a liquid, which was prepared by diluting PEDOT-PSS including a conductive polymer and a polyanion (CLEVIOS (registered trademark) P VP AI 4083 manufacture by Hereosu Materials Technology, conductivity 1×10⁻³ S/cm) with an equal volume of isopropanol, was coated using a blade coater so as to have a dry film thickness of about 30 nm, and dried. Subsequently, the coating was heat treated at 90° C. for 20 seconds with warm air, thereby forming a hole transport layer (organic material layer) including an organic substance. Meanwhile, the temperature and the humidity of the air in the coating was 23° C. and 65%.

Next, a element was provided such that a shadow mask of 10 mm width was perpendicular to a transparent electrode, and pressure in a vacuum deposition apparatus was reduced to 1×10⁻³ Pa or lower, and then Ag metal was deposited thereon by 200 nm at a deposition rate of 0.5 nm/s, thereby forming a second electrode (anode). The laminate thus obtained was moved into a nitrogen chamber, sandwiched between UBF-9L manufactured by Sumitomo 3M Limited (water vapor transmission rate 5.0×E-4 g/m²/d), sealed using a UV curable resin (UV RESIN XNR5570-B1 manufactured by Nagase ChemteX Corporation), and then taken out in the air, thereby obtaining an organic photoelectric conversion element having a light receiving part of about 10×10 mm in size.

In addition, a reverse layered type organic photoelectric conversion element was prepared in the same manner except that the substrate was not taken out from the glove box (GB) (oxygen concentration 10 ppm, dew point temperature −80° C.) under a nitrogen atmosphere after the photoelectric conversion layer was prepared, but the hole transport layer was formed in the glove box.

### Examples 2 to 12 and Comparative Examples 1 to 4

Organic photoelectric conversion elements were prepared in the same manner as in Example 1 except using each of Exemplary Compounds 2 to 12 and Comparative Compounds 1 to 4 instead of Exemplary Compound 1 as the p-type organic semiconductor material.

<Evaluation of Reverse Layered Type Organic Photoelectric Conversion Element>

### (Evaluation on Open Circuit Voltage, Fill Factor, and Photoelectric Conversion Efficiency)

The organic photoelectric conversion elements were separately sealed with an epoxy resin and a glass cap, respectively. This was irradiated with light having an intensity of 100 mW/cm² using a solar simulator (AM1.5G filter), a mask having an effective area of 1 cm² was superimposed on the light receiving part, and then the IV characteristics were evaluated, thereby measuring a short circuit current density J_{sc} (mA/cm²), an open circuit voltage V_{oc} (V), and a fill factor FF. A photoelectric conversion efficiency η [%] was calculated from J_{sc} (mA/cm²), V_{oc} and FF thus obtained by the following Expression (1). The results are shown in Table 1.

[Numerical Formula 1]

η [%]=J_{sc} [mA/cm²]×V_{oc} [V]×FF[%] [Expression 1]

(Evaluation on Film Forming Property of Hole Transport Layer on Photoelectric Conversion Layer)

The preparation of reverse layered type organic photoelectric conversion element was attempted five times for each of Examples 1 to 10 and Comparative Examples 1 to 4 above. Then, film forming property was evaluated by the number in which a hydrophilic solvent contained in the dispersion of organic solvent-based PEDOT: PSS was not repelled on the photoelectric conversion layer and a hole transport layer was favorably formed when the hole transport layer was coated on the photoelectric conversion layer in the air or in a glove box (GB) under a nitrogen atmosphere. The results are shown in Table 1.

(Evaluation on Durability)

The organic photoelectric conversion elements obtained in Examples 1 to 12 and Comparative Examples 1 to 4 were stored in a container maintained at a temperature of 80° C. and a humidity of 80%, and regularly taken out therefrom and subjected to the IV characteristics measurement. The initial photoelectric conversion efficiency was regarded as 100, and the time, at which the efficiency was deteriorated to 80% of the initial efficiency, was taken as LT80 [hours], and the evaluation was performed by the values. It means that the durability is favorable as the value of LT80 is great. The results are shown in Table 2.

TABLE 2

| | | | Coating | | | | | |
|---|---|---|---|---|---|---|---|---|
| | | Number | property | | | | Photoelectric | |
| | | average | of hole | | | | conversion | |
| | | molecular | transport | | | | efficiency | LT80 |
| | Polymer | weight | layer | Voc | Jsc | FF | [%] | [h] |
| Comparative | Comparative | 32300 | Air: 5/5 | 0.50 | 6.3 | 0.55 | 1.73 | 15 |
| Example 1 | Compound 1 | | GB: 5/5 | 0.50 | 6.4 | 0.53 | 1.70 | 40 |
| Comparative | Comparative | 31000 | Air: 2/5 | 0.50 | 5.8 | 0.51 | 1.48 | 28 |
| Example 2 | Compound 2 | | GB: 4/5 | 0.50 | 5.7 | 0.50 | 1.43 | 70 |
| Comparative | Comparative | 15500 | Air: 2/5 | 0.66 | 4.1 | 0.41 | 1.11 | 27 |
| Example 3 | Compound 3 | | GB: 3/5 | 0.66 | 4.0 | 0.41 | 1.08 | 60 |
| Comparative | Comparative | 13600 | Air: 2/5 | 0.77 | 6.1 | 0.48 | 2.25 | 3.1 |
| Example 4 | Compound 4 | | GB: 2/5 | 0.77 | 6.1 | 0.47 | 2.21 | 6.6 |
| Example 1 | Exemplary | 20100 | Air: 5/5 | 0.72 | 9.3 | 0.68 | 4.55 | 210 |
| | Compound 1 | | GB: 5/5 | 0.73 | 9.5 | 0.66 | 4.58 | 460 |
| Example 2 | Exemplary | 15400 | Air: 5/5 | 0.75 | 6.7 | 0.61 | 3.07 | 200 |
| | Compound 2 | | GB: 5/5 | 0.75 | 6.9 | 0.60 | 3.11 | 490 |
| Example 3 | Exemplary | 21000 | Air: 5/5 | 0.72 | 8.8 | 0.67 | 4.25 | 190 |
| | Compound 3 | | GB: 5/5 | 0.72 | 8.9 | 0.65 | 4.17 | 390 |
| Example 4 | Exemplary | 19000 | Air: 5/5 | 0.72 | 8.6 | 0.63 | 3.90 | 170 |
| | Compound 4 | | GB: 5/5 | 0.72 | 8.6 | 0.61 | 3.78 | 350 |
| Example 5 | Exemplary | 16500 | Air: 5/5 | 0.72 | 8.6 | 0.66 | 4.09 | 150 |
| | Compound 5 | | GB: 5/5 | 0.72 | 8.8 | 0.64 | 4.06 | 350 |
| Example 6 | Exemplary | 15000 | Air: 5/5 | 0.75 | 6.7 | 0.61 | 3.07 | 140 |
| | Compound 6 | | GB: 5/5 | 0.75 | 6.9 | 0.58 | 3.00 | 300 |
| Example 7 | Exemplary | 23000 | Air: 5/5 | 0.80 | 5.8 | 0.59 | 2.74 | 100 |
| | Compound 7 | | GB: 5/5 | 0.80 | 6.1 | 0.57 | 2.78 | 180 |
| Example 8 | Exemplary | 21600 | Air: 5/5 | 0.82 | 6.3 | 0.54 | 2.79 | 110 |
| | Compound 8 | | GB: 5/5 | 0.82 | 6.3 | 0.53 | 2.74 | 180 |
| Example 9 | Exemplary | 20000 | Air: 5/5 | 0.74 | 9.8 | 0.67 | 4.86 | 220 |
| | Compound 9 | | GB: 5/5 | 0.74 | 9.9 | 0.66 | 4.84 | 480 |
| Example 10 | Exemplary | 19800 | Air: 5/5 | 0.77 | 8.8 | 0.65 | 4.40 | 200 |
| | Compound 10 | | GB: 5/5 | 0.77 | 8.9 | 0.65 | 4.45 | 480 |
| Example 11 | Exemplary | 31000 | Air: 5/5 | 0.80 | 13.1 | 0.53 | 5.60 | 240 |
| | Compound 11 | | GB: 5/5 | 0.80 | 13.1 | 0.53 | 5.60 | 440 |
| Example 12 | Exemplary | 34000 | Air: 5/5 | 0.81 | 13.6 | 0.55 | 6.10 | 200 |
| | Compound 12 | | GB: 5/5 | 0.81 | 13.6 | 0.55 | 6.10 | 470 |

From the results in Table 2, it is noted that Examples 1 to 12 using the conjugated polymer compound having a specific partial structure according to the present invention exhibit excellent durability and sufficient photoelectric conversion efficiency as compared to Comparative Examples 1 to 4.

With regard to the evaluation on the durability of element, the durability was significantly improved in all of Examples, in which the hole transport layer was formed both in the air and in a glove box, as compared to Comparative Examples. In particular, Examples 1 to 4, 9, and 10 to 12 using a conjugated polymer compound having a sulfonamide group introduced as the polar group thereinto exhibited particularly high durability as compared to the other Examples.

Moreover, it is noted that the durability of element is further improved in Examples, in which a hole transport layer is formed in a glove box having less oxygen and moisture, as compared with the other Examples, in which a hole transport layer is formed in the air. On the other hand, film forming in Comparative Example 4, in which a polar group was not introduced, was significantly difficult since the hydrophilic solvent was repelled when the hole transport layer was coated in a glove box, but it is noted that the coating property of hole transport layer is favorable and high photoelectric conversion efficiency can be attained in Examples 1 to 12, in which a strong polar group is introduced.

This application is based upon Japanese Patent Application No. 2011-282048 filed on Dec. 22, 2011, and the entire contents of which are incorporated herein by reference.

1. An organic photoelectric conversion element comprising a conjugated polymer compound having a partial structure represented by the following Chemical Formula 1; 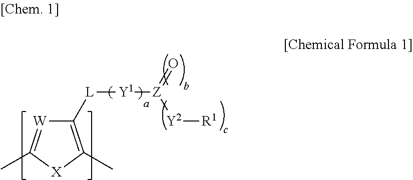
wherein X independently represents an oxygen atom (O), a sulfur atom (S), NR², or CR³═CR⁴;
W independently represents CH or a nitrogen atom (N);
L independently represents a linear or branched alkylene group having 1 to 10 carbon atoms;
Y¹ and Y² independently represent an oxygen atom (O) or NR⁵;
Z independently represents a carbon atom (C), a sulfur atom (S), or a phosphorus atom (P);
R¹ to R⁵ independently represent a hydrogen atom (H), a linear or branched alkyl group having 1 to 24 carbon atoms, a cycloalkyl group having 3 to 20 carbon atoms, an alkenyl group having 2 to 20 carbon atoms, an aryl group having 6 to 30 carbon atoms, or a heteroaryl group having 1 to 20 carbon atoms; and
a, b, and c independently represent an integer satisfying the relation: 3≦a+b+c≦4 and 0≦a, b, c≦2.

2. The organic photoelectric conversion element according to claim 1, wherein the organic photoelectric conversion element comprises:
a first electrode;
a second electrode; and
a photoelectric conversion layer containing an n-type organic semiconductor and a p-type organic semiconductor, and provided between the first electrode and the second electrode,
wherein the p-type organic semiconductor contains the conjugated polymer compound having the partial structure represented by Chemical Formula 1.

3. The organic photoelectric conversion element according to claim 1, wherein W represents CH.

4. The organic photoelectric conversion element according to claim 1, wherein at least either Y¹ or Y² represents NR⁵.

5. The organic photoelectric conversion element according to claim 4, wherein Y² represents NR⁵.

6. The organic photoelectric conversion element according to claim 1, wherein Z represents a sulfur atom (S).

7. The organic photoelectric conversion element according to claim 1, wherein X represents a sulfur atom (S).

8. The organic photoelectric conversion element according to claim 1, wherein the conjugated polymer compound has a partial structure represented by the following Chemical Formula 2; 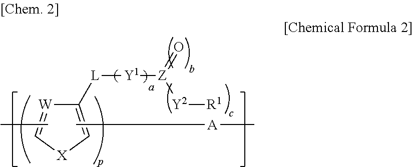
wherein A independently represents an acceptor unit,
X, W, L, Y¹, Y², Z, R¹, a, b, and c are as are as defined in the Chemical Formula 1, and
p independently represents an integer from 1 to 5.

9. The organic photoelectric conversion element according to claim 1, wherein the conjugated polymer compound has a partial structure represented by the following Chemical Formula 3; 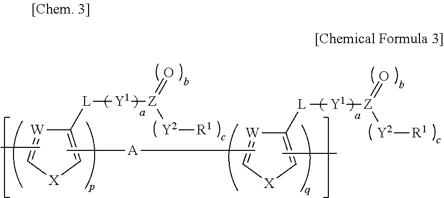
wherein A each independently represents an acceptor unit,
X, W, L, Y¹, Y², Z, R¹, a, b, and c are as defined in the Chemical Formula 1, and
p and q independently represent an integer from 1 to 5.

10. The organic photoelectric conversion element according to claim 1, wherein the conjugated polymer compound has at least a partial structure represented by the following Chemical Formula 4; 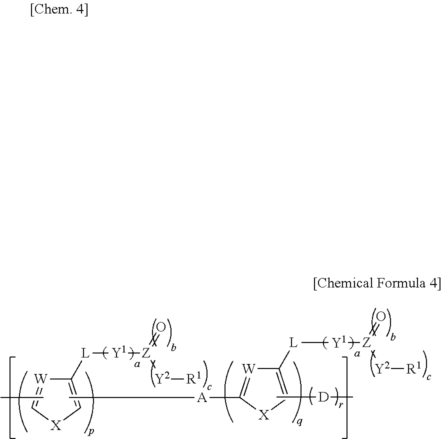
wherein A independently represents an acceptor unit,
D independently represents a donor unit,
X, W, L, Y¹, Y², Z, R¹, a, b, and c are as defined in the Chemical Formula 1, and
p, q, and r independently represent an integer from 1 to 5.

11. The organic photoelectric conversion element according to claim 1, wherein A represents the following Chemical Formula A or Chemical Formula B; 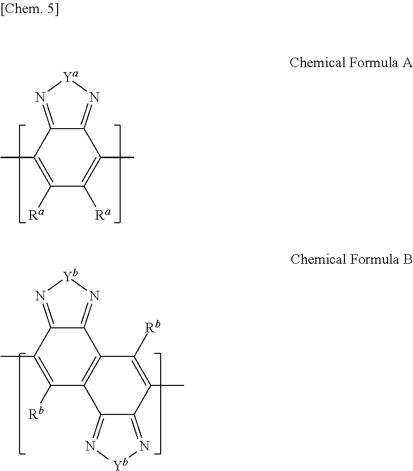
wherein Y^{a} and Y^{b} independently represent —O—, —NR^{c}—, —S—, —C(R^{d})═C(R^{e})—, —N═C(R^{f})—, or —CR^{g}R^{h}—, and
R^{a} to R^{h} independently represent a hydrogen atom, a halogen atom, or an alkyl group having 1 to 24 carbon atoms, a fluorinated alkyl group having 1 to 24 carbon atoms, a cycloalkyl group having 3 to 20 carbon atoms, a fluorinated cycloalkyl group having 3 to 20 carbon atoms, an alkoxy group having 1 to 24 carbon atoms, a fluorinated alkoxy group having 1 to 24 carbon atoms, an alkylthio group having 1 to 24 carbon atoms, a fluorinated alkylthio group having 1 to 24 carbon atoms, an aryl group having 6 to 30 carbon atoms, a fluorinated aryl group having 6 to 30 carbon atoms, a heteroaryl group having 1 to 20 carbon atoms, or a fluorinated heteroaryl group having 1 to 20 carbon atoms which are substituted or unsubstituted, wherein each of R^{a} or R^{d} and R^{e} or R^{g} and R^{h} may be bound each other to form a ring that may have a substituent or may form a condensed ring.

12. The organic photoelectric conversion element according to claim 1, wherein the first electrode is a transparent electrode, the second electrode is a counter electrode, and a hole transport layer is provided between the second electrode and the photoelectric conversion layer.

13. A solar cell comprising the organic photoelectric conversion element set forth in claim 1.

14. The organic photoelectric conversion element according to claim 3, wherein at least either Y¹ or Y² represents NR⁵.

15. The organic photoelectric conversion element according to claim 14, wherein Z represents a sulfur atom (S).

16. The organic photoelectric conversion element according to claim 15, wherein X represents a sulfur atom (S).

17. The organic photoelectric conversion element according to claim 9, wherein at least either Y¹ or Y² represents NR⁵.

18. The organic photoelectric conversion element according to claim 17, wherein Z represents a sulfur atom (S).

19. The organic photoelectric conversion element according to claim 2, wherein the first electrode is a transparent electrode, the second electrode is a counter electrode, and a hole transport layer is provided between the second electrode and the photoelectric conversion layer.

20. The organic photoelectric conversion element according to claim 19, wherein the conjugated polymer compound has a partial structure represented by the following Chemical Formula 3; 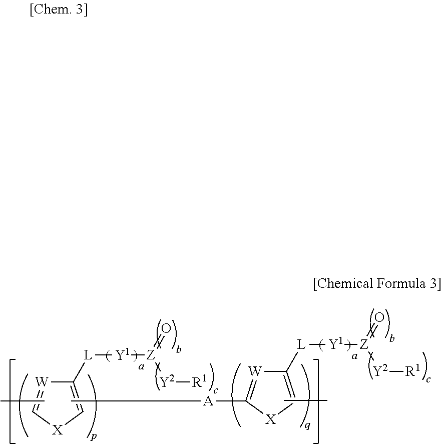
wherein A each independently represents an acceptor unit,
X, W, L, Y¹, Y², Z, R¹, a, b, and c are as defined in the Chemical Formula 1, and
p and q independently represent an integer from 1 to 5.
